(19) United States
(12) Patent Application Publication
(10) Pub. No.: US 2005/0260786 A1
(43) Pub. Date: Nov. 24, 2005

(54) Dye-sensitized solar cell

(75) Inventors: Masato Yoshikawa, Kodaira-shi (JP); Shingo Ohno, Kodaira-shi (JP); Taichi Kobayashi, Kodaira-shi (JP); Takayuki Sugimura, Kodaira-shi (JP); Yoshinori Iwabuchi, Kodaira-shi (JP); Osamu Shiino, Kodaira-shi (JP); Hideo Sugiyama, Kodaira-shi (JP); Yasuo Horikawa, Kodaira-shi (JP); Shinichi Toyosawa, Kodaira-shi (JP)

Correspondence Address: SUGHRUE MION, PLLC, 2100 PENNSYLVANIA AVENUE, N.W., SUITE 800, WASHINGTON, DC, 20037, US

(73) Assignee: BRIDGESTONE CORPORATION, Tokyo (JP)

(21) Appl. No.: 10/524,261

(22) PCT Filed: Aug. 6, 2003
(86) PCT No.: PCT/JP03/09983

§ 371 Date: Mar. 10, 2005

(30) Foreign Application Priority Data
Aug. 13, 2002 (JP) 2002-235408
Aug. 13, 2002 (JP) 2002-235393
Aug. 13, 2002 (JP) 2002-235405
Oct. 1, 2002 (JP) 2002-288939
Oct. 31, 2002 (JP) 2002-317340
Dec. 12, 2002 (JP) 2002-361071
Dec. 12, 2002 (JP) 2002-361067
Dec. 12, 2002 (JP) 2002-361068
Dec. 12, 2002 (JP) 2002-361069

(51) Int. Cl. H01L 21/00

(52) U.S. Cl. 438/85

(57) ABSTRACT

An electrolyte for dye-sensitized solar cells, wherein an oxidation-reduction substance is carried by a vulcanized rubber, a phosphazene polymer, a porous body comprising a high molecular material which has a three-dimensional continuous network skeleton structure, or an EVA resin film. A dye-sensitized solar cell comprising dye-sensitized semiconductor electrodes 2, 3, a counter electrode 4 arranged at an opposed position to the electrodes, and an electrolyte 6 between the electrodes 2, 3 and the electrode 4. A solid electrolyte for dye-sensitized solar cells effective in improving the generation efficiency, durability, and safety of dye-sensitized solar cells and can be manufactured inexpensively.

### FIELD OF THE INVENTION

(1) The first invention relates to an electrolyte for dye-sensitized solar cells and a dye-sensitized solar cell and, particularly, to a solid electrolyte to be used for dye-sensitized solar cells and a dye-sensitized solar cell provided with such a solid electrolyte.

(2) The second invention relates to an electrode for dye-sensitized solar cells and a method of manufacturing the same and, more particularly, to improvement of a method of forming a titanium oxide thin membrane for adsorbing sensitizing dye of a dye-sensitized solar cell.

(3) The third invention relates to an organic dye-sensitized solar cell.

(4) The fourth invention relates to an organic dye-sensitized solar cell and a building material such as a window pane, a roofing material, and the like having such a solar cell.

(5) The fifth invention relates to an organic dye-sensitized solar cell, an organic dye-sensitized metal oxide semiconductor electrode to be advantageously used in the solar cell, and a metal oxide semiconductor membrane to be advantageously used for manufacturing the electrode.

(6) The sixth invention relates to an organic dye-sensitized solar cell, an organic dye-sensitized metal oxide semiconductor electrode to be advantageously used in manufacturing of the solar cell and a method of forming the same, and a transparent electrode substrate to be advantageously used for manufacturing the semiconductor electrode and a method of forming the same.

### BACKGROUND OF THE INVENTION

(1) It is already known that an oxide semiconductor to which sensitizing dye is adsorbed is used as an electrode to manufacture a solar cell. FIG. 1 is a sectional view showing a general structure of such a dye-sensitized solar cell. As shown in FIG. 1, a transparent electrode 2 is formed on a substrate 1 such as a glass substrate and a semiconductor membrane 3 of metal oxide into which a spectral sensitizing dye is adsorbed is formed on the transparent electrode 2. A counter electrode 4 is provided to be spaced apart from and to face the transparent electrode 2 of the dye-sensitized semiconductor electrode. Further, the outer edge of the lamination is sealed by sealing material 5, and an electrolyte 6 is encapsulated between the dye-sensitized semiconductor electrode and the counter electrode 4. The dye-adsorbing semiconductor membrane 3 is normally a titanium oxide thin membrane to which a dye is adsorbed. The dye adsorbed to the titanium oxide thin membrane is excited by light in visible region. Electrons generated by the excitation are moved to titanium oxide microparticles, thereby generating electric power.

Since conventional electrolyte in dye-sensitized solar cells is normally liquid-type electrolyte which is made by dissolving oxidation-reduction substance into solvent, there is a problem of liquid leakage from a sealed portion. This affects the durability and reliability of dye-sensitized solar cells.

To solve this problem, it has been proposed to turn liquid-type electrolyte into pseudo solidified state by using any of various polymers to carry the liquid-type electrolyte. However, it is still desired to provide a solid electrolyte which works without loosing power generation efficiency of dye-sensitized solar cells and which is excellent in safety and durability and is low in price.

(2) A dye-sensitized solar cell comprises a cathode electrode and an anode electrode which are arranged to face each other so as to form a cell in which an electrolyte is encapsulated. The cathode electrode is composed of a conductive glass and the anode electrode comprises a conductive glass and a TiO₂ thin membrane to which a dye is adsorbed and which is formed on the conductive glass. The cathode electrode and the anode electrode are spaced apart from each other by a distance from several tens of μm to several mm to face each other via the electrolyte. The dye adsorbed to the TiO₂ thin membrane of the anode electrode is excited by light in visible region. Electrons generated by the excitation are moved to TiO₂ fine particles, thereby generating electric power.

Conventionally, such an anode electrode is manufactured by making TiO₂ particles into paste by using organic binder, applying the paste of the TiO₂ particles onto a glass substrate having a transparent conductive thin membrane formed thereon, after that, baking the applied paste to remove the binder, and adsorbing sensitizing dye to thus obtained TiO₂ thin membrane by impregnation method.

In the method for making a conventional anode electrode in which the TiO₂ thin membrane is formed by applying and baking the paste of TiO₂ particles, it is required to use a heat-resisting glass as the substrate. This leads to disadvantage in reduction of thickness, weight, and cost of electrodes. The transparent conductive thin membrane under the TiO₂ thin membrane is normally formed by spattering method. In the conventional method in which the TiO₂ thin membrane is formed by applying and baking the paste of TiO₂ particles, it is impossible to continuously conduct the process of forming the transparent conductive thin membrane and the process of forming the TiO₂ thin membrane. It is also disadvantage in film forming operation.

(3) In recent years, solar cells which directly convert sunlight to electric energy are drawing the attention of people in view of energy-saving, effective utilization of natural materials, and prevention against environmental pollution and thus its development is promoted.

Mainstream solar cell is a solar cell using crystalline silicon or amorphous silicon as photoelectric converting material. However, large energy is required to form such crystalline silicon. The utilization of silicon contradicts the original object of solar cells as energy-saving cells utilizing sunlight. In addition, as a result of using large energy, solar cells using silicon as the photoelectric converting material inevitably become expensive.

The photoelectric converting material is a material for converting light energy into electrical energy by utilizing electrochemical reaction between electrodes. For example, by irradiating the photoelectric converting material with light, electrons are generated at one of electrodes and are moved to a counter electrode. Electrons moved to the counter electrode are moved as ions in the electrolyte to return the one of the electrodes. That is, the photoelectric converting material is a material capable of continuously taking electrical energy from light energy so that the photoelectric converting material is utilized in solar cells.

A solar cell is known which use an oxide semiconductor, which is sensitized by organic dye, as the photoelectric converting material without using silicon. Proposed in Nature, 268 (1976), page 402 is a solar cell using a metal oxide semiconductor electrode in which rose Bengal as organic dye is adsorbed to a surface of a sintered body. The sintered body is formed by compression-molding zinc oxide powder and sintering the molded zinc oxide powder for 1 hour at 1300° C. As for the current/voltage curve of the solar cell, the current value at generation of voltage of 0.2V is very low about 25 μA so that it has been considered that it is impossible to put into practical use. However, dislike the solar cell using the aforementioned silicon, both the oxide semiconductor and the organic dye are mass-produced and are thus relatively low in price so that the solar cell is very advantageous from the viewpoint of material.

As another example as solar cells using an oxide semiconductor, which is sensitized by organic dye, as the photoelectric converting material as mentioned above, a solar cell having a layer of spectral sensitizing dye such as a complex of transition metal on a surface of a metal oxide semiconductor described in JP H01-220380A and a solar cell having a layer of spectral sensitizing dye such as a complex of transition metal on a surface of a titanium oxide semiconductor layer which is doped by metal ion described in JP H05-504023A are also known.

The aforementioned solar cell does not obtain a practical current/voltage curve. As a solar cell having a layer of spectral sensitizing dye giving a practical current/voltage curve, JP H10-92477A discloses a solar cell using an oxide semiconductor membrane which is formed of a burned substance of aggregate of oxide semiconductor fine particles. The semiconductor membrane is formed by applying slurry of the oxide semiconductor fine particles on a transparent electrode, drying the applied slurry, and then baking the dried matter for 1 hour at 500° C.

The organic dye-sensitized solar cell using the organic dye-sensitized metal oxide semiconductor membrane employs a configuration that a semiconductor membrane is sandwiched between glass substrates from both sides thereof. As for the organic dye-sensitized solar cell, semiconductor membranes and dyes have been studied for the purpose of bringing the characteristics thereof to a practical level. As well as studies from such an aspect, it is also important to study from an aspect for achieving higher efficiency of using solar energy. It is also concerned that there is a problem of scattering of glass pieces when broken because the glass substrates are used on both sides.

(4) The organic dye-sensitized solar cell using the organic dye-sensitized metal oxide semiconductor membrane generally employs a configuration that a semiconductor membrane is sandwiched between glass substrates from both sides thereof. The installation location of such solar cells may be normally on a house top or a roof. Since the glass substrates are used, the solar cells have no flexibility so that it is difficult to cover with the solar cells. Therefore, the solar cells are separately installed.

The inventors of the present invention have been studied from the viewpoint of seeking solar cells that are easer to use. As a result, the inventors reached the following conclusion. That is, an organic dye-sensitized solar cell which is flexible and thus is easily attached and which maintains transparency when attached to a glass, a solar cell which has flexibility and has color, pattern, high reflexivity and the like so that it is provided with designing property and decorative property are advantageous from usability. Further, a building material such as a roofing material or a wall material which is covered with solar cells is also advantageous because it can be easily used.

(5) In the aforementioned solar cell of JP H10-92477A, the oxide semiconductor membrane of a burned substance of aggregate of oxide semiconductor fine particles is formed by so-called sol-gel method. In this forming method, since it is necessary to heat for a long period at high temperature after applied, heat resistance is also required to the substrate and the transparent electrode. Since normal transparent electrodes such as ITO does not have such heat resistance, it is required to use tin oxide doped with fluoride as a transparent electrode having excellent heat resistance. Since the tin oxide doped with fluoride is poor in conductivity, it is not suitable for such an application requiring a large surface area like a solar cell.

(6) In the aforementioned solar cell of JP H10-92477A, the oxide semiconductor membrane of a burned substance of aggregate of oxide semiconductor fine particles is formed by so-called sol-gel method. In this forming method, since it is necessary to heat for a long period at high temperature after applied, heat resistance is also required to the substrate and the transparent electrode. The oxide semiconductor of a burned substance has a relatively large surface area so that its dye adsorbing amount is high and its light energy conversion efficiency is high, thereby providing a practical current/voltage curve. However, since heating at high temperature for a long period is required, it is difficult to use a normal transparent electrode such as ITO which has insufficient heat resistance. Therefore, it is desired to provide an organic dye-sensitized metal oxide semiconductor electrode which has oxide semiconductor membrane having a larger surface area, i.e. high light energy conversion efficiency, without the necessity of heating at high temperature and also to provide an organic dye-sensitized metal oxide semiconductor electrode having an oxide semiconductor membrane having further larger surface area.

### OBJECTS OF THE INVENTION

(1) It is an object of the first invention to provide a solid electrolyte for dye-sensitized solar cells which is effective for improving power generation efficiency, durability, and safety of dye-sensitized solar cells and which can be manufactured at a low cost and to provide a dye-sensitized solar cell using the solid electrolyte.

(2) It is an object of the second invention to provide an electrode for dye-sensitized solar cells in which a titanium oxide thin membrane is formed by reactive sputtering, thereby enabling the use of an organic resin film as a substrate and thus reducing the thickness, weight, and cost and improving the production efficiency, and to provide a method of manufacturing the electrode for dye-sensitized solar cells.

(3) It is an object of the third invention to provide an organic dye-sensitized solar cell having an organic dye-sensitized metal oxide semiconductor electrode capable of effectively utilizing light energy.

It is another object of the third invention to provide an organic dye-sensitized solar cell having an organic dye-sensitized metal oxide semiconductor electrode which is capable of effectively utilizing light energy and possesses little danger of breakage.

(4) It is an object of the fourth invention to provide an organic dye-sensitized solar cell which is flexible and thus is easily installed.

It is another object of the fourth invention to provide an organic dye-sensitized solar cell which is flexible and thus is easily attached and which is provided with designing property and decorative property and to provide a building material which is covered with the organic dye-sensitized solar cell.

(5) It is an object of the fifth invention to provide a method of forming a metal oxide semiconductor membrane which achieves the easy formation of a metal oxide semiconductor membrane provided with improved dye adsorptive property at a low temperature.

It is another object of the fifth invention to provide an organic dye-sensitized metal oxide semiconductor electrode having high light energy conversion efficiency which is obtained by the aforementioned method and to provide an organic dye-sensitized solar cell having the organic dye-sensitized metal oxide semiconductor electrode.

(6) It is an object of the sixth invention to provide a transparent electrode substrate having large surface area and a low resistance which is suitable for forming a metal oxide semiconductor membrane and which is capable of obtaining a metal oxide semiconductor membrane provided with improved dye adsorptive property and to provide a method of forming the transparent electrode substrate.

It is another object of the sixth invention to provide a method of forming a metal oxide semiconductor membrane which achieves the easy formation of a metal oxide semiconductor membrane provided with improved dye adsorptive property at a low temperature, to provide an organic dye-sensitized metal oxide semiconductor electrode having high light energy conversion efficiency which is advantageously obtained by the aforementioned method, and to provide an organic dye-sensitized solar cell having the organic dye-sensitized metal oxide semiconductor electrode.

### SUMMARY OF THE INVENTION

(1) First Invention

(1-i) An electrolyte for dye-sensitized solar cells of this invention is characterized in that an oxidation-reduction substance is carried by a vulcanized rubber.

(1-ii) An electrolyte for dye-sensitized solar cells of this invention is characterized in that an oxidation-reduction substance is carried by a porous body comprising a high molecular material which has a three-dimensional continuous network skeleton structure.

(1-iii) An electrolyte for dye-sensitized solar cells of this invention is characterized in that an oxidation-reduction substance is carried by a phosphazene polymer.

(1-iv) the electrolyte for dye-sensitized solar cells of this invention is characterized in that an ethylene vinyl acetate copolymer resin (hereinafter, referred to as “EVA resin”) film carries an oxidation-reduction substance.

The oxidation-reduction substance is carried by a vulcanized rubber, a porous body comprising a high molecular material which has a three-dimensional continuous network skeleton structure, or an EVA resin film, thereby mimically solidifying the electrolyte. The electrolyte does not affect the power generation efficiency of a dye-sensitized solar cell, is excellent in safety and durability, and can be provided at a low cost.

(1-v) A dye-sensitized solar cell of this invention comprises a dye-sensitized semiconductor electrode, a counter electrode arranged at an opposed position to the dye-sensitized semiconductor electrode, and a solid electrolyte arranged between the dye-sensitized semiconductor electrode and the counter electrode, wherein the solid electrolyte is an electrolyte for dye-sensitized solar cells as described in any one of the inventions (1-i) through (1-iv). Therefore, the dye-sensitized solar cell is excellent in power generation efficiency, safety, and durability and can be provided at a low cost.

(2) Second Invention

(2-i) A method of manufacturing an electrode for dye-sensitized solar cells of the present invention includes a step of forming a titanium oxide thin membrane on a substrate, and is characterized in that dthe titanium oxide thin membrane is formed by reactive sputtering using a Ti metal target.

Since the titanium oxide thin membrane is formed by reactive sputtering in this invention, an organic resin film which is lightweight, allows formation into a thin membrane, and is inexpensive can be employed as the substrate and continuous film formation of titanium oxide thin membranes is enabled in formation of the transparent conductive thin membrane. Therefore, it is possible to achieve reduction in thickness, weight, and cost of the electrode and improvement of the productivity.

By the way, the reactive sputtering using a Ti metal target provides very slow film formation under the ordinal condition, resulting in poor productivity.

The reactive sputtering is conducted in an atmosphere which is a little short of oxygen for the film formation of TiO₂ thin membrane in this invention, the speed of film formation is significantly higher than that of the sputtering in an atmosphere with excessive oxygen. The oxygen concentration is easily controlled by plasma emission control or impedance control.

When the reactive sputtering is conducted by using a dual cathode system, stable film formation can be conducted at higher speed for a long period of time.

(2-ii) An electrode for dye-sensitized solar cells of this invention is manufactured by the method of the invention (2-i) and has a titanium oxide thin membrane formed on an organic resin film by the reactive sputtering using a Ti metal target. Therefore, the electrode has a reduced thickness and light weight and can be provided inexpensively.

(3) Third Invention

(3-i) An organic dye-sensitized solar cell of this invention comprises a transparent substrate having a transparent electrode on a surface thereof, an organic dye-sensitized metal oxide semiconductor electrode having a metal oxide semiconductor membrane formed on the transparent electrode and containing organic dye adsorbed in a surface of the semiconductor membrane, a counter electrode arranged at an opposed position to the electrode, and a redox electrolyte filled between these electrodes, and is characterized in that an antireflective membrane is formed on a surface of said transparent substrate at a side where no transparent electrode is formed.

(3-ii) An organic dye-sensitized solar cell of this invention comprises a transparent substrate having a transparent electrode on a surface thereof, an organic dye-sensitized metal oxide semiconductor electrode having a metal oxide semiconductor membrane formed on the transparent electrode and containing organic dye adsorbed in a surface of the semiconductor membrane, a counter electrode arranged at an opposed position to the electrode, and a redox electrolyte filled between these electrodes, and is characterized in that an antireflective film having an antireflective membrane is attached to a surface of said transparent substrate at a side where no transparent electrode is formed via an adhesive layer.

In the aforementioned solar cell, it is preferable that the antireflective membrane reduces the reflectance in a wavelength in which the absorbancy of the organic dye is maximum and that the antireflective membrane has minimum reflectance in a wavelength in which the absorbancy of the organic dye is maximum. The same is true for the antireflective film. According to the kind of dye, the reflectance is effectively reduced.

The antireflective film generally comprises a transparent polymer film and an antireflective membrane formed on the transparent polymer film.

It is preferable that the antireflective membrane is an inorganic laminated membrane consisting of, in top-to-bottom order, low-refractive transparent inorganic thin membrane(s) and high-refractive transparent inorganic thin membrane(s) which are alternately laminated. The number of layers is preferably from 2 to 6 for achieving effective usage of solar energy. A low-refractive organic thin membrane may be provided instead of the upper-most low-refractive transparent inorganic thin membrane.

It is preferable that the antireflective film has an ultraviolet protection layer between the transparent polymer film and the antireflective membrane formed on the transparent polymer film. It prevents deterioration of the dye. It is also preferable that the high-refractive transparent inorganic thin membrane of the antireflective membrane is a thin membrane having refractive index of 1.8 or more made of ITO (indium tin oxide), ZnO, Al-doped ZnO, Al-doped TiO₂, Al-doped SnO₂, or ZrO and that the low-refractive transparent inorganic thin membrane of the antireflective membrane is a thin membrane having refractive index of 1.6 or less made of SiO₂, MgF₂, or Al₂O₃.

It is preferable that the adhesive layer contains ethylene-vinyl acetate copolymer or sticky acrylic resin because the glass plate is prevented from scattering.

The transparent substrate is preferably a glass plate.

As a result of further study, the inventors found that the antireflective sheet is designed to correspond to the adsorptive property of a ruthenium containing dye (ruthenium phenanthroline, ruthenium diketonate) and/or coumarin derivative dye which are generally used for organic dye-sensitized solar cells, whereby solar energy can be further effectively used.

Therefore, the present invention also provides an organic dye-sensitized solar cell in which the aforementioned dye is a ruthenium containing dye (ruthenium phenanthroline, ruthenium diketonate) and the antireflective membrane preferably has light reflectance of 10% or less (especially, 5% or less) in a range of wavelength from 300 to 600 nm. More preferably, the dye has minimum light reflectance in the aforementioned range.

Further, the present invention also provides an organic dye-sensitized solar cell in which the aforementioned dye is a coumarin derivative dye, the antireflective membrane preferably has light reflectance of 10% (especially, 5% or less) or less in a range of wavelength from 400 to 600 nm. More preferably, the dye has minimum light reflectance in the aforementioned range.

(4) Fourth Invention

(4-i) An organic dye-sensitized solar cell of this invention comprises a transparent substrate having a transparent electrode on a surface thereof, an organic dye-sensitized metal oxide semiconductor electrode having a metal oxide semiconductor membrane formed on the transparent electrode and containing organic dye adsorbed in a surface of the semiconductor membrane, a counter electrode arranged at an opposed position to the electrode, and a redox electrolyte filled between these electrodes, and is characterized in that the transparent substrate is a transparent organic polymer substrate and the counter electrode is formed on an organic polymer substrate.

In the solar cell, it is preferable that the transparent electrode is provided between the counter electrode and the organic polymer substrate. This improves electrical conductivity. It is preferable that the organic polymer substrate having the counter electrode has a high reflectance and that the organic polymer substrate having the counter electrode is colored and/or has a pattern providing the designing property and the decorative property. The high reflectance enables effective utilization of light energy. The designing property and the like expands an applicable range of installation location of solar cells, thus improving usability. Since the color or pattern providing the designing property is formed on a back surface of the solar cell, the light intensity of sun light directly incident on the color or pattern is significantly reduced. Therefore, the color or pattern is protected from sun light, thus providing advantage of significantly reducing deterioration of the color or pattern.

It is preferable that the material of the (transparent) organic polymer substrate is polyethylene terephthalate, polycarbonate, polymethyl methacrylate, or fluorocarbon resin (for example, PTFE (polytetrafluoroethylene), ETFE (ethylene/tetrafluoroethylene copolymer)). These are excellent in transparency.

It is also preferable that a release film is attached to the back surface of the organic polymer substrate having the counter electrode via an adhesive layer. This facilitates attachment of the solar cell to various places such as a window pane, a wall material, and the like. It is preferable that the adhesive layer contains ethylene-vinyl acetate copolymer or sticky acrylic resin. These are excellent in durability.

(4-ii) A building material of this invention is characterized by comprising the organic dye-sensitized solar cell of the above (4-i), wherein the back surface of the transparent organic polymer substrate having the counter electrode is bonded to a surface of a base material via an adhesive layer.

It is preferable that the base material is a window pane or a roofing material.

In the aforementioned solar cell of JP H10-92477A, the oxide semiconductor membrane of a burned substance of aggregate of oxide semiconductor microparticles is formed by so-called sol-gel method. In this forming method, since it is necessary to heat for a long period at high temperature after application, heat resistance is also required to the substrate and the transparent electrode. Since normal transparent electrodes such as ITO does not have such heat resistance, it is required to use tin oxide doped with fluoride as a transparent electrode having excellent heat resistance. Since the tin oxide doped with fluoride is poor in conductivity, it is not suitable for such an application requiring a large surface area like a solar cell.

The present applicant has filed an application relating to an organic dye-sensitized metal oxide semiconductor membrane having a metal oxide semiconductor membrane having improved dye-adsorption property which can be easily formed at reduced temperature, and an organic dye-sensitized solar cell having the organic dye-sensitized metal oxide semiconductor membrane (JP 2001-314334A). This enables formation of an organic dye-sensitized metal oxide semiconductor membrane on a transparent electrode having excellent conductivity.

Therefore, the metal oxide semiconductor membranes of the third invention and the fourth invention are preferably metal oxide semiconductor membranes which have improved dye-adsorption property and can be easily formed at reduced temperature. That is, such a semiconductor membrane is generally formed by vapor deposition. The vapor deposition is preferably physical deposition, vacuum deposition, sputtering, ion plating, CVD, or plasma CVD. The vapor deposition is preferably a facing targets sputtering method; or a reactive spattering method. The metal oxide semiconductor membrane is made of titanium oxide, zinc oxide, tin oxide, antimony oxide, niobium oxide, tungsten oxide, indium oxide, or any of these metal oxides doped with other metal or other metal oxide. Among these, the metal oxide semiconductor membrane made of titanium oxide is preferable, the metal oxide semiconductor membrane made of anatase-type titanium dioxide is especially preferable. The thickness of the metal oxide semiconductor membrane is preferably 10 nm or more.

(5) Fifth Invention

(5-i) A method of forming a metal oxide semiconductor membrane of the present invention is characterized in that coating liquid in which metal oxide microparticles are dispersed in a binder is applied to a substrate having a transparent electrode on a surface thereof and is dried so as to form a metal oxide containing coating, and the metal oxide containing coating is subjected to ultraviolet irradiation treatment so as to remove the binder (organic binder), thereby forming a metal oxide semiconductor membrane having a large surface area.

In the above method, the wavelength of ultraviolet light to be used for the ultraviolet irradiation treatment is in a range of generally from 1 to 400 nm, preferably from 1 to 300 nm, especially preferably from 1 to 200 nm. Accordingly, the removal of the binder at reduced temperature can be conducted speedily. It is preferable that the ultraviolet irradiation treatment is conducted in the presence of gas of at least one selected from a group consisting of oxygen, fluorine atom containing compound (CF₄ or the like), and chlorine atom containing compound gases. This facilitates decomposition of the binder. The obtained metal oxide semiconductor membrane is preferably a membrane which is made of substantially only a metal oxide. This is because all of organic substances including the binder are removed. The metal oxide is preferably titanium oxide, zinc oxide, tin oxide, antimony oxide, niobium oxide, tungsten oxide, indium oxide, or any of these metal oxides doped with other metal or other metal oxide. The metal oxide is preferably titanium oxide, especially anatase-type titanium dioxide (in terms of light energy conversion efficiency). The primary particle diameter (mean primary particle diameter) of the metal oxide microparticles is preferably in a range of from 0.001 to 5 μm (facilitating the formation of membrane having high porosity). The obtained semiconductor membrane is generally made of the same material. The binder is generally an organic polymer (facilitating the plasma treatment). The thickness of the metal oxide semiconductor membrane is 10 nm or more (in terms of light energy conversion efficiency).

(5-ii) An organic dye-sensitized metal oxide semiconductor electrode of this invention is characterized by including a substrate having a transparent electrode on the surface thereof and a metal oxide semiconductor membrane formed on the transparent electrode which are obtained by the aforementioned method, and an organic dye adsorbed in the surface of the semiconductor membrane.

(5-iii) An organic dye-sensitized solar cell of this invention comprises the above organic dye-sensitized metal oxide semiconductor electrode, a counter electrode arranged at an opposed position to the organic dye-sensitized metal oxide semiconductor electrode, and a redox electrolyte filled between these electrodes.

(6) Sixth Invention

(6-i) A method of forming a transparent electrode of this invention being characterized in that coating liquid in which conductive metal oxide microparticles are dispersed in a binder is applied to a surface of a substrate and is dried so as to form a conductive metal oxide containing coating, the binder is then removed from the conductive metal oxide containing coating so as to form a coating-type transparent electrode membrane, and a conductive metal oxide is deposited on the coating-type transparent electrode membrane by vapor deposition so as to form a vapor deposition-type transparent electrode membrane, thereby providing a lamination-type transparent electrode.

(6-ii) A method of forming a transparent electrode of this invention being characterized in that a conductive metal oxide is deposited on a surface of a substrate so as to form a vapor deposition-type transparent electrode membrane by vapor deposition, coating liquid in which conductive metal oxide microparticles are dispersed in a binder is applied to the vapor deposition-type transparent electrode membrane and is dried so as to form a conductive metal oxide containing coating, and then the binder is removed from the conductive metal oxide containing coating so as to form a transparent electrode membrane, thereby providing a lamination-type transparent electrode.

The inventors of the present invention have focused on that a transparent electrode has a flat surface because it is formed by vapor deposition so that there is a limitation of formation of an oxide semiconductor membrane having large surface area on the flat surface. That is, the inventors have studied to increase the surface area of the transparent electrode surface by roughening the surface of the transparent electrode and, according to this, to improve the light energy conversion efficiency. In this manner, the inventors have reached to the present invention.

In both of the inventions (6-i) and (6-ii), there are double layer transparent electrode membranes formed by vapor deposition method and coating method, respectively. The inventions (6-i) and (6-ii) are different from each other in a point that the forming order is reverse. These both can provide an organic dye-sensitized metal oxide semiconductor electrode and an organic dye-sensitized solar cell having light energy conversion efficiency higher than ever before, by efficiently utilizing the coating-type transparent electrode membrane having large surface area which is obtained by removing the binder from the conductive metal oxide containing coating.

The binder is preferably removed by plasma treatment or ultraviolet irradiation treatment. It enables treatment at reduced temperature. The plasma treatment is preferably conducted with high-frequency plasma, microwave plasma, or a hybrid type thereof. The removal of the binder at reduced temperature can be conducted speedily. It is preferable that the plasma treatment is conducted in the presence of gas of at least one selected from a group consisting of oxygen, fluorine, and chlorine gases. This facilitates decomposition of the binder.

The wavelength of ultraviolet light to be used for the ultraviolet irradiation treatment is preferably in a range of from 1 to 400 nm. This enables quick treatment. The ultraviolet irradiation treatment is preferably conducted in the presence of gas of at least one selected from a group consisting of ozone, oxygen, fluorine atom containing compound and chlorine atom containing compound gases. This facilitates decomposition of the binder.

The conductive metal oxide (microparticles) to be used for coating is at least one of selected from a group consisting of In₂O₃: Sn(ITO), SnO₂:Sb, SnO₂:F, ZnO:Al, SnO₂, ZnO:F, and CdSnO₄. This provides high conductivity. The binder is generally an organic compound such as an organic polymer (especially, polyalkylene glycol).

The vapor deposition for forming the vapor deposition-type transparent electrode membrane is preferably physical deposition, vacuum deposition, sputtering, ion plating, CVD, or plasma CVD. The vapor deposition-type transparent electrode membrane is at least one of selected from a group consisting of In₂O₃:Sn(ITO), SnO₂:Sb, SnO₂:F, ZnO:Al, SnO₂, ZnO:F, and CdSnO₄.

The thickness of the vapor deposition-type transparent electrode membrane is preferably in a range of from 0.1 to 100 nm. The thickness of the coating-type transparent electrode membrane is preferably in a range of from 10 to 500 nm.

This invention also provides a transparent electrode substrate having a transparent electrode membrane which is formed on a substrate surface according to the aforementioned method of forming a transparent electrode membrane.

This invention also provides a method of forming a metal oxide semiconductor membrane including a step of forming a metal oxide semiconductor membrane on the transparent electrode of the aforementioned transparent electrode substrate by vapor deposition.

The vapor deposition is preferably physical deposition, vacuum deposition, sputtering, ion plating, CVD, or plasma CVD.

The metal oxide is preferably titanium oxide, zinc oxide, tin oxide, antimony oxide, niobium oxide, tungsten oxide, indium oxide, or any of these metal oxides doped with other metal or other metal oxide.

The metal oxide is preferably titanium oxide, especially anatase-type titanium dioxide (in terms of light energy conversion efficiency). The thickness of the metal oxide semiconductor membrane is 10 nm or more (in terms of light energy conversion efficiency).

(6-iii) An organic dye-sensitized metal oxide semiconductor electrode of this invention is characterized by including a substrate having a transparent electrode on the surface thereof and a metal oxide semiconductor membrane formed on the transparent electrode which are obtained by the aforementioned method, and an organic dye adsorbed in the surface of the semiconductor membrane.

(6-iv) An organic dye-sensitized solar cell of this invention is characterized by comprising the aforementioned organic dye-sensitized metal oxide semiconductor electrode, a counter electrode arranged at an opposed position to the organic dye-sensitized metal oxide semiconductor electrode, and a redox electrolyte filled between these electrodes.

### BRIEF DESCRIPTION OF THE DRAWINGS

FIG. 1 is a sectional view showing a general structure of a dye-sensitized solar cell;

FIG. 2 is a schematic diagram showing a netted structure of a three-dimensional continuous skeleton structure of a porous body according to an invention (1-ii);

FIG. 3 is a sectional view showing an embodiment of a electrode for dye-sensitized solar cells according to the second invention;

FIG. 4 is a sectional view showing an embodiment of a solar cell according to the third invention;

FIG. 5 is a sectional view showing another embodiment of the solar cell according to the third invention;

FIG. 6 is a sectional view showing an embodiment of a antireflective film according to the third invention;

FIG. 7 is a sectional view showing an embodiment of a solar cell according to the fourth invention;

FIG. 8 is a sectional view showing another embodiment of the solar cell according to the fourth invention;

FIG. 9 is a sectional view showing another embodiment of the solar cell according to the fourth invention;

FIG. 10 is a sectional view showing an example of a method of forming a metal oxide semiconductor membrane according to the fifth invention;

FIG. 11 is a sectional view showing an embodiment of a solar cell according to the fifth invention;

FIG. 12 is a schematic drawing for explaining an example of a method of forming a transparent electrode according to the sixth invention;

FIG. 13 is a schematic drawing for explaining another example of a method of forming a transparent electrode according to the sixth invention;

FIG. 14 is a sectional view showing an example of a plasma generator which is suitably used in the method of forming a transparent electrode membrane according to the sixth invention; and

FIG. 15 is a sectional view showing an embodiment of a solar cell according to the sixth invention.

### DETAILED DESCRIPTION

(1) Embodiments of electrolyte for dye-sensitized solar cells and embodiments of a dye-sensitized solar cell according to the first invention will be described in detail.

(1-i) In an electrolyte for dye-sensitized solar cells, as the rubber composition of vulcanized rubber carrying oxidation-reduction substance, natural rubbers (NR) and synthetic rubbers having a carbon-to-carbon double bond in its structural formula may be used alone or in a blended state of two or more. Exemplary synthetic rubbers include homopolymers of conjugated diene compounds such as isoprene, butadiene and chloroprene, for example, polyisoprene rubber (IR), polybutadiene rubber (BR), and polychloroprene rubber; copolymers of the aforementioned conjugated diene compounds with vinyl compounds such as styrene, acrylonitrile, vinylpyridine, acrylic acid, methacrylic acid, alkyl acrylates, and alkyl methacrylates, for example, styrene-butadiene copolymer rubber (SBR), vinylpyridine-butadiene-styrene copolymer rubber, acrylonitrile-butadiene copolymer rubber, acrylic acid-butadiene copolymer rubber, methacrylic acid-butadiene copolymer rubber, methyl acrylate-butadiene copolymer rubber, and methyl methacrylate-butadiene copolymer rubber; copolymers of olefins such as ethylene, propylene, and isobutylene with diene compounds (for example, isobutylene-isoprene copolymer rubber (IIR)); copolymers (EPDM) of olefins with unconjugated dienes (for example, ethylene-propylene-cyclopentadien-ternary copolymer, ethylene-propylene-5-ethylidene-2-norbornene ternary copolymer, and ethylene-propylene-1,4-hexadiene ternary copolymer); polyalkenamers resulting from ring-opening polymerization of cycloolefins (for example, polypentenamer); rubbers resulting from ring-opening polymerization of oxirane rings (for example, sulfur-vulcanizable polyepichlorohydrin rubber); and polypropylene oxide rubber. Also included are halogenated products of the foregoing various rubbers, for example, chlorinated isobutylene-isoprene copolymer rubbers (Cl-IIR) and brominated isobutylene-isoprene copolymer rubbers (Br-IIR). Ring-opened polymers of norbornene are also useful. Additionally, useful blended rubbers are blends of the foregoing rubbers with saturated elastomers such as epichlorohydrin rubber, polypropylene oxide rubber, and chlorosulfonated polyethylene.

The vulcanized rubber is manufactured by vulcanizing and cross-linking the rubber composition by vulcanizing agent. As the vulcanizing agent, sulfur, organic sulfur compounds, organic peroxide, or another cross-linking agent may be used. The vulcanizing agent is preferably used in an amount of from 0.01 to 10 parts, more preferably from 0.1 to 6 parts by weight per 100 parts by weight of the aforementioned rubber component.

For vulcanization, the rubber composition may also contain a vulcanization promoter, such as aldehyde ammonias, aldehyde amines, guanidines, thioureas, thiazoles, dithiocarbamates, xanthates, and thirams, preferably in an amount of from 0.01 to 10 parts, more preferably from 0.1 to 5 parts by weight per 100 parts by weight of the aforementioned rubber component. Further, the rubber composition may also contain a vulcanization promoter aid such as zinc flower and stearic acid, preferably in an amount of from 0.1 to 10 parts, more preferably from 0.5 to 5 parts by weight per 100 parts by weight of the aforementioned rubber component.

In the vulcanized rubber of (1-i), it is preferable to blend oil such as paraffinic, naphthenic and aromatic process oils, ethylene-α-olefin co-oligomers, mineral oils such as paraffin wax and liquid paraffin, and vegetable oils such as castor oil, cottonseed oil, linseed oil, colza oil, soybean oil, palm oil, coconut oil, and peanut oil. The addition of such oil is effective for improving workability of rubber. The amount of oil blended is preferably about 3 to 50 parts, especially about 4 to 10 parts by weight per 100 parts by weight of the rubber component.

In the vulcanized rubber of (1-i), a filler such as carbon black, silica, calcium carbonate, calcium sulfate, clay and mica may be added in accordance with a particular purpose and application according to the ordinary method. The amount of the filler(s) is preferably from 0.5 to 20 parts, more preferably from 1 to 10 parts by weight per 100 parts by weight of the rubber component.

The vulcanized rubber of (1-i) can be made by heating the rubber composition prepared by mixing the aforementioned components under pressure to achieve vulcanization.

Other than the vulcanization using sulfur vulcanizing agent, organic sulfur vulcanization using organic sulfur compounds such as dithiomorpholine and thiuram vulcanizing agents, heat cross-linking using an organic peroxide, ultraviolet cross-linking, or radiation-induced cross-linking may be employed. The vulcanization using sulfur vulcanizing agent is most preferable because the sulfur vulcanizing agent hardly reacts with iodine as oxidation-reduction substance. In this case, the content of sulfur or sulfur in organic sulfur compound is preferably 0.5 to 7 parts, especially 1 to 6 parts by weight per 100 parts by weight of the rubber component.

As the vulcanized rubber to be used in (1-i), a vulcanized rubber having, as side chains, an aromatic ring, for example, especially a benzene ring or a pyridine ring is preferably used in order to exhibit the effect of increasing the conductivity. Therefore, it is preferable to use a rubber component containing a copolymer component such as styrene or vinylpyridine in order to achieve introduction of such an aromatic ring.

The content of the aromatic ring such as a benzene ring or pyridine ring in the vulcanized rubber is preferably from 5 to 50% by weight relative to the entire rubber component. When the amount is less than 5% by weight, sufficient effect of improving conductivity can not be obtained. On the other hand, when the amount is more than 50% by weight, a hard and brittle membrane having poor toughness is formed.

In (1-i), an oxidation-reduction substance is carried by the vulcanized rubber. To carry oxidation-reduction substance on the vulcanized rubber, for example, the vulcanized rubber is soaked in a solution of the oxidation-reduction substance so that the vulcanized rubber is impregnated with the oxidation-reduction substance solution and, after that, is dried.

In an electrolyte for dye-sensitized solar cells of (1-ii), a high molecular material having a three-dimensional continuous network skeleton structure of a porous body which has a three-dimensional continuous network skeleton structure on which an oxidation-reduction substance is carried is preferably composed of ethylene-propylene copolymer.

The copolymer is an ethylene-propylene rubber (EPR) mainly consisting of ethylene and propylene. The content of ethylene is preferably 60% by weight or more. When the content of ethylene is less than 60% by weight, the high-molecular network skeleton structure has poor properties. When the content of ethylene is preferably 65% by weight or more, more preferably 70% by weight or more while the upper limit is preferably 95% by weight, especially 90% by weight. The three-dimensional continuous network skeleton preferably has both a rigid block portion of, for example, a crystal structure or an aggregate structure and a flexible block portion of, for example, an amorphous structure. The crystallinity of EPR is 3% or more, preferably 5% or more, most preferably 8% or more while the upper limit is preferably 60%, especially 50%. The melting point (Tm) of polyethylene portion exhibiting blocking property of ethylene is set to 25° C. or more, preferably 30° C. or more, more preferably 35° C. according to Differential scanning calorimetry (DSC). The number average molecular weight of the copolymer is 20000 or more, preferably 30000 or more, more preferably 40000 or more.

The aforementioned copolymer may contain a copolymer component other than ethylene or propylene, if necessary. Examples of the copolymer component include 1,5-hexadiene, 1,4-hexadiene, dicyclopentadiene, and ethylidene norbornene. EPDM may be made by blending one or more of such third components into ethylene and propylene. In this case, the content of the third component is from 1 to 15% by weight, preferably from 2 to 10% by weight of the entire copolymer.

In the three-dimensional continuous network skeleton according to (1-ii), it may be effective, according to a particular application, to change the properties of the aforementioned EPR, EPDM by introducing a hydrophilic group such as a hydroxyl group, a lyophilic group such as a nitro group into the EPR, EPDM to modify the EPR, EPDM.

The three-dimensional continuous network skeleton composed of the aforementioned copolymer has a micro structure as shown in FIG. 2. In FIG. 2, numeral 11 designates a three-dimensional continuous skeleton, 12 designates an opening (inner continuous cavity). An oxidation-reduction substance as will be described later is held inside the opening 12.

The average diameter d of the skeleton 11 is 8 μm or less, preferably from 0.5 to 5 μm. The average diameter D of the opening 12 is 80 μm or less, preferably from 1 to 50 μm. The opening ratio is 40% or more, preferably from 50 to 95%.

The porous body can be made by mixing a high molecular material such as the aforementioned ethylene-propylene copolymer and a low molecular material in an amount much more than the high molecular material under such a mixing condition that the high molecular material can form a three-dimensional continuous network skeleton structure so as to obtain a precursor in which the high molecular material forms a three-dimensional continuous network skeleton structure, and removing the low molecular material from the precursor. Concretely, a method using a high-speed agitator such as a high shearing mixing machine and setting the agitating speed to be 300 rpm or more, preferably 500 rpm or more, more preferably 1000 rpm or more. If the agitation is not conducted at high speed i.e. in case of low speed mixing using a roll mixer, a rotor mixer, or a cylinder mixer, it is difficult to obtain a uniform three-dimensional continuous network skeleton structure of a high molecular material such as ethylene-propylene copolymer as desired. The mixing temperature is from 100 to 250° C., preferably from 150 to 200° C., and the mixing time period is from 1 to 120 minutes, preferably from 2 to 90 minutes.

After the aforementioned mixing, cross-linking may be conducted by adding a vulcanizing agent such as sulfur or organic peroxide to the mixture or by irradiating the mixture with electron beam.

The low molecular material to be mixed with the high molecular material may be solid or liquid and various low molecular materials may be used according to the application. When the low molecular material is an organic material, the number average molecular weight of the low molecular material is less than 20,000, preferably 10,000 or less, more preferably 5,000 or less. There is no particular limitation of low molecular material, but examples are as follows.

Softeners: Mineral oils, vegetable oils and synthetic softeners for use in rubbers and resins. Exemplary mineral oils are aromatic, naphthenic, and paraffinic process oils. Exemplary vegetable oils are castor oil, cottonseed oil, linseed oil, rape oil, soybean oil, palm oil, coconut oil, peanut oil, haze tallow, pine oil, and olive oil.

Plasticizer: Ester plasticizers such as phthalate esters, phthalate mixed esters, aliphatic dibasic acid esters, glycol esters, fatty acid esters, phosphate esters, and stearate esters; epoxy plasticizers; other plasticizers for plastics; and plasticizers for NBR such as phthalates, adipates, sebacates, phosphates, polyethers, and polyesters.

Tackifier: Tackifiers including coumarone resins, coumarone-indene resins, phenol terpene resins, petroleum hydrocarbons, and rosin derivatives.

Oligomer: Oligomers including crown ether, fluorinated oligomers, Polybutene, xylene resin, chlorinated rubber, polyethylene wax, petroleum resin, rosin ester rubber, polyalkylene glycol diacrylates, liquid rubbers (e.g., polybutadiene, styrene-butadiene rubber, butadiene-acrylonitrile rubber, and polychloroprene), silicone oligomers, and poly-α-olefins.

Lubricant: Hydrocarbon lubricants such as paraffin and wax; fatty acid lubricants such as higher fatty acids and oxyfatty acids; fatty acid amide lubricants such as fatty acid amides and alkylene bisfatty acid amides; alcohol lubricants such as fatty acid lower alcohol esters, fatty acid polyhydric alcohol esters, fatty alcohols, polyhydric alcohols, polyglycols, and polyglycerols; metal soaps; and mixtures.

Other useful low molecular materials are latex, emulsion, liquid crystal, bitumen, clay, natural starch, saccharides, inorganic silicone oil, and phosphazenes. Also included are animal oils such as beef tallow, lard, horse tallow, chicken oil, and fish oil, honey, fruit juice, chocolate, milk products such as yogurt; organic solvents such as hydrocarbon, halogenated hydrocarbon, alcohol, phenol, ether, acetal, ketone, fatty acid, ester, nitrogen compound and sulfur compound solvents; various pharmaceutical components, soil modifiers, fertilizers, petroleum, water, and aqueous solutions. These materials may be used alone or in admixture.

Here, the mixing ratio of the high molecular material to the low molecular material will be described. Assuming that A is the amount of the high molecular material such as the aforementioned copolymer of which the three-dimensional continuous network is constructed and B is the amount of the low molecular material, the weight fraction of the high molecular material such as the copolymer represented by [A/(A+B)×100] is preferably 30% or less, more preferably from 7 to 25%.

The precursor thus prepared retains the aforementioned low molecular material in the three-dimensional continuous network skeleton (inner continuous cavities) of the three-dimensional continuous network skeleton structure formed by the high molecular material. The porous body of the present invention is prepared by removing the low molecular material, constituting the majority of the precursor, from the precursor.

There is no particular limitation on the method of removing the low molecular material. Exemplary suitable method is a method in which the low molecular material is dissolved in and extracted with a suitable solvent and, after that, the remaining solvent is volatilized and dried.

Any desired solvent may be used insofar as the high molecular material such as ethylene-propylene copolymer is insoluble or substantially insoluble, but the low molecular material and other components are well soluble in the solvent. Exemplary solvents include aromatic hydrocarbons such as xylene, toluene, and benzene, unsaturated aliphatic hydrocarbons such as hexene and pentene, saturated aliphatic hydrocarbons such as hexane and pentane, ketones such as acetone and methyl ethyl ketone, alcohols such as ethanol and butanol, chlorinated aliphatic hydrocarbons such as methylene chloride and chloroform, alicyclic hydrocarbons such as cyclohexanone, ethers such as dioxane and tetrahydrofuran, esters such as butyl acetate, water, alkaline and acidic aqueous solutions. These may be used alone or in admixture and can be used for carrying out one or more steps of extraction.

For dissolving and extracting the low molecular material with the solvent, it is suitable that the precursor of the high molecular material containing the low molecular material is formed in pieces or in a thin membrane and is then soaked in the aforementioned solvent so as to extract the low molecular material. In this regard, effective recovery of the low molecular material is desirable. If the low molecular material is liquid, it is recommended to compress the precursor by means of a roll or press or apply a physical force thereto by means of a suction pump, a vacuum pump, a centrifugal separator or an ultrasonic vibrator for taking out the majority of the low molecular material before dissolution and extraction with the solvent is carried out.

The porous body of three-dimensional continuous network skeleton structure resulting from the extraction step may be subject to post treatment for altering its characteristics. Using ultraviolet radiation, electron radiation, heat or the like, the polymer component can be cross-linked for enhancing thermal stability. By treating with surface active agents or coupling agents, gas etching, plasma treatment or sputtering treatment, the porous body can be altered in hydrophilic, hydrophobic, electrical, and optical properties as well as strength.

In (1-ii), an oxidation-reduction substance is carried in the cavities (inner continuous cavities) of the porous body thus obtained from which the low molecular material has been removed. To carry oxidation-reduction substance on the porous body, for example, the porous body is soaked in a solution of the oxidation-reduction substance so that the porous body is impregnated with the oxidation-reduction substance solution and, after that, is dried.

In an electrolyte for dye-sensitized solar cells of (1-iii), a phosphazene polymer carrying an oxidation-reduction substance is a phosphazene polymer prepared by polymerizing from several to several thousand phosphazene derivatives.

Exemplary phosphazene derivatives suitably used are chain phosphazene derivatives expressed by a following general formula (1) (hereinafter, sometimes referred to as “phosphazene derivatives (1)”) and cyclic phosphazene derivatives expressed by a following general formula (2) (hereinafter, sometimes referred to as “phosphazene derivatives (2)”).
(R¹)₃P═N—X (1)
(in the general formula (1), R¹ represents a monovalent substituent group or a halogen element. “X” represents an organic group containing at least one kind of element selected from a group consisting of carbon, silicon, germanium, tin, nitrogen, phosphorus, oxygen, and sulfur.)
(PNR²₂)ₙ (2)
(in the general formula (2), R² represents a monovalent substituent group or a halogen element. “n” represents a number from 2 to 14.)

There is no special limitation on the substituents groups R¹, R² in the general formulae so that any monovalent substituent group or halogen element may be used. Examples of the monovalent substituent groups include hydroxyl group, alkoxy group, phenoxy group, alkyl group, carboxyl group, acyl group, aryl group, amino group, and alkylthio group. Particularly preferable examples among these are alkoxy group, phenoxy group, and amino group. Suitable examples of the halogen element include fluorine, chlorine, and bromine. Particularly preferable examples among these are chlorine and fluorine. R¹ of the general formula (1) and R² of the general formula (2) may be substituent groups all of which are the same or some of which are different from the other.

Examples of the alkoxy groups of R¹ and R² include methoxy group, ethoxy group, propoxy group, and butoxy group, further allyloxy group containing double bond, alkoxy-substituted alkoxy groups such as methoxyethoxy group and methoxyethoxyethoxy group. Particularly preferable examples among these are ethoxy group and methoxyethxy group. The hydrogen elements in the substituents groups may be substituted by halogen elements as mentioned above. The substituents may contain a functional group such as hydroxyl, mercaptan, amine, carboxyl, and epoxy. The functional group is advantageously used to obtain a high molecular compound or a three-dimensional compound because the functional group provides its portions as reactive sites, thus enabling polymerization and cross-linking reaction.

Examples of the alkyl groups of R¹ and R² include methyl group, ethyl group, propyl group, butyl group, and pentyl group. Examples of the acyl groups include formyl group, acetyl group, propionyl group, butyryl group, isobutyryl group, and valeryl group. Examples of the aryl groups include phenyl group, tolyl group, and naphthyl group.

Examples of the amino groups include amino group, methylamino group, dimethylamino group, ethyl amino group, diethyl amino group, aziridyl group, and pyrrolidine group.

In the aforementioned general formula (1), it is preferable that “X” is an organic group containing at least one kind of element selected from a group consisting of carbon, silicon, nitrogen, phosphorus, oxygen, and sulfur and it is more preferable that “X” is an organic group having a structure expressed by following general formulae (3A), (3B):

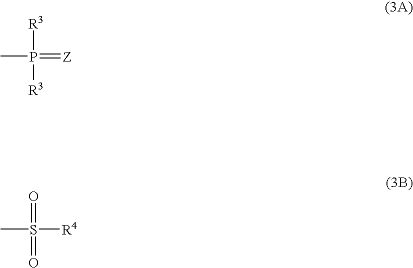

In the general formulae (3A), (3B), each of R³ and R⁴ represents a monovalent substituent group or a halogen element.

In general formulae (3A), (3B), the same monovalent substituent groups and halogen elements as mentioned above relating to R¹ and R² of the general formulae (1), (2) may be suitably used as R³ and R⁴. R³ may be the same or different from each other in the same organic group and may be bonded to each other to form a cycle. Examples of Z in the general formula (3A) include CH₂ group, CHR group (R represents alkyl group, alkoxyl group, phenyl group or the like. The same is true for the following description.), NR group, and groups containing elements such as oxygen, sulfur, selenium, boron, aluminum, scandium, gallium, yttrium, indium, lanthanum, thallium, carbon, silicon, titanium, tin, germanium, zirconium, lead, phosphorus, vanadium, arsenic, niobium, antimony, tantalum, bismuth, chromium, molybdenum, tellurium, polonium, tungsten, iron, cobalt, and nickel. Preferable examples among these are NR group, and groups containing elements of oxygen and sulfur.

Among organic groups expressed by the general formulae (3A), (3B), an organic group containing phosphorous expressed by the general formula (3A) is particularly preferable because such an organic group can effectively provide self-extinguishing property and flame retardancy. An organic group containing sulfur expressed by the general formula (3B) is also preferable in terms of reduction in interface resistance.

There is no special limitation on “n” in the aforementioned general formula (2) so that the “n” may be any of 2-14. Most preferable is n=3 in terms of stability and versatility (material is easily obtainable).

The phosphazene polymer is prepared by polymerizing the aforementioned phosphazene derivatives (1) or (2) by any of various methods. Generally, the phosphazene polymer is prepared by heating the phosphazene derivatives (1) or (2) to a temperature from 200 to 400° C. By adding an organic substance such as benzoic acid and/or an inorganic salt such as aluminum chloride as a catalyst in an amount of from 0.01% to 10% by weight relative to the phosphazene derivatives, the phosphazene polymer can be prepared at a lower temperature and for a shorter period of time. The polymerization can be achieved by using plasma or UV other than heat. The molecular skeleton of the phosphazene polymer thus obtained has basically a straight chain structure of —(N═PR₂)ₙ—. However, according to the polymerization condition, a phosphazene polymer of which the molecular skeleton has a ring shape or a three-dimensional shape is obtained.

It is also possible to prepare a phosphazene polymer by reaction of the phosphazene derivatives (1) or (2) by a coupling agent between molecules using substituents on phosphorous atoms. In this case, a phosphazene polymer of which molecular skeleton basically maintains a straight chain structure or a ring structure.

The phosphazene polymer used in (1-iii) is not limited to a polymer prepared by polymerizing phosphazene derivatives of one kind by means of the aforementioned polymerizing method and may be a copolymer prepared by copolymerizing phosphazene derivatives of two or more kinds. The phosphazene polymer may contain a component other than the phosphazene derivatives within a scope which does not damage the characteristics of the phosphazene polymer.

The phosphazene polymer obtained by polymerizing of the phosphazene derivatives preferably has 100,000 or more molecules. In case that the phosphazene polymer has less than 100,000 molecules, the strength should be poor so that the phosphazene polymer may be in a sole state rather than a gel state.

The phosphazene polymer used in (1-iii) preferably has substituent group containing halogen element in its molecular structure. In the phosphazene polymer having substituent group containing halogen elements in its molecular structure, the molecular structure enables an obtained electrolyte to have self-extinguishing property and flame retardancy by halogen gas induced from the aforementioned phosphazene polymer. A compound of which substituent group has halogen elements may have a problem of generation of halogen radial. However, since phosphorus elements in the molecular structure capture halogen radical so as to form a stable phosphorus halide the phosphazene polymer, the phosphazene polymer does not have such a problem.

The content of halogen elements in the phosphazene polymer is preferably from 2% to 80% by weight, more preferably from 2% to 60% by weight, still more preferably from 2% to 50% by weight. If the amount is less than 2% by weight, the effect by contained halogen can not be effectively obtained. On the other hand, if the amount exceeds 80% by weight, the function of the electrolyte thus obtained may be deteriorated. Examples to be suitably used as halogen elements are fluorine, chlorine, and bromine. Particularly preferable example among these is fluorine.

In (1-iii), an oxidation-reduction substance is carried by the phosphazene polymer thus obtained. To carry oxidation-reduction substance on the phosphazene polymer, for example, the phosphazene polymer is soaked in a solution of the oxidation-reduction substance so that the phosphazene polymer is impregnated with the oxidation-reduction substance solution and, after that, is dried.

In an electrolyte for dye-sensitized solar cells of (1-iv), an EVA resin composing an EVA resin film on which an oxidation-reduction substance is carried is preferably an EVA resin containing vinyl acetate in an amount of from 5% to 50% by weight, especially from 15% to 40% by weight. Less than 5% by weight of vinyl acetate interferes with the weatherability and the transparency, while exceeding 40% by weight of vinyl acetate significantly reduces mechanical characteristics, makes the film formation difficult, and produces a possibility of blocking between films.

It is preferable to add a cross-linking agent into an EVA resin composition as a material for forming an EVA resin film so that the obtained EVA resin film has a cross-linking structure for carrying the electrolyte and that the cross-linking agent can function as adhesives for integrating an upper electrode and a lower electrode in a solar cell structure.

As the cross-linking agent, in case of cross-linked by heating, organic peroxide is preferable. The organic peroxide is selected according to the temperature for sheet process, the temperature for cross-linking, and the storage stability. Examples of available peroxide include 2,5-dimethylhexane-2,5-dihydro peroxide; 2,5-dimethyl-2,5-di(t-butylperoxy)hexane-3; di-t-butyl peroxide; t-butylcumyl peroxide; 2,5-dimethyl-2,5-di(t-butylperoxy)hexane; dicumyl peroxide; α,α′-bis(t-butylperoxy isopropyl)benzene; n-butyl-4,4-bis (t-butylperoxy)-valerate; 2,2-bis(t-butylperoxy)butane; 1,1-bis (t-butylperoxy)cyclohexane; 1,1-bis(t-butylperoxy)-3,3,5-trimethylcyclohexane; t-butylperoxy benzoate; benzoyl peroxide; t-butyl peroxyacetate; 2,5-dimethyl-2,5-bis(t-butylperoxy)hexyne-3; 1,1-bis(t-butylperoxy)-3,3,5-trimethylcyclohexane; 1,1-bis (t-butylperoxy)cyclohexane; methyl ethyl ketone peroxide; 2,5-dimethylhexyl-2,5-bis-peroxy-benzoate; t-butyl-hydroperoxide; p-menthane hydroperoxide; p-chlorobenzoyl peroxide; t-butyl peroxyisobutyrate; hydroxyheptyl peroxide; and chlorohexanone peroxide. These are used alone or in mixed state, normally 10 parts by weight or less, preferably from 0.1 to 10 parts by weight per 100 parts by weight of EVA resin.

The organic peroxide is normally mixed to the EVA resin by an extruder or a roll mill or may be added to the EVA resin film by means of impregnation by dissolving the peroxide into organic solvent, plasticizer, or vinyl monomer.

In order to improve the properties of the EVA resin (mechanical strength, optical property, adhesive property, weatherability, blushing resistance, crosslinking rate, and the like), a compound containing acryloxy group or methacryloxy group and allyl group may be added into the EVA resin. Such a compound used for this purpose is usually acrylic acid or methacrylic acid derivative, for example, ester or amide thereof. Examples of ester residues include alkyl group such as methyl, ethyl, dodecyl, stearyl, and lauryl and, besides such alkyl group, cyclohexyl group, tetrahydrofurfuryl group, aminoethyl group, 2-hydroxyethyl group, 3-hydroxypropyl group, and 3-chloro-2-hydroxypropyl group. Ester with polyfunctional alcohol such as ethylene glycol, triethylene glycol, polyethylene glycol, trimetylolpropane, or pentaerythritol may be also employed. The typical amide is diacetone acrylamide. More concrete examples of such a compound include compounds containing polyfunctional ester such as acrylic ester or methacrylate ester such as trimetylolpropane, pentaerythritol and glycerin, or allyl group such as triallyl cyanurate, triallyl isocyanurate, diallyl phthalate, diallyl isophthalate, and diallyl maleate. These are used alone or in the mixed state, normally from 0.1 to 2 parts by weight, preferably from 0.5 to 5 parts by weight per 100 parts by weight of EVA resin.

When the EVA resin is crosslinked by light, photosensitizer is used instead of the above peroxide, in an amount of normally 10 parts by weight or less, preferably from 0.1 to 10 parts by weight per 100 parts by weight of EVA resin. In this case, examples of available photosensitizer include benzoin; benzophenone; benzoin methyl ether; benzoin ethyl ether; benzoin isopropyl ether; benzoin isobutyl ether; dibenzyl; 5-nitroacenaphthene; hexachlorocyclopentadiene; p-nitrodiphenyl; p-nitroaniline; 2,4,6-trinitroaniline; 1,2-benzanthraquinone; and 3-methyl-1,3-diaza-1,9-benzanthrone. These can be used either alone or in the mixed state.

In this case, silane coupling agent may be further used as adhesive accelerator. Examples of the silane coupling agent include vinyltriethoxysilane, vinyl-tris(α-methoxyethoxy)silane, γ-methacryloxypropyl trimethoxysilane, vinyltriacetoxysilane, γ-glycidoxypropyltrimetoxysilane, γ-glycidoxypropyltrietoxysilane, β-(3,4-epoxycyclohexyl) ethyltrimethoxysilane, γ-chloropropyl methoxysilane, vinyltrichlorosilane, γ-mercaptopropyl trimethoxysilane, γ-aminopropyl triethoxysilane, and N-β(aminoethyl)-γ-aminopropyl trimethoxysilane. These are used alone or in the mixed state, normally from 0.001 to 10 parts by weight, preferably from 0.001 to 5 parts by weight per 100 parts by weight of EVA resin.

Besides the aforementioned additives, the EVA resin film according to (1-iv) may contain, in small amounts, ultraviolet absorbing agent, infrared absorbing agent, age resistor, and/or paint processing aid. If necessary, it may contain, in suitable amounts, coloring agent such as dye and pigment for adjusting the color of a solar cell to be obtained, and filter such as carbon black, hydrophobic silica and calcium carbonate.

It is also effective that the EVA resin film according to (1-iv) is subjected to corona discharge process, low temperature plasma process, electron beam irradiation process, or ultraviolet irradiation process as measures of improving the adhesive property relative to a semiconductor electrode and counter electrode.

Since the thickness of the electrolyte in the dye-sensitized solar cell is normally in a range of from 10 nm to 2 mm, the EVA resin film according to (1-iv) is preferably formed to have a thickness in the same range. The EVA resin film can be manufactured by dissolving a material such as EVA resin into a solvent or the like and forming a film if the film is thin or by forming a film using a film extruding apparatus such as a T-die if the film is thick. In case of a thickness of from 50 μm to 2 mm, the film can be made by first mixing the EVA resin and the additives listed above, kneading them by an extruder or a roll, and after that, forming into a predetermined configuration by means of a film forming method such as calendaring, rolling, T-die extrusion, or inflation. During the film formation, embossing is provided if necessary. In case of a thickness of 0.1 mm or less, the film can be easily made by mixing the EVA resin and the additives listed above, diluting the mixture by a solvent or the like, and applying the diluted mixture using a roll coater, a die coater a knife coater, a micabar coater, a flow coater, a spray coater or the like.

The following methods may be used for making an EVA resin film carrying an oxidation-reduction substance.

(1) An oxidation-reduction substance is mixed into an EVA resin composition as the material of an EVA resin film together with a cross-linking agent and other additives relative to the EVA resin, and a film is made of the mixture according to an ordinary method, thereby obtaining the EVA resin film containing the oxidation-reduction substance.

(2) A formed EVA resin film is impregnated with an oxidation-reduction substance. For example, the EVA resin sheet is soaked in a solution of the oxidation-reduction substance so that the EVA resin film is impregnated with the oxidation-reduction substance solution and, after that, is dried.

In (1-i) through (1-iv), the oxidation-reduction substance to be carried by the vulcanized rubber, the porous body comprising a high molecular material having a three-dimensional continuous network skeleton structure, the phosphazene polymer, or the EVA resin film (hereinafter, these will be sometimes referred to as “carrier”) is not particularly limited and thus may be any which can be generally used in a buttery or a solar cell. Preferable examples of the oxidation-reduction substance include combinations of metal iodide and iodine such as LiI, NaI, KI, and CaI₂, or combinations of metal bromide and bromine such as LiBr, NaBr, KBr, and CaBr₂. Particularly preferable examples among these are combination of metal iodide and iodine.

The concentration of the oxidation-reduction substance in the oxidation-reduction substance solution to be used for impregnation into the carrier is preferably in a range of from 0.01 to 1 mol/liter, particularly from 0.05 to 0.5 mol/liter.

Examples of the solvent include carbonate compounds such as propylene carbonate, nitrile compounds such as acetonitrile, alcohols such as ethanol as well as water and aprotic polar substance. Particularly preferable examples among these are carbonate compounds and nitrile compounds.

When the carrier is soaked in such an oxidation-reduction substance solution, it requires about 5 hours for soaking. It is preferable to set the soaking temperature high because the oxidation-reduction substance solution is activated to speed up the soaking, thereby shortening the period of time for making the electrolyte. The soaking temperature is required to be set not to cause radical reaction and is concretely in a range of from 35° C. to 65° C.

The period of time for drying after the soaking is preferably in a range of from 0.5 to 1 hour.

In the electrolyte for dye-sensitized solar cells of the first invention thus obtained, the amount of the oxidation-reduction substance carried by the carrier is preferably 5% by weight or more because, when the amount of the oxidation-reduction substance carried by the carrier is too small, the function of the electrolyte should be poor. Since, when this amount is excessively large, the oxidation-reduction substance carried may bleed from the carrier, the strength of the carrier may be poor, and the carrier may be deteriorated, it is detrimental to handling during the cell assembly. Therefore, the amount of the oxidation-reduction substance carried by the vulcanized rubber, the phosphazene polymer, or the EVA resin film is normally preferably from 10% to 30% by weight. On the other hand, the amount of the oxidation-reduction substance carried by the porous body is normally preferably from 5% to 90% by weight.

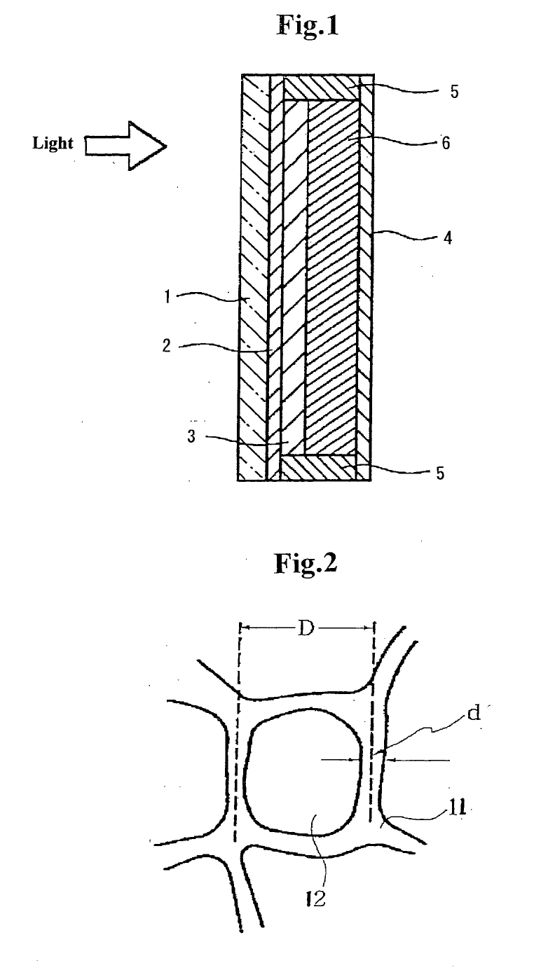

The dye-sensitized solar cell of the first invention uses, as its electrolyte, the electrolyte for dye-sensitized solar cells of the first invention. The structure other than the electrolyte of the dye-sensitized solar cell is the same as a conventional dye-sensitized solar cell as shown in FIG. 1.

As a substrate 1 for the dye-sensitized solar cell, normally a glass plate such as a silicate glass is normally used and any of various plastic substrates capable of ensuring optical transparency of a visible light may be also used. The thickness of the substrate is generally from 0.1 mm to 10 mm, preferably from 0.3 mm to 5 mm. As the glass plate, a glass plate which is chemically or thermally reinforced is preferable.

As a transparent electrode 2, a substrate with a thin membrane of conductive metal oxide such as In₂O₃ and SnO₂ or a substrate made of a conductive material such as metal may be employed. Examples of preferable conductive metal oxides include In₂O₃: Sn(ITO), SnO₂:Sb, SnO₂:F, ZnO:Al, ZnO:F, and CdSnO₄.

As a metal oxide semiconductor of a metal oxide semiconductor membrane 3 into which a spectral sensitizing dye is adsorbed, one or more of known semiconductors such as titanium oxide, zinc oxide, tungsten oxide, antimony oxide, niobium oxide, indium oxide, barium titanate, strontium titanate, and cadmium sulfide. Particularly, titanium oxide is preferable in terms of stability and safety. Exemplary titanium oxides include titanium oxides such as anatase-type titanium dioxide, rutile type titanium dioxide, amorphous titanium oxide, metatitanic acid, and orthotitanic acid, titanium hydroxide, and hydrous titanium oxide. In the present invention, particularly preferable example is anatase-type titanium dioxide. The metal oxide semiconductor membrane preferably has a fine crystal structure. It is also preferable that the metal oxide semiconductor membrane is porous. The thickness of the metal oxide semiconductor membrane is generally 10 nm or more, preferably from 100 to 1000 nm.

The organic dye (spectral sensitizing dye) to be adsorbed in the oxide semiconductor membrane may be one or more of various metal complexes and organic dyes having adsorptive property in visible light range and/or infrared light range. The spectral sensitizing dyes having functional groups such as carboxyl group, hydroxyalkyl group, hydroxyl group, sulfonic group, and carboxyalkyl group in their molecules are preferable because they are quickly adsorbed into semiconductors. The metal complexes are preferable because they are excellent in effect of spectral sensitization and durability. Examples which may be used as the metal complex are complexes of metal phtalocyanines such as copper phthalocyanine and titanyl phthalocyanine, chlorophyll, hemin, ruthenium described in JP H01-220380A or JP H05-504023A, osmium, iron, and zinc. Examples which may be used as the organic dye are metal-free phthalocyanine, cyanine dyes, merocyanine dyes, xanthene dyes, and triphenylmethane dyes. Specific examples of cyanine dyes include NK1194 and NK3422 (both available from Hayashibara Biochemical Laboratories, Inc.). Specific examples of merocyanine dyes include NK2426 and NK2501 (both available from Hayashibara Biochemical Laboratories, Inc.). Specific examples of xanthene dyes include Uranine, Eosine, rose Bengal, rhodamine B, and Dibromofluorescein. Specific examples of triphenylmethane dyes include malachite green and crystal violet.

To adsorb the organic dye (spectral sensitizing dye) to the semiconductor membrane, organic dye solution is prepared by dissolving the organic dye in organic solvent, and the oxide semiconductor membrane is soaked together with the substrate in the organic dye solution at ordinary temperature or under heated condition. The solvent of the organic solution may be any of solvents capable of dissolving the used spectral sensitizing dye. Specific examples of such a solvent include water, alcohol, toluene, and dimethylformamide.

The dye-sensitized semiconductor electrode is manufactured by applying a transparent electrode (transparent conductive membrane) 2 as a coating on the substrate 1, forming a semiconductor membrane for photoelectric conversion material on the transparent electrode 2, and adsorbing the dye to the semiconductor membrane. Another substrate such as a glass plate, which is coated with a transparent conductive membrane, as a counter electrode 4 is bonded to the dye-sensitized semiconductor electrode by sealing material 5. The electrolyte 6 of the first invention is encapsulated between the electrodes, thereby forming a solar cell of the present invention.

The thickness of the electrolyte depends on the specification of the dye-sensitized solar cell and is normally in a range of from 0.01 to 0.3 mm.

The counter electrode 4 may be any of conductive materials. It is preferable to use, as the counter electrode 4, a conductive material having catalytic power to conduct reductive reaction of oxidized redox ion such as I₃⁻ ion of the electrolyte at a sufficient high speed. Examples of such a conductive material include a platinum electrode, a conductive material having a platinized surface or a surface with platinum deposition, rhodium metal, ruthenium metal, ruthenium oxide, carbon, cobalt, nickel, and chromium.

Though the dye-sensitized semiconductor electrode, the electrolyte, and the counter electrode are housed in a casing and then sealed in the dye-sensitized solar cell of the first invention, these may be sealed entirely with resin. In this case, the resin sealing is designed so that the dye-sensitized semiconductor electrode is exposed to light. In the cell having such a structure, as sun light or visible light similar to the sun light is incident on the dye-sensitized semiconductor electrode, a potential difference is generated between the dye-sensitized semiconductor electrode and the counter electrode so that current flows between the electrodes.

### EXAMPLES OF THE FIRST INVENTION

### Example 1-1

[Production of Electrolyte]

A rubber composition consisting of the following components were heated at 150° C. under pressure of 10 MPa so as to obtain a vulcanized rubber.

<Rubber Composition (Parts)>

Rubber component (vinylpyridine rubber): 100
(20 wt % stylene, 20 wt % vinylpyridine, 60 wt % butadiene)
Sulfur: 2
Oil: 5
Vulcanization accelerator (Nocceller M): 2
Zinc flower: 3
Carbon black (SAF): 20

The obtained vulcanized rubber was cut into a piece of 5 mm×5 mm×0.1 mm. The piece was soaked in the following oxidation-reduction substance solution at a room temperature for 6 hours so that the vulcanized rubber was impregnated with the oxidation-reduction substance solution, thereby obtaining an electrolyte for dye-sensitized solar cells of the present invention. Before use, the electrolyte was dried in the atmosphere to evaporate a low boiling point solvent (acetonitrile and the like). The electrolyte was sandwiched between electrodes while viscosity remains on the rubber surface.

[Oxidation-Reduction Substance Solution]

Solvent:acetonitrile:1 L
Oxidation-reduction substance
Lithium iodide: 0.2 mole
1,2 dimethyl-3-propylimidazolium iodide: 0.2 mole
Iodine: 0.1 mole
t-butylpyridine: 0.4 mole

The amount of the oxidation-reduction substance carried by the vulcanized rubber was 15% by weight.

[Production of Dye-Sensitized Solar Cell]

An ITO membrane having a thickness of 3000 Å was formed on a glass substrate (thickness: 2 mm) of 2.5×3 cm. A titanium oxide thin membrane having a thickness of 10 m and an area of 5 mm×5 mm was formed on the ITO membrane.

A solution was prepared by dissolving cis-di(thiocyanato)-bis (2,2+-bipyridyl-4-dicarboxylate-4′-tetrabutylammonium carboxylate) ruthenium(II) as spectral sensitizing dye into ethanol solvent at a rate of 3×10⁻⁴ mole/L. The substrate having the titanium oxide membrane formed thereon was entered into the solution and was soaked at a room temperature for 18 hours, thereby obtaining a dye-sensitized semiconductor electrode. The adsorptive amount of the spectral sensitizing dye was 10 μg per cm² specific area of the titanium oxide membrane.

As a counter electrode, a transparent conductive glass plate coated with fluorine-doped tin oxide and carrying platinum thereon was used. The aforementioned electrolyte was sandwiched between the two electrodes. The sides of the lamination were sealed by resin and lead wires were attached, thereby producing a dye-sensitized solar cell of the present invention.

As light with intensity of 100 W/m² was incident on the obtained dye-sensitized solar cell by a solar simulator, Voc (voltage in open-circuit) was 0.72V, Jsc (density of current flowing in short-circuit) was 9.5 mA/cm², FF (fill factor) was 0.52, η(conversion efficiency) was 4.5%. From the results, it was confirmed that the dye-sensitized solar cell is useful.

### Example 1-2

Ethylene-propylene copolymer (10% by weight) having a number average molecular weight shown in Table 1 and di-isodecyl adipate (DIDA) (90% by weight) were mixed by a high shearing-type mixing machine under the agitating condition shown in Table 1 to obtain a precursor. As for the obtained precursor, the average diameter d of the skeleton and the average diameter D of the opening were measured. Then, the DIDA was dissolved and extracted by acetone, thereby obtaining a porous body of a three-dimensional continuous network skeleton structure. The average diameter d of the skeleton and the average diameter D of opening of the porous body were measured. The results are also shown in Table 1.

TABLE 1

| EPR copolymer | Content of ethylene (% by weight) | 78 |
|---|---|---|
| | Crystallinity (%) | 12 |
| | Tm (° C.) | 48 |
| | Number average molecular weight | 250,000 |
| Low molecular material | | DIDA |
| Weight fraction of EPR copolymer (% by weight) | | 10 |
| Agitating condition | Temperature (° C.) | 180 |
| | Speed of rotation (rpm) | 3000 |
| Precursor | Average diameter of skeleton (μm) | 1-2 |
| | Average diameter of opening (μm) | 10-20 |
| Porous body | Average diameter of skeleton (μm) | 1-2 |
| | Average diameter of opening (μm) | 10-20 |

The obtained porous body was cut into a piece of 5 mm×5 mm×0.2 mm. The piece was soaked in the same oxidation-reduction substance solution as used in Example 1-1 at 25° C. for 5 hours so that the porous body was impregnated with the oxidation-reduction substance solution, thereby obtaining an electrolyte for dye-sensitized solar cells of the present invention. Before use, the electrolyte was dried in the atmosphere to evaporate a low boiling point solvent (acetonitrile and the like). The electrolyte was sandwiched between electrodes while viscosity remains on the porous body surface.

The amount of the oxidation-reduction substance carried by the porous body was 20% by weight.

A dye-sensitized solar cell was produced by using the electrolyte for dye-sensitized solar cells in the same manner as Example 1-1. As light with intensity of 100 W/m² was incident on the obtained dye-sensitized solar cell by a solar simulator, Voc (voltage in open-circuit) was 0.72V, Jsc (density of current flowing in short-circuit) was 9.2 mA/cm², FF (fill factor) was 0.51, η(conversion efficiency) was 4.2%. From the results, it was confirmed that the dye-sensitized solar cell is useful.

### Example 1-3

Phosphazene derivatives expressed by the aforementioned general formula (1) wherein R¹═Cl and the general formula (3A) wherein R³═OC₂H₅ and Z═O and p-phenylenediamine of 50% relative to the phosphazene derivatives were heated at 250° C. for 8 hours in an autoclave, thereby obtaining a rubber-like phosphazene polymer. The polymer was subjected to Soxhlet extraction for 6 hours by using toluene solution so as to remove unreacted substances and impure substances. The molecular weight measurement of tetrahydrofuran extractive in the polymer was conducted and the number average molecular weight was 140,000. After the obtained phosphazene polymer was dried in vacuo at 80° C. for 6 hours, the dried phosphazene polymer was cut into a piece of 5 mm×5 mm×0.2 mm. The piece was soaked in the same oxidation-reduction substance solution as used in Example 1-1 at 30° C. for 5 hours so that the phosphazene polymer was impregnated with the oxidation-reduction substance solution, thereby obtaining an electrolyte for dye-sensitized solar cells of the present invention. Before use, the electrolyte was dried in the atmosphere to evaporate a low boiling point solvent (acetonitrile and the like). The electrolyte was sandwiched between electrodes while viscosity remains on the phosphazene polymer surface.

The amount of the oxidation-reduction substance carried by the phosphazene polymer was 18% by weight.

A dye-sensitized solar cell was produced by using the electrolyte for dye-sensitized solar cells in the same manner as Example 1-1. As light with intensity of 100 W/m² was incident on the obtained dye-sensitized solar cell by a solar simulator, Voc (voltage in open-circuit) was 0.70V, Jsc (density of current flowing in short-circuit) was 8.8 mA/cm², FF (fill factor) was 0.65, η(conversion efficiency) was 4.0%. From the results, it was confirmed that the dye-sensitized solar cell is useful.

[Evaluation of Self-Extinguishing Property, Flame Retardancy, and Incombustibility]

As for the electrolyte for dye-sensitized solar cells using the phosphazene polymer, burning behavior of fire ignited in the air environment was observed and evaluated according to an altered method of UL94HB method of UL (Underwriters Laboratories) standard. Concretely, according to the UL test standard, the electrolyte for dye-sensitized solar cells was evaluated as follows.

(Evaluation of Incombustibility)

In case that the test piece is not fired by test fire (burning length: 0 mm), it is evaluated that the electrolyte has incombustibility.

(Evaluation of Flame Retardancy)

In case that the test piece is fired, the fire does not reach 25 mm line of an apparatus, and no dropping from network is fired, it was evaluated that the electrolyte has flame retardancy.

(Evaluation of Self-Extinguishing Property)

In case that the test piece is fired, the fire is extinguished between 25 mm line and 100 mm line of the apparatus, and no dropping from network is fired, it is evaluated that the electrolyte has self-extinguishing property.

(Evaluation of Flammability)

In case that the test piece is fired and the fire exceeds 100 mm line, it is evaluated that the electrolyte is flammable.

According to the aforementioned evaluation, the electrolyte had flame retardancy. On the other hand, a solar cell was produced only using electrolysis solution not using the phosphazene polymer and the same test was conducted for this solar cell. The result showed that it was flammable.

### Example 1-4

Phosphazene derivatives expressed by the aforementioned general formula (2) wherein n=3 and three of six R² of the derivatives were —OC₂H₅ and other three were —NH₂ were prepared. Aluminum chloride of 0.5% (relative to the phosphazene derivatives) and 2,2,3,3-tetrafluoro-1,4-butanediol of 20% were added to the phosphazene derivatives and they were heated at 300° C. for 20 hours in an autoclave, thereby obtaining a rubber-like phosphazene polymer. The polymer was insoluble to tetrahydrofuran solvent. The polymer was subjected to Soxhlet extraction for 6 hours by using tetrahydrofuran solvent so as to remove unreacted substances and impure substances from the polymer. After the obtained phosphazene polymer was dried in vacuo at 80° C. for 6 hours, an electrolyte for dye-sensitized solar cells was obtained by the same process as Example 1-3. Further, oxidation-reduction substance solution treatment was conducted, and a dye-sensitized solar cell was produced in the same manner as Example 1-3.

As light with intensity of 100 W/m² was incident on the obtained dye-sensitized solar cell by a solar simulator, Voc (voltage in open-circuit) was 0.68V, Jsc (density of current flowing in short-circuit) was 9.1 mA/cm², FF (fill factor) was 0.68, η(conversion efficiency) was 4.2%. From the results, it was confirmed that the dye-sensitized solar cell is useful.

In addition, as evaluation of incombustibility was conducted in the same manner as Example 1-3, it was confirmed that it has flame retardancy.

### Example 1-5

Phosphazene derivatives expressed by the aforementioned general formula (2) wherein n=3 and three of six R² of the derivatives were —OCH₂CH₂O(O)C—CH═CH₂ and other three were F were prepared. Benzoyl peroxide of 1% was added to the phosphazene derivatives and they were heated at 220° C. for 8 hours, thereby obtaining a resin-like phosphazene polymer. The polymer was insoluble to tetrahydrofuran solvent. An electrolyte for dye-sensitized solar cells was obtained from the obtained phosphazene polymer by the same process as Example 1-3. Further, oxidation-reduction substance solution treatment was conducted and a dye-sensitized solar cell was produced in the same manner as Example 1-3.

As light with intensity of 100 W/m² was incident on the obtained dye-sensitized solar cell by a solar simulator, Voc (voltage in open-circuit) was 0.71V, Jsc (density of current flowing in short-circuit) was 8.9 mA/cm², FF (fill factor) was 0.65, η(conversion efficiency) was 4.1%. From the results, it was confirmed that the dye-sensitized solar cell is useful.

In addition, as evaluation of incombustibility was conducted in the same manner as Example 1-3, it was confirmed that it has self-extinguishing property.

### Example 1-6

An EVA resin film having a thickness of 0.2 mm was obtained by forming EVA resin composition consisting of the following components by a calendar machine.

<EVA Resin Composition (Parts)>

EVA resin: 100
Organic peroxide (dicumyl peroxide): 2
Trimethylolpropane triacrylate: 5

The obtained EVA resin film was cut into a piece of 5 mm×5 mm. The piece was soaked in the same oxidation-reduction substance solution as used in Example 1-1 at 30° C. for 5 hours so that the film was impregnated with the oxidation-reduction substance solution, thereby obtaining an electrolyte for dye-sensitized solar cells of the present invention. Before use, the electrolyte was dried in the atmosphere to evaporate a low boiling point solvent (acetonitrile and the like). The electrolyte was sandwiched between electrodes while viscosity remains on the EVA resin film surface.

The amount of the oxidation-reduction substance carried by the EVA resin film was 18% by weight.

A dye-sensitized semiconductor electrode was produced using the electrolyte for dye-sensitized solar cells in the same manner as Example 1-1. As a counter electrode, a transparent conductive glass plate coated with fluorine-doped tin oxide and carrying platinum thereon was used. The aforementioned electrolyte was sandwiched between the dye-sensitized semiconductor electrode and the counter electrode and heated under pressure to crosslink and harden the EVA resin. The sides of the lamination were sealed by resin and lead wires were attached, thereby producing a dye-sensitized solar cell of the present invention.

As light with intensity of 100 W/m² was incident on the obtained dye-sensitized solar cell by a solar simulator, Voc (voltage in open-circuit) was 0.72 V, Jsc (density of current flowing in short-circuit) was 8.8 mA/cm², FF (fill factor) was 0.51, η(conversion efficiency) was 4.0%. From the results, it was confirmed that the dye-sensitized solar cell is useful.

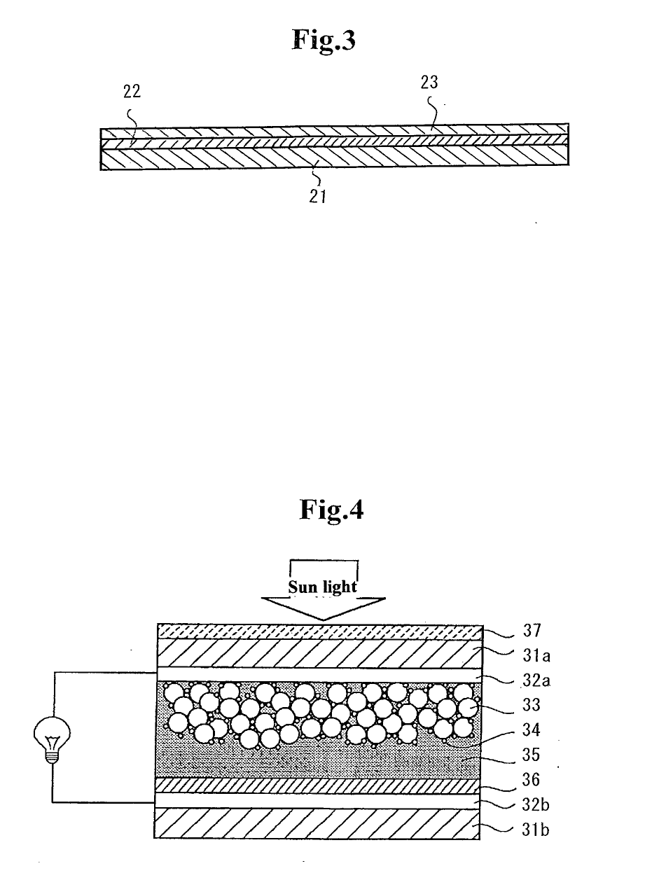

(2) Embodiments of electrode for dye-sensitized solar cells and embodiments of a method for producing the same according to the second invention will be described with reference to FIG. 3.

As shown in FIG. 3, an electrode for dye-sensitized solar cells comprises a substrate such as polyethylene terephthalate (PET) film 21 and a dye-adsorbed titanium oxide thin membrane 23 which is formed on the substrate via a transparent conductive thin membrane 22. The titanium oxide thin membrane of the dye-adsorbed titanium oxide thin membrane 23 is formed by reactive sputtering using Ti metal target.

Though glass may be used as the substrate as is conventionally done, an organic resin film is preferably used in order to achieve reduction in thickness, weight, and cost. Examples of such an organic resin film include films of polyester, polyethylene terephtalate (PET), polybutylene terephtalate, polymethyl methacrylate (PMMA), acrylic resin, polycarbonate (PC), polystyrene, triacetate (TAC), polyvinyl alcohol, polyvinyl chloride, polyvinylidene chloride, polyethylene, ethylene-vinyl acetate copolymers, polyvinyl butyral, metal ion-crosslinked ethylene-methacrylic acid copolymers, polyurethane, and cellophane. Particularly preferable is PET, PC, PMMA, or TAC film because of its high strength, and more particularly preferable is PET or TAC film.

The thickness of such an organic resin film is normally from 50 to 300 μm. When the thickness of the organic resin film is less than 25 μm, the organic resin film may not have enough durability as an electrode for dye-sensitized solar cells. When the thickness exceeds 1000 μm, the obtained electrode becomes unfavorably thick.

The transparent conductive thin membrane 22 formed on the organic resin film such as the PET film 21 may be a transparent conductive thin membrane of ITO (indium oxide and tin oxide), IZO (indium oxide and zinc oxide), ATO (alumina-doped tin oxide), or AZO (antimony-doped zinc oxide). The thickness of the transparent conductive thin membrane 22 is normally from 20 to 2000 μm. The transparent conductive thin membrane 22 is normally formed by sputtering.

Therefore, in the second invention, the transparent conductive thin membrane 22 and a titanium oxide thin membrane on the transparent conductive thin membrane 22 can be continuously formed in the same sputtering device.

In the second invention, the titanium oxide thin membrane is formed on the transparent conductive thin membrane 22 by reactive sputtering using a Ti metal target. The reactive sputtering is preferable because it achieves high-speed formation of a titanium oxide thin membrane by controlling the oxygen concentration in atmosphere such that oxygen is slightly insufficient for the film formation condition of TiO₂ thin membrane.

The oxygen concentration in atmosphere varies depending on the sputtering conditions such as total pressure in a chamber and exhaust velocity, so it is difficult to define the preferable oxygen concentration. It is preferable that the titanium oxide thin membrane to be formed is a thin membrane containing lower oxide of Ti represented by TiOₓ (x<2), especially TiOₓ (x<1.98) because the film formation of which speed is 5-6 time higher than that of the film formation of TiO₂ thin membrane can be conducted.

When the x of TiOₓ is excessively low, the semiconductor characteristics of TiO₂ become impaired, TiOₓ (1.7≦x) is preferable.

The control of oxygen concentration in atmosphere to be insufficient can be easily conducted by plasma emission control or plasma impedance control.

To form a titanium oxide thin membrane, it is preferable to use a dual cathode system to conduct the reactive sputtering, that is, that i metal targets are set to two cathodes arranged in parallel and voltage is applied alternately. This further speeds up the film formation.

Though there is no special limitation on the reactive sputtering condition, the following condition is preferable.
Pressure: 0.2-5 Pa
Atmosphere: Ar+O₂, flow ratio of O₂: 3-50%

In case of employing the dual cathode system, alternate voltage applying frequency is preferably from 10 to 100 kHz.

The thickness of the titanium oxide thin membrane thus formed is normally in a range from 0.5 to 10 μm. When the thin membrane is thinner than this range, the amount of sensitizing dye to be adsorbed becomes small so that the effect of generating power by light adsorption should be poor. When the thin membrane is thicker than this range, the electric resistance of the titanium oxide thin membrane becomes high so as to deteriorate the capability as an electrode.

The sensitizing dye to be adsorbed in the titanium oxide thin membrane thus formed may be any of dyes having adsorption property in a visible light range and/or infrared light range. That is, there is no special limitation on available sensitizing dye so that a metal complex or an organic dye may be used as the sensitizing dye. Examples of metal complexes include metal phthalocyanine such as copper phthalocyanine and titanyl phthalocyanine, chlorophyll and its derivertives, complexes of metal such as hemin, ruthenium, osmium, iron, and zinc (for example, cis-di cyanato-bis(2,2′-bipyridyl-4-dicarboxylate) ruthenium(II)). Examples of the organic dye include metal-free phthalocyanine, cyanine dye, methalocyanine dye, xanthene dye, and triphenylmethane dye.

Any of these sensitizing dyes can be adsorbed in the titanium oxide thin membrane by soaking the substrate on which the titanium oxide thin membrane is formed into solution containing the sensitizing dye.

Since an organic resin film can be employed as the substrate in the electrode for dye-sensitized solar cells of the second invention, it is possible to achieve reduction in thickness, weight, and cost of the electrode. By using this electrode to manufacture a dye-sensitized solar cell, it is possible to achieve reduction in thickness, weight, and cost of the dye-sensitized solar cell.

### EXAMPLES OF THE SECOND INVENTION

### Examples 2-1 through 2-3

A PET film having a thickness of 188 μm was used as the substrate. An ITO transparent conductive membrane having a thickness of 500 nm was formed on one surface of the PET film by sputtering method. Then, a titanium oxide thin membrane having a thickness of 3 μm was formed under the following condition by reactive sputtering using a Ti metal target. The reactive sputtering was conducted by setting the Ti metal target to a single cathode system of a magnetron DC sputtering apparatus.

[Condition of Reactive Sputtering]

Pressure: 0.5 Pa
Power: 2 kw

During the reactive sputtering, the flow ratio of O₂ in Ar+O₂ atmosphere was controlled to have a value shown in Table 2 by plasma emission control or plasma impedance control. The oxidation degree of the obtained titanium oxide thin membrane was shown in Table 2.

The film formation speed (the thickness of thin membrane formed per unit time) was measured. The result is shown in Table 2.

### Examples 2-4 through 2-6

A titanium oxide thin membrane was formed in the same manner as that of Examples 2-1 through 2-3 except that Ti metal targets were set to two cathodes of a dual cathode system of a magnetron DC sputtering apparatus. The oxidation degree of the obtained titanium oxide thin membrane and the film formation speed were measured. The results are shown in Table 2.

[Condition of Reactive Sputtering]

Pressure: 0.5 Pa
Power: 10 kw

Voltage applying frequency to dual cathode: 50 kHz

TABLE 2

| | | Flow ratio | | Film |
|---|---|---|---|---|
| | Kind of | of O₂ in | Oxidation degree of | formation |
| | cathode | atmosphere | titanium oxide thin | speed |
| Example | system | (%) | membrane | (nm/min) |
| 2-1 | single | 30 | TiO₂ | 20 |
| 2-2 | single | 10 | TiO_{1.9} | 60 |
| 2-3 | single | 5 | TiO_{1.8} | 150 |
| 2-4 | dual | 30 | TiO₂ | 80 |
| 2-5 | dual | 15 | TiO_{1.9} | 250 |
| 2-6 | dual | 8 | TiO_{1.8} | 600 |

It was found from Table 2 that the reactive sputtering with slightly insufficient oxygen, preferably the reactive sputtering using a dual cathode system, enables high-speed film formation.

An N3 dye as a sensitizing dye was adsorbed in a PET film, on which any one of the titanium oxide thin membranes of Examples 2-1 through 2-6 was formed, by soaking the film into acetonitrile solution of N3 dye, thus producing an electrode. The electrode was used to assemble a dye-sensitized solar cell by an ordinary method. The obtained dye-sensitized solar cell had an effect of generating power equal to that of a conventional one.

(3) Embodiments of an organic dye-sensitized solar cell having a metal oxide semiconductor electrode according to the third invention will be described with reference to drawings.

FIG. 4 is a sectional view of an embodiment of the organic dye-sensitized solar cell of the third invention.

In FIG. 4, an organic dye-sensitized solar cell comprises a glass substrate 31a, a transparent electrode 32a formed on a surface of the glass substrate 31a, a metal oxide semiconductor membrane 33 with spectral sensitizing dye 34 adsorbed therein formed on a surface of the transparent electrode 32a, and a counter electrode 36 (e.g. Pt electrode) formed beneath the metal oxide semiconductor membrane 33. The counter electrode 36 is arranged at an opposed position to the transparent electrode. The counter electrode 36 is formed on a transparent electrode 32b formed on a glass substrate 31b. An electrolyte (solution) 35 is encapsulated between the metal oxide semiconductor membrane 33 and the counter electrode 36. Further, an antireflective membrane 37 is formed on the glass substrate 3 la.

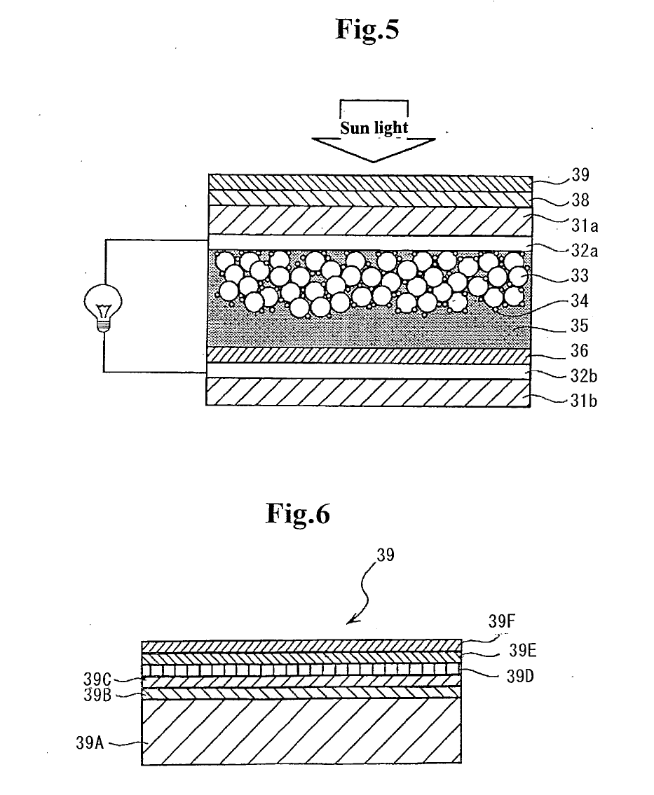

FIG. 5 is a sectional view of an embodiment of the organic dye-sensitized solar cell of the third invention.

In FIG. 5, an organic dye-sensitized solar cell comprises a glass substrate 31a, a transparent electrode 32a formed on a surface of the glass substrate 31a, a metal oxide semiconductor membrane 33 with spectral sensitizing dye 34 adsorbed therein formed on a surface of the transparent electrode 32a, and a counter electrode 36 (e.g. Pt electrode) formed beneath the metal oxide semiconductor membrane 33. The counter electrode 36 is arranged at an opposed position to the transparent electrode. The counter electrode 36 is formed on a transparent electrode 32b formed on a glass substrate 31b. An electrolyte 35 is encapsulated between the metal oxide semiconductor membrane 33 and the counter electrode 36. Further, an antireflective film 39 is attached to the glass substrate 31a via an adhesive layer 38.

In organic dye-sensitized solar cell using organic dye-sensitized metal oxide semiconductor membrane, various studies have been made about the semiconductor membrane and the dye in order to make its properties to practical use level. However, no or little attention has been given to studies for finding a way of utilizing a solar energy itself at high efficiency. The present inventors have studied on this point. That is, by providing an antireflective membrane or an antireflective film on a glass substrate of an organic dye-sensitized solar cell, efficient acceptance of solar energy is achieved. Particularly in case of providing the antireflective film, scattering of glass pieces of the solar cell when the glass substrate is broken can be prevented.

The antireflective film comprises a transparent polymer film and an antireflective membrane formed on the transparent polymer film. The antireflective membrane is generally:
(1) an inorganic laminated membrane consisting of, in top-to-bottom order, low-refractive transparent inorganic thin membrane(s) and high-refractive transparent inorganic thin membrane(s) which are alternately laminated; or
(2) an inorganic laminated membrane consisting of low-refractive transparent inorganic thin membrane(s) and high-refractive transparent inorganic thin membrane(s) which are alternately laminated, wherein the upper-most low-refractive transparent inorganic thin membrane is a low-refractive organic thin membrane.

Examples of the antireflective membrane include:
(a) a lamination consisting of a moderate (or low)-refractive transparent inorganic thin membrane and a high-refractive transparent inorganic thin membrane, i.e. two layers in amount, which are laminated in this order;
(b) a lamination consisting of a moderate (or low)-refractive transparent inorganic thin membrane, a low-refractive transparent inorganic thin membrane, and a high-refractive transparent inorganic thin membrane, i.e. three layers in amount, which are laminated in this order; and
(c) a lamination consisting of a low-refractive transparent inorganic thin membrane, a high-refractive transparent inorganic thin membrane, a low-refractive transparent inorganic thin membrane, and a high-refractive transparent inorganic thin membrane, i.e. four layers in amount, which are laminated in this order.
   The number of inorganic thin membranes is generally from 2 to 6.

In the above (2), the formation of an (fluorinated or non-fluorinated) organic thin membrane imparts antifouling function in addition to antireflective function. That is, since an organic thin membrane is excellent in antifouling property, antifouling function can be imparted when the organic thin membrane is formed on the front-most surface. In (2), the transparent inorganic thin membrane just below the organic thin membrane is a high-refractive transparent inorganic thin membrane. By forming a low-refractive organic thin membrane on the high-refractive transparent thin membrane, high-performance antireflective function by lamination of a high-refractive transparent inorganic thin membrane and a low-refractive transparent thin membrane can be obtained. By forming a lamination of transparent inorganic thin membranes just below the organic thin membrane, interferential action of light by a lamination of a high-refractive transparent inorganic thin membrane and a low-refractive transparent inorganic thin membrane effectively prevent reflection of light, thereby achieving an antireflective film which is excellent in light transmittance and has high transparency and good color tone.

FIG. 6 is a sectional view schematically showing an example of the antireflective film 39 of the third invention.

The antireflective film 39 of the third invention includes a transparent polymer film 39A and comprises an ultraviolet protection layer 39B, a high-refractive transparent inorganic thin membrane 39C, a low-refractive transparent inorganic thin membrane 39D, a high-refractive transparent inorganic thin membrane 39E, and a low-refractive transparent inorganic thin membrane 39F which are formed on the transparent polymer film 39A in this order. The inorganic thin membranes 39C through 39F compose an antireflective membrane. The antireflective film may not employ the ultraviolet protection layer 39B and, instead of this, may employ an under coating layer or a hard coating layer.

Use of the antireflective membrane in the form of an antireflective film provides advantage of improving productivity.

Examples of the aforementioned transparent polymer film 39A include polyester, polyethylene terephtalate (PET), polybutylene terephtalate, polymethyl methacrylate (PMMA), acrylic resin, polycarbonate (PC), polystyrene, triacetate, polyvinyl alcohol, polyvinyl chloride, polyvinylidene chloride, polyethylene, ethylene-vinyl acetate copolymers, polyurethane, and cellophane. Particularly preferable are transparent films of PET, PC, PMMA.

The thickness of the transparent polymer film 39B is suitably determined according to the desired characteristics (for example, strength, thinness) and is usually in a range of from 1 μm to 10 mm.

The ultraviolet protection layer is formed on the transparent polymer film 39A as mentioned above. The ultraviolet protection layer is generally a hard coating layer containing an ultraviolet absorber (e.g. 2-hydroxybenzophenone). There is no special limitation on material of the hard coating layer. The material of the hard coating layer may acrylic resin having multifunctional group (in general, polymerizable group) or silicon resin having multifunctional group. These resins are preferably cross-linked by heat, light, or electron beam. In case of using light, an UV cure resin is employed.

As the high-refractive transparent inorganic thin membrane 39C or 39E, a thin membrane having refractive index of 1.8 or more made of ITO (indium tin oxide), ZnO, Al-doped ZnO, Al-doped TiO₂, Al-doped SnO₂, or ZrO can be used.

On the other hand, as the low-refractive transparent 15 inorganic thin membrane 39D or 39F, a thin membrane having a low refractive index of 1.6 or less made of SiO₂, MgF₂, Al₂O₃, or the like can be used. The thickness of the high-refractive transparent inorganic thin membrane and the low-refractive transparent inorganic thin membrane depends on the thin membrane structure, the kind of thin membrane, and the center wavelength in order to reduce the reflectance in a visible light range by light interference.

In case of a structure consisting of four layers as shown in FIG. 6, it is preferable that, in order from the transparent polymer film, the first layer (a high-refractive transparent inorganic thin membrane) has a thickness of from 5 to 50 nm, the second layer (a low-refractive transparent inorganic thin membrane) has a thickness of from 5 to 50 nm, the third layer (a high-refractive transparent inorganic thin membrane) has a thickness of from 50 to 150 nm, and the fourth layer (a low-refractive transparent inorganic thin membrane) has a thickness of from 50 to 150 nm.

The high-refractive transparent inorganic thin membranes and the low-refractive transparent inorganic thin membranes can be formed by one of methods including vapor deposition, sputtering, ion plating, and CVD. In case of a zinc oxide membrane as the high-refractive transparent inorganic thin membrane, it is preferable to use reactive sputtering method using zinc metal as a target. In this case, as the sputtering condition, it is preferable that the atmospheric condition is O₂ 100% or O₂ 40% or more with O₂—Ar.

Instead of the low-refractive transparent inorganic thin membrane as the upper-most layer, a fluorinated or non-fluorinated low-refractive organic thin membrane may be formed. Examples of material for the non-fluorinated organic thin membrane include acrylic resin, silicon resin, acrylic silicon resin, and urethane resin which are usually used for hard coating.

Examples of material of the fluorinated organic thin membrane include FET (fluoroethylene/propylene copolymer), PTFE (polytetrafluoroethylene), ETFE (ethylene/tetrafluoroethylene), PVF (poly vinyl fluoride), and PVD (poly vinylindene fluoride).

It is also preferable to add fluorinated and/or silicon additive(s) in order to impart antifouling property and/or smoothness. Among these, silicon resin and acrylic resin are suitable because these are low in price.

Since the organic thin membrane is generally a low-refractive thin membrane having a reflective index of from 1.3 to 1.6, antireflective function can be obtained by forming this organic thin membrane as the upper-most layer of the antireflective film on the high-refractive transparent inorganic thin membrane. The organic thin membrane is also excellent in antifouling property and abrasion-resistance.

To obtain both the antireflective function by light interference and the antifouling function, the thickness of the organic thin membrane is preferably in such a range capable of obtaining the antifouling function and optical range, i.e. from 50 to 500 nm, and is preferably, for example, about ¼ λ of wavelength of 500 nm (=125 nm). The same is true for the thickness of the low-refractive transparent inorganic thin membrane as the upper-most layer.

In case of an antireflective film comprising a lamination of transparent inorganic thin membranes on a transparent polymer film, the material may have insufficient transparency. Therefore, the antireflective film has a tendency to rapidly reduce its light transmission in short wavelength from about 400 nm, so it is not suitable for such an application. This may cause a defect that the antireflective film takes on a yellow tinge. Though some materials having sufficient transparency have been proposed, such material has significantly low film formation speed or high light transmittance relative to ultraviolet rays of wavelength shorter than about 350 nm so as to cause a defect that it is impossible to have ultraviolet protective property.

By forming an ultraviolet protection layer as mentioned above, an antireflective film provided with both the visible light transmittance and the ultraviolet protective property and having well productivity can be obtained.

The antireflective film of the third invention is attached to a surface, on which no transparent electrode is formed, by an adhesive layer 8. Examples of resin to be used for the adhesive layer include ethylene-vinyl acetate copolymer and sticky acrylic resin (e.g. butyl acrylate polymer). The resin may be cross-linked by heat or the like. The thickness of the adhesive layer is generally from 1 to 1000 μm, preferably from 10 to 500 μm.

In the above-mentioned metal oxide semiconductor electrode and the organic dye-sensitized solar cell having the same according to the third invention, the metal oxide semiconductor membrane 33 formed on the transparent electrode on the substrate has a configuration in which spherical particles of various sizes are bonded and has large irregularities on surface thereof and a lot of cavities inside thereof as apparent from FIG. 4. The metal oxide semiconductor membrane of the third invention may be formed by applying slurry of oxide semiconductor microparticles as conventionally used onto the transparent electrode, then drying the applied slurry, and after that baking it at 500° C. for 1 hour or may be formed by vapor deposition.

<Metal Oxide Semiconductor Membrane>

The metal oxide semiconductor membrane of the third invention is normally formed by the vapor deposition and preferably has a rough surface and a porosity of 25% or more. It is more preferable that the porosity is 30% or more, particularly 35% or more. According to this configuration, the adsorptive amount of organic dye is increased. Though the upper limit of the porosity may be almost 100% if the adsorbed amount of organic dye is increased, the upper limit is preferably about 95% in terms of maintaining the shape as a membrane.

The metal oxide semiconductor membrane 33 of the third invention has a large area of the surface thereof and has a large surface area of cavities inside thereof so that the area in which the organic dye is adsorbed is large. This structure (configuration) facilitates invasion of organic dye on the surface and into inner sides thereof, thereby achieving the dye adsorption in a short period of time. Since the membrane has a large surface area on the surface thereof and a large surface area inside thereof, it has increased adsorbed amount of organic dye, thereby improving the light energy conversion efficiency.

The metal oxide semiconductor membrane 33 having the aforementioned structure can be obtained under a variety of conditions of vapor deposition. Basically, the metal oxide semiconductor membrane 33 is preferably formed by short-time film formation with high electric power or film formation at high gas pressure, and may be formed by changing the flow rate of gas mixture, using an arc ion sputtering, or by a suitable combination of these methods.

A preferable method of forming the metal oxide semiconductor membrane 33 of the third invention is a sputtering method with a target introduction power density of 1.3 W/cm² or more, particularly 2.6 W/cm² or more, especially 11 W/cm² or more and under a pressure condition of 0.6 Pa or more, particularly 2.0 Pa or more, especially 2.6 Pa or more. As the sputtering method, a facing targets sputtering method is suitable and a reactive sputtering method is also preferable. By employing the more strict condition than the ordinary sputtering condition, the semiconductor membrane can be rapidly formed, thereby obtaining a metal oxide semiconductor membrane having a specific configuration and structure of the present invention. Therefore, the adsorbed amount of organic dye can be significantly increased, thus obtaining a high-efficiency solar cell having high energy conversion efficiency.

Each of the aforementioned substrates 31a, 31b may be any of transparent substrates and is generally a glass plate. As such a glass plate, a silicate glass is normally used. However, any of various plastic substrates capable of ensuring optical transparency of a visible light may be also used. Examples of plastic include polyesters such as polyethylene terephthalate, acrylic resins such as polymethyl methacrylate, and polycarbonate. The thickness of the substrate is generally from 0.1 mm to 10 mm, preferably from 0.3 mm to 5 mm. As the glass plate, a glass plate which is chemically or thermally reinforced is preferable. It should be noted that the substrate 31b may be non-transparent.

<Transparent Electrode>

As the aforementioned transparent electrode 32a, a substrate with a thin membrane of conductive metal oxide such as In₂O₃ and SnO₂ or a substrate made of a conductive material such as metal may be employed. Examples of preferable conductive metal oxides include In₂O₃: Sn(ITO), SnO₂:Sb, SnO₂:F, ZnO:Al, ZnO:F, and CdSnO₄.

<Semiconductor for Photoelectric Conversion Material>

Formed on the aforementioned transparent electrode is a metal oxide semiconductor membrane as a semiconductor for photoelectric conversion material, whereby spectral sensitizing dye is adsorbed. As the metal oxide semiconductor of the present invention, one or more of known semiconductors such as titanium oxide, zinc oxide, tungsten oxide, antimony oxide, niobium oxide, indium oxide, barium titanate, strontium titanate, and cadmium sulfide. Particularly, titanium oxide is preferable in terms of stability and safety. Exemplary titanium oxides include titanium oxides such as anatase-type titanium dioxide, rutile type titanium dioxide, amorphous titanium oxide, metatitanic acid, and orthotitanic acid, titanium hydroxide, and hydrous titanium oxide. In the present invention, particularly preferable example is anatase-type titanium dioxide. The thickness of the metal oxide semiconductor membrane is generally 10 nm or more, preferably from 100 to 1000 nm.

The metal oxide semiconductor membrane of the third invention can be formed by vapor deposition such as physical deposition, vacuum deposition, sputtering, ion plating, CVD, or plasma CVD, using metal and/or metal oxide corresponding to the used material as a target or targets under the conditions as mentioned above. A preferable method of forming the metal oxide semiconductor membrane 33 of the present invention is a sputtering method with a target introduction power density and under a pressure condition as mentioned above. As the sputtering method, a facing targets sputtering method is suitable and a reactive sputtering method is also preferable.

The facing targets sputtering method of the third invention is preferably a reactive sputtering method in which metal or metal oxide is sputtered while reactive gas such as oxygen gas is introduced. It is particularly preferable to conduct the sputtering using titanium metal or titanium oxide, especially conductive titanium oxide as the targets while introducing oxygen gas.

The organic dye (spectral sensitizing dye) is adsorbed as monomolecular membrane to the oxide semiconductor membrane surface on the substrate thus obtained.

The spectral sensitizing dye has adsorptive property in visible light range and/or infrared light range. In the present invention, one or more of various metal complexes and organic dyes may be used. The spectral sensitizing dyes having functional groups such as carboxyl group, hydroxyalkyl group, hydroxyl group, sulfonic group, and carboxyalkyl group in their molecules are preferable because they are quickly adsorbed into semiconductors. The metal complexes are preferable because they are excellent in effect of spectral sensitization and durability. Examples which may be used as the metal complex are complexes of metal phtalocyanines such as copper phthalocyanine and titanyl phthalocyanine, chlorophyll, hemin, ruthenium described in JP H01-220380A or JP H05-504023A, osmium, iron, and zinc. Examples which may be used as the organic dye are metal-free phthalocyanine, cyanine dyes, merocyanine dyes, xanthene dyes, and triphenylmethane dyes. Specific examples of cyanine dyes include NK1194 and NK3422 (both available from Hayashibara Biochemical Laboratories, Inc.). Specific examples of merocyanine dyes include NK2426 and NK2501 (both available from Hayashibara Biochemical Laboratories, Inc.). Specific examples of xanthene dyes include Uranine, Eosine, rose Bengal, rhodamine B, and Dibromofluorescein. Specific examples of triphenylmethane dyes include malachite green and crystal violet.

Among these, a ruthenium complex (for example, ruthenium phenanthroline, ruthenium diketonate) and/or coumarin derivatives can generally provide relatively high energy conversion efficiency. When the antireflective membrane or antireflective film of the present invention is made using the ruthenium complex and/or the coumarin derivatives, solar energy can be further effectively used. When the antireflective membrane or antireflective film is designed to effect light adsorptive characteristics of the ruthenium complex and/or the coumarin derivatives, solar energy can be further effectively used. As for the ruthenium complex, the antireflective membrane (film) preferably has light reflectance of 10% or less in a range of wavelength from 300 to 600 nm, more preferably, minimum light reflectance in the aforementioned range. As for the coumarin derivative dye, the antireflective membrane (film) preferably has light reflectance of 10% or less in a range of wavelength from 400 to 600 nm. As the antireflective film which is suitable for both dyes, a PET film (thickness of 100 μm) on which an ultraviolet protection layer containing an ultraviolet absorbent, a TiO₂ layer (thickness of 20 nm), a SiO₂ layer (thickness of 25 nm), a TiO₂ layer (thickness of 90 nm), and a SiO₂ layer (thickness of 80 nm) are formed is preferable. Therefore, an antireflective membrane consisting of the aforementioned four layers is preferable.

To adsorb the organic dye (spectral sensitizing dye) to the semiconductor membrane, organic dye solution is prepared by dissolving the organic dye in organic solvent, and the oxide semiconductor membrane is soaked together with the substrate in the organic dye solution at ordinary temperature or under heated condition. The solvent of the organic solution may be any of solvents capable of dissolving the used spectral sensitizing dye. Specific examples of such a solvent include water, alcohol, toluene, and dimethylformamide.

In this manner, the organic dye-sensitized metal oxide semiconductor electrode (semiconductor for photoelectric conversion material) is obtained.

A solar cell is manufactured using an organic dye-sensitized metal oxide semiconductor electrode having a transparent electrode and an organic dye adsorbed metal oxide semiconductor formed thereon. That is, a substrate such as a glass plate having the antireflective film on one surface thereof and a transparent electrode (transparent conductive membrane) applied on the other surface thereof is prepared. A semiconductor membrane for photoelectric conversion material is formed on the transparent electrode on the substrate, thereby forming one electrode. Another substrate such as a glass plate, which is coated with a transparent conductive membrane, as a counter electrode is bonded to the electrode by sealing agent. An electrolyte is encapsulated between the electrodes, thereby forming a solar cell.

As the spectral sensitizing dye adsorbed to the semiconductor membrane of the third invention is irradiated with sun light, the spectral sensitizing dye adsorbs light in visible light range and is thus excited. Electrons generated by the excitation is moved to the semiconductor and then moved to the counter electrode through the transparent conductive glass electrode. The electrons moved to the counter electrode reduce the oxidation-reduction substance in the electrolyte. On the other hand, the spectral sensitizing dye moving the electrons to the semiconductor is in a state of oxidant. The oxidant is reduced by the oxidation-reduction substance in the electrolyte so that the spectral sensitizing dye returns to its original state. Electrons flow in this manner, thereby constituting a solar cell using a semiconductor for photoelectric conversion material.

Examples of the electrolyte (redox electrolyte) include I⁻/I₃⁻ series and Br⁻/Br₃⁻ series electrolytes, and quinine/hydroquinone series electrolytes. These redox electrolytes can be obtained in conventional manners. For example, the I⁻/I₃⁻ series electrolyte can be obtained by mixing iodine ammonium salt and iodine. The electrolyte may be liquid electrolyte or solid high-molecular electrolyte which is prepared by impregnating the liquid electrolyte to high-molecular substance. As the solvent for the liquid electrolyte, solvent which is electrochemically inactive is used. Examples of such a solvent include acetonitrile, propylene carbonate, and ethylene carbonate. The counter electrode may be any of electrodes having conductivity so that any conductive material can be used. It is preferable to use a conductive material having catalytic power to conduct reductive reaction of oxidized redox ion such as I₃⁻ ion at a sufficient high speed. Examples of such a conductive material include a platinum electrode, a conductive material having a platinized surface or a surface with platinum deposition, rhodium metal, ruthenium metal, ruthenium oxide, and carbon.

Though the oxide semiconductor electrode, the electrolyte, and the counter electrode are housed in a casing and then sealed in the solar cell of the third invention, these may be sealed entirely with resin. In this case, the resin sealing is designed so that the oxide semiconductor electrode is exposed to light. In the cell having such a structure, as sun light or visible light similar to the sun light is incident on the oxide semiconductor electrode, a potential difference is generated between the oxide semiconductor electrode and the counter electrode so that current flows between the electrodes.

### EXAMPLES OF THE THIRD INVENTION

### Example 3-1

(1) Production of Antireflective Film

Acrylic UV cure resin solution (Z7501, available from JSR corporation) containing 2 parts by mass of 2-hydroxybenzophenone as an ultraviolet absorber was applied on a PET film (thickness of 100 μm) and was irradiated with ultraviolet light, thereby forming an ultraviolet protection layer (thickness of 5 μm).

A TiO₂ layer (thickness of 20 nm), a SiO₂ layer (thickness of 25 nm), TiO₂ layer (thickness of 90 nm), and a SiO₂ layer (thickness of 80 nm) were laminated in this order by sputtering, thereby obtaining an antireflective film.

(2) Production of Transparent Electrode and Placement of Antireflective Film

A transparent electrode membrane was produced by using a sputtering apparatus.

Sputtering was conducted onto a glass substrate of 5×5 cm (thickness of 2 mm) for 5 minutes using a ceramic target of ITO (indium-tin oxide) of 100 mmφ while supplying argon gas at 10 cc/minute and oxygen gas at 1.5 cc/minute under conditions that the pressure inside the apparatus was set at 5 mTorr and the supply power was 500 W. In this manner, an ITO membrane having a thickness of 3000 Å was formed. The surface resistance was 10Ω/□.

The antireflective film and the glass substrate were laminated such that the side without thin membranes of the antireflective film and the side without the transparent electrode of the glass substrate were attached to each other via an ethylene-vinyl acetate copolymer film (25 μm) and were pressed at 150° C. for 30 minutes.

(3) Production of Metal Oxide Semiconductor Membrane

A facing targets sputtering apparatus was used and two targets of titanium metal having a diameter of 100 mm were placed on the ITO transparent electrode glass plate in the apparatus. After oxygen gas and argon gas were supplied at 5 cc/minute and at 5 cc/minute, respectively, sputtering was conducted for 32 minutes under conditions that the pressure inside the apparatus was set at 5 mTorr (0.7 Pa) and the supply power was 3 kW (power density of 19 W/cm²), thereby forming a titanium oxide membrane having a thickness of 3000 Å.

The porosity of the obtained semiconductor membrane was measured.
Measuring method of porosity:
The following weights were measured, respectively and the porosity was calculated by the following equation (measurement was conducted according to JISZ8807):
w1: mass of a sample when fully filled with water (g)
w2: absolute dry mass of the sample (g)
w3: buoyancy of the sample (g)
Porosity=(w1−w2)/w3×100

According to the measurement, the porosity of the aforementioned semiconductor membrane was 17%.

(4) Adsorption of Spectral Sensitizing Dye

A spectral sensitizing dye represented by cis-di(thiocyanato)-bis (2,2′-bipyridyl-4-dicarboxylate-4′-tetrabutylammonium carboxylate) ruthenium(II) was dissolved into ethanol solvent. The concentration of the spectral sensitizing dye was 3×10⁻⁴ mole/L. The aforementioned substrate having the titanium oxide membrane formed thereon was entered into the ethanol solution and was soaked at a room temperature for 18 hours, thereby obtaining a metal oxide semiconductor electrode of the present invention. The adsorptive amount of the spectral sensitizing dye was 10 μg per 1 cm² specific area of the titanium oxide membrane.

(5) Production of Solar Cell

The metal oxide semiconductor electrode was used as one electrode and a transparent conductive glass plate coated with fluorine-doped tin oxide and carrying platinum thereon was used as a counter electrode. An electrolyte was sandwiched between the two electrodes. The sides of the lamination were sealed by resin and lead wires were attached, thereby producing a solar cell of the present invention. It should be noted that the electrolyte was a solution prepared by dissolving lithium iodide, 1,2 dimethyl-3-propylimidazolium iodide, iodine, and t-butylpyridine into acetonitrile solvent such that the respective concentrations were 0.1 mole/L, 0.3 mole/L, 0.05 mol/L, and 0.5 mole/L. As light with intensity of 100 W/m² was incident on the obtained solar cell by a solar simulator, Voc (voltage in open-circuit) was 0.58V, Jsc (density of current flowing in short-circuit) was 1.30 mA/cm², FF (fill factor) was 0.53, η(conversion efficiency) was 4.01%. From the results, it was confirmed that the solar cell is useful.

### Example 3-2

A solar cell was manufactured in the same manner as Example 3-1 except that coumarin derivative dye was used as the spectral sensitizing dye.

As light with intensity of 100 W/m² was incident on the obtained solar cell by a solar simulator, Voc (voltage in open-circuit) was 0.59V, Jsc (density of current flowing in short-circuit) was 6.5 mA/cm², FF (fill factor) was 0.53, η(conversion efficiency) was 2.05%. From the results, it was confirmed that the solar cell is useful.

### Comparative Example 3-1

A solar cell was manufactured in the same manner as Example 3-1 except that no antireflective film was formed.

As light with intensity of 100 W/m² was incident on the obtained solar cell by a solar simulator, Voc (voltage in open-circuit) was 0.62V, Jsc (density of current flowing in short-circuit) was 1.00 mA/cm², FF (fill factor) was 0.56, η(conversion efficiency) was 3.50%. From the results, it was found that the solar cell has lower usability of light as compared to the solar cells of the aforementioned examples so that it can be hardly said that the solar cell is useful.

As the glass plate surfaces of the solar cells obtained in Examples 3-1 and 3-2 and Comparative Example 3-1 were broken using a hammer, the glass plates of the solar cells of Examples 3-1 and 3-2 were not scattered while the glass plate of the solar cell obtained in Comparative Example 3-1 was scattered due to breakage.

As apparent from the above, the solar cell having the organic dye-sensitized metal oxide semiconductor electrode of the third invention is an organic dye-sensitized solar cell which has increased adsorbing amount of light energy because of the antireflective membrane. Therefore, the solar cell has improved usability of light energy and is therefore provided with sufficient capability as a solar cell. Particularly when a metal oxide conductive membrane which can be easily obtained at a low temperature by vapor deposition is used, an organic dye-sensitized solar cell further provided with increased adsorbed amount of dye can be obtained.

The solar cell of the third invention has improved usability of light energy and is therefore provided with sufficient capability as a solar cell as mentioned above. By the presence of an antireflective membrane, particularly an antireflective film, the glass plate is prevented from scattering when broken so that the solar cell is also excellent in safety.

(4) The fourth Invention

Embodiments of an organic dye-sensitized solar cell having a metal oxide semiconductor electrode according to the fourth invention will be described with reference to drawings.

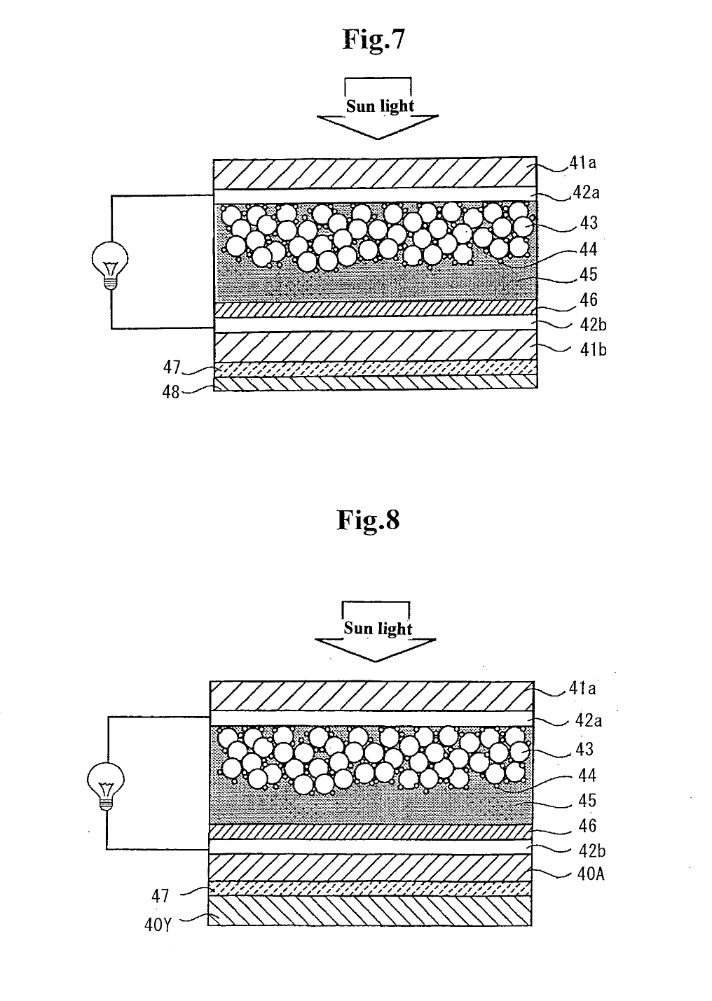

FIG. 7 is a sectional view of an embodiment of the organic dye-sensitized solar cell having a release sheet of the fourth invention.

In FIG. 7, an organic dye-sensitized solar cell comprises a transparent organic polymer substrate 41a, a transparent electrode 42a formed on a surface of the substrate 41a, a metal oxide semiconductor membrane 43 with spectral sensitizing dye 44 adsorbed therein formed on a surface of the transparent electrode 42a, and a counter electrode 46 (e.g. Pt electrode) formed beneath the metal oxide semiconductor membrane 43. The counter electrode 46 is arranged at an opposed position to the transparent electrode. The counter electrode 46 is formed on a transparent electrode 42b formed on an organic polymer substrate 41b. An electrolyte (solution) 45 is encapsulated between the metal oxide semiconductor membrane 43 and the counter electrode 46. Further, a release film 48 is attached to the back surface of the transparent organic polymer substrate 41b via a transparent adhesive layer 47.

Since the solar cell uses flexible organic polymer films as substrates, the solar cell can be attached to any place after removing the release film. Since the solar cell has flexibility, the solar cell can be uniformly attached even if the place to which the solar cell is attached is not a complete flat surface. The organic polymer substrate 41b may be transparent, may have light reflectivity and/or designing property as will be described later. The solar cell may not have the adhesive layer 47 and the release film 48. In this case, the solar cell is bonded to a base member such as a roof by using adhesive agent.

Respective materials which can be commonly used in the preceding examples or the following examples will be described later. As the release film, a polycarbonate film, a PET film, or the like may be used. The thickness of the release film is generally from 1 to 1000 μm, preferably from 10 to 500 μm. Examples of resin to be used in the adhesive layer include ethylene-vinyl acetate copolymer and sticky acrylic resin (e.g. butyl acrylate polymer). These resins may be crosslinked by heat. The thickness of the adhesive layer is generally from 1 to 1000 μm, preferably from 10 to 500 μm.

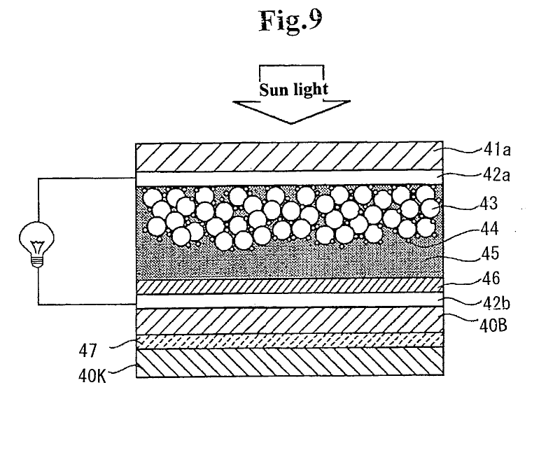

FIG. 8 is a sectional view showing an example of a roofing material having an organic dye-sensitized solar cell of the fourth invention.

In FIG. 8, an organic dye-sensitized solar cell comprises a transparent organic polymer substrate 41a, a transparent electrode 42a formed on a surface of the substrate 41a, a metal oxide semiconductor membrane 43 with spectral sensitizing dye 44 adsorbed therein formed on a surface of the transparent electrode 42a, and a counter electrode 46 (e.g. Pt electrode) formed beneath the metal oxide semiconductor membrane 43. The counter electrode 46 is arranged at an opposed position to the transparent electrode. The counter electrode 46 is formed on a transparent electrode 42b formed on a light reflective organic polymer substrate 40A. An electrolyte (solution) 45 is encapsulated between the metal oxide semiconductor membrane 43 and the counter electrode 46. Further, a transparent adhesive layer 47 is formed on the back surface of the light reflective organic polymer substrate 40A. By the adhesive layer, the solar cell is attached to a roofing material 40Y.

The solar cell uses flexible organic polymer films as the upper and lower substrates and is previously bonded to the roofing material. Therefore, the solar cell is usually used as an ordinary roofing material and has a function as a solar cell. That is, this roofing material provides an advantage that solar cells are automatically installed when a roof is constructed. The roofing material may be other building materials such as a window pane and a wall material. The light reflective organic polymer substrate 40A generally has a reflection layer on its surface, whereby sun light not adsorbed by the metal oxide electrode is reflected so that the reflected light tends to be adsorbed by the electrode again. Therefore, the roof material is excellent in its designing property and enables effective utilization of light energy.

The light reflective organic polymer substrate 40A comprises an organic polymer film as will be described later, a reflective layer which is formed on the organic polymer film by vapor deposition, sputtering using aluminum, silver, or the like, and a transparent electrode which is formed on the reflective layer. The thickness of the reflective layer is generally from 10 nm to 50 μm, preferably from 10 nm to 10 μm. In case that the reflective layer is conductive, the reflective layer can also function as the transparent electrode.

The adhesive layer may be the same as mentioned above. Instead of the light reflective organic polymer substrate 40A, an organic polymer substrate without reflective property may be used.

FIG. 9 is a sectional view showing an example of a wall material having an organic dye-sensitized solar cell of the fourth invention.

In FIG. 9, an organic dye-sensitized solar cell comprises a transparent organic polymer substrate 41a, a transparent electrode 42a formed on a surface of the substrate 41a, a metal oxide semiconductor membrane 43 with spectral sensitizing dye 44 adsorbed therein formed on a surface of the transparent electrode 42a, and a counter electrode 46 (e.g. Pt electrode) formed beneath the metal oxide semiconductor membrane 43. The counter electrode 46 is arranged at an opposed position to the transparent electrode. The counter electrode 46 is formed on a transparent electrode 42b formed on a decorative organic polymer substrate 40B. An electrolyte (solution) 45 is encapsulated between the metal oxide semiconductor membrane 43 and the counter electrode 46. Further, a transparent adhesive layer 47 is formed on the back surface of the decorative organic polymer substrate 40A. By the adhesive layer, the solar cell is attached to a wall material 40K.

The solar cell uses flexible organic polymer films as the upper and lower substrates and is previously bonded to the wall material. Therefore, the solar cell is usually used as an ordinary wall material and has a function as a solar cell. That is, this wall material provides an advantage that solar cells are automatically installed when a wall is constructed. The wall material may be other building materials such as a window pane and a roofing material. The decorative organic polymer substrate 40B generally is colored and/or has a pattern and/or characters so that it is provided with designing property and decorative property.

In case of the decorative organic polymer substrate 40B being colored, it is generally a substrate comprising an organic polymer substrate (film) as will be described which contains a coloring agent (pigment, dye), for example, by melting and mixing a polymer material and a coloring agent and forming a film of the mixture. In case of the decorative organic polymer substrate 40B being provided with a pattern, the pattern can be provided by printing the substrate or attaching a film with the pattern to the substrate. The adhesive layer may be the same as mentioned above. Examples of the pattern include woodgrain pattern and brick pattern.

In the above-mentioned metal oxide semiconductor electrode and the organic dye-sensitized solar cell having the same according to the fourth invention, the metal oxide semiconductor membrane 43 formed on the transparent electrode on the substrate has a configuration in which spherical particles of various sizes are bonded and has large irregularities on surface thereof and a lot of cavities inside thereof as apparent from FIGS. 7 through 9. The metal oxide semiconductor membrane of this invention is preferably formed by vapor deposition.

The same description as for the metal oxide semiconductor membrane of the third invention can be adopted to the metal oxide semiconductor membrane 43 of the fourth invention.

As each of the transparent organic polymer substrates 41a, 41b, 40A, 40B, any of various transparent organic polymer substrates capable of ensuring optical transparency of a visible light may be used. The thickness of the substrate is generally from 25 μm to 10 mm, preferably from 0.1 mm to 10 mm. Examples of organic polymer include polyesters such as polyethylene terephthalate, acrylic resins such as polymethyl methacrylate, polycarbonate, and fluorocarbon resins such as PTFE (polytetrafluoroethylene) and ETFE (ethylene/tetrafluoroethylene copolymer).

The non-transparent organic polymer substrate may be made of the same material as mentioned above and is colored and/or provided with a pattern.

The same description as for the transparent electrode of the third invention can be adopted to the transparent electrodes 42a, 42b of the fourth invention.

The same description as for the semiconductor for photoelectric conversion material of the third invention can be adopted to the metal oxide semiconductor electrode membrane for adsorbing spectral sensitive dye, as a semiconductor for photoelectric conversion material on the transparent electrode 42a of the fourth invention.

The same description as made for the method of forming the metal oxide semiconductor membrane in the third invention can be adopted to the fourth invention.

The same description as made for the organic dye (spectral sensitizing dye) to be adsorbed as monomolecular membrane to the oxide semiconductor membrane surface on the substrate in the third invention can be also adopted to the fourth invention.

Also in the fourth invention, a solar cell is manufactured by using an organic dye-sensitized metal oxide semiconductor electrode which comprises a substrate and a transparent electrode and an organic dye-sensitized metal oxide semiconductor formed on the substrate, similarly to the third invention. For example, a semiconductor membrane for photoelectric conversion material is formed on a transparent organic polymer substrate which is coated with a transparent electrode (transparent conductive membrane) so as to prepare an electrode. Then, another organic polymer substrate, which is coated with a transparent conductive membrane (a substrate having a transparent electrode is generally used and the transparent conductive membrane is formed on the electrode thereof), as a counter electrode is bonded to the electrode by sealing agent. An electrolyte is encapsulated between the electrodes, thereby forming a solar cell.

As the spectral sensitizing dye adsorbed to the semiconductor membrane of the fourth invention is irradiated with sun light, the spectral sensitizing dye adsorbs light in visible light range and is thus excited. Electrons generated by the excitation is moved to the semiconductor and then moved to the counter electrode through the transparent conductive electrode. The electrons moved to the counter electrode reduce the oxidation-reduction substance in the electrolyte. On the other hand, the spectral sensitizing dye moving the electrons to the semiconductor is in a state of oxidant. The oxidant is reduced by the oxidation-reduction substance in the electrolyte so that the spectral sensitizing dye returns to its original state. Electrons flow in this manner, thereby constituting a solar cell using a semiconductor for photoelectric conversion material.

The same description about the electrolyte of the third invention can be adopted to the aforementioned electrolyte (redox electrolyte) of this invention.

Though the oxide semiconductor electrode, the electrolyte, and the counter electrode are housed in a casing and then sealed in the solar cell of the fourth invention similar to the third invention, these may be sealed entirely with resin. In this case, the resin sealing is designed so that the oxide semiconductor electrode is exposed to light. In the cell having such a structure, as sun light or visible light similar to the sun light is incident on the oxide semiconductor electrode, a potential difference is generated between the oxide semiconductor electrode and the counter electrode so that current flows between the electrodes.

### EXAMPLES OF THE FOURTH INVENTION

### Example 4-1

(1) Production of Transparent Organic Polymer Substrate with Transparent Electrode

A transparent electrode membrane was formed on a transparent organic polymer substrate by using a sputtering apparatus.

Sputtering was conducted onto a polyethylene telephtalate substrate of 5×5 cm (thickness of 188 μm) for 5 minutes using a ceramic target of ITO (indium-tin oxide) of 100 mmφ while supplying argon gas at 10 cc/minute and oxygen gas at 1.5 cc/minute under conditions that the pressure inside the apparatus was set at 5 mTorr and the supply power was 500 W. In this manner, an ITO membrane having a thickness of 3000 Å was formed. The surface resistance was 10 Ω/□.

(2) Production of Metal Oxide Semiconductor Membrane

A facing targets sputtering apparatus was used and two targets of titanium metal having a diameter of 100 mm were placed on the ITO transparent glass plate in the apparatus. After oxygen gas and argon gas were supplied at 5 cc/minute and at 5 cc/minute, respectively, sputtering was conducted for 32 minutes under conditions that the pressure inside the apparatus was set at 5 mTorr (0.7 Pa) and the supply power was 3 kW (power density of 19 W/cm²), thereby forming a titanium oxide membrane having a thickness of 3000 Å.

The porosity of the obtained semiconductor membrane was measured.

Measuring method of porosity:

The following weights were measured, respectively and the porosity was calculated by the following equation (measurement was conducted according to JISZ8807):
w1: mass of a sample when fully filled with water (g)
w2: absolute dry mass of the sample (g)
w3: buoyancy of the sample (g)
Porosity=(w1−w2)/w3×100

According to the measurement, the porosity of the aforementioned semiconductor membrane was 17%.

(3) Adsorption of Spectral Sensitizing Dye

A spectral sensitizing dye represented by cis-di(thiocyanato)-bis (2,2′-bipyridyl-4-dicarboxylate-4′-tetrabutylammonium carboxylate) ruthenium(II) was dissolved into ethanol solvent. The concentration of the spectral sensitizing dye was 3×10⁻⁴ mole/L. The aforementioned substrate having the titanium oxide membrane formed thereon was entered into the ethanol solution and was soaked at a room temperature for 18 hours, thereby obtaining a metal oxide semiconductor electrode. The adsorptive amount of the spectral sensitizing dye was 10 μg per 1 cm² specific area of the titanium oxide membrane.

(4) Attachment of an Adhesive Layer and a Release Film to the Transparent Organic Polymer Substrate with a Counter Electrode

As a counter electrode, a transparent conductive organic polymer substrate, which comprises a polyethylene telephtalate substrate (thickness of 188 μm) coated with fluorine-doped tin oxide and carrying platinum thereon, was used.

A release sheet (thickness of 75 μm: trade name No. 23 available from Fujimori Kogyo Co., Ltd.) was attached to the back surface of the transparent conductive organic polymer substrate via an adhesive layer (ethylene-vinyl acetate copolymer) at 80° C. with certain pressure.

(5) Production of Solar Cell

An electrolyte was sandwiched between the two electrodes thus obtained. The sides of the lamination were sealed by resin and lead wires were then attached, thereby producing a solar cell of the present invention. It should be noted that the electrolyte was a solution prepared by dissolving lithium iodide, 1,2 dimethyl-3-propylimidazolium iodide, iodine, and t-butylpyridine into acetonitrile solvent such that the respective concentrations were 0.1 mole/L, 0.3 mole/L, 0.05 mol/L, and 0.5 mole/L.

As light with intensity of 100 W/m² was incident on the obtained solar cell by a solar simulator, Voc (voltage in open-circuit) was 0.58V, Jsc (density of current flowing in short-circuit) was 1.30 mA/cm², FF (fill factor) was 0.53, TI(conversion efficiency) was 4.01%. From the results, it was confirmed that the solar cell is useful.

### Example 4-2

(4) A solar cell is manufactured in the same manner as Example 4-1 except that an adhesive layer and a release film are attached to the transparent polymer substrate with the counter electrode as will be described below.

(4) Attachment of an Adhesive Layer and a Release Film to a Transparent Organic Polymer Substrate with a Counter Electrode

A transparent electrode membrane was prepared by a sputtering apparatus.

A reflective layer (thickness of 300 μm) was formed by depositing aluminum onto a surface of a polyethylene telephtalate substrate (thickness of 188 μm) of 5×5 cm. The reflective layer also functions as an electrode.

An adhesive layer and a release sheet were attached to the back surface of the transparent conductive organic polymer substrate in the same manner as Example 4-1.

The porosity measured in the same manner as Example 4-1 was 19%.

The obtained solar cell with the reflective layer was attached to a surface of a roofing material using a roller, thereby obtaining a roofing material with a solar cell.

As light with intensity of 100 W/m² was incident on the obtained roofing material by a solar simulator, Voc (voltage in open-circuit) was 0.59V, Jsc (density of current flowing in short-circuit) was 1.31 mA/cm², FF (fill factor) was 0.53, η(conversion efficiency) was 4.12%. From the results, it was confirmed that the solar cell is useful.

After the solar cell was exposed outdoors for 1 month, it showed little deterioration in the aforementioned characteristics.

### Example 4-3

(4) A solar cell is manufactured in the same manner as Example 4-1 except that an adhesive layer and a release film are attached to the transparent polymer substrate with the counter electrode as will be described below.

(4) Attachment of an Adhesive Layer and a Release Film to a Transparent Organic Polymer Substrate with a Counter Electrode

A transparent conductive organic polymer substrate, which comprises a polyethylene telephtalate substrate (thickness of 2 mm) of 5×5 cm, of which surface was printed with woodgrain pattern and which was coated with fluorine-doped tin oxide and carries platinum thereon, was used.

An adhesive layer and a release sheet were attached to the back surface of the transparent conductive organic polymer substrate in the same manner as Example 4-1.

The solar cell was attached to a surface of a glass plate after removing the release film, thereby obtaining a glass plate with a solar cell.

The porosity measured in the same manner as Example 4-1 was 19%.

After the solar cell was exposed outdoors for 1 month, it showed little deterioration in color when the woodgrain pattern was observed.

As apparent from the above, the organic dye-sensitized solar cell of the fourth invention uses flexible organic polymer films as the substrate so that the solar cell can be bonded to or placed on a surface of any material. Since the organic dye-sensitized solar cell of the present invention is a solar cell which has flexibility, designing property, and decorative property (color, pattern, high reflection) and is capable of being bonded, it can be used for a place requiring decorative property. Since building materials such as roofing materials or wall materials having solar cells of the present invention attached thereto by bonding or the like, the building materials have function as solar cells when used as building materials, thus providing advantage.

(5) An embodiment of a method of forming a metal oxide semiconductor membrane of the fifth invention will be described with reference to a drawing.

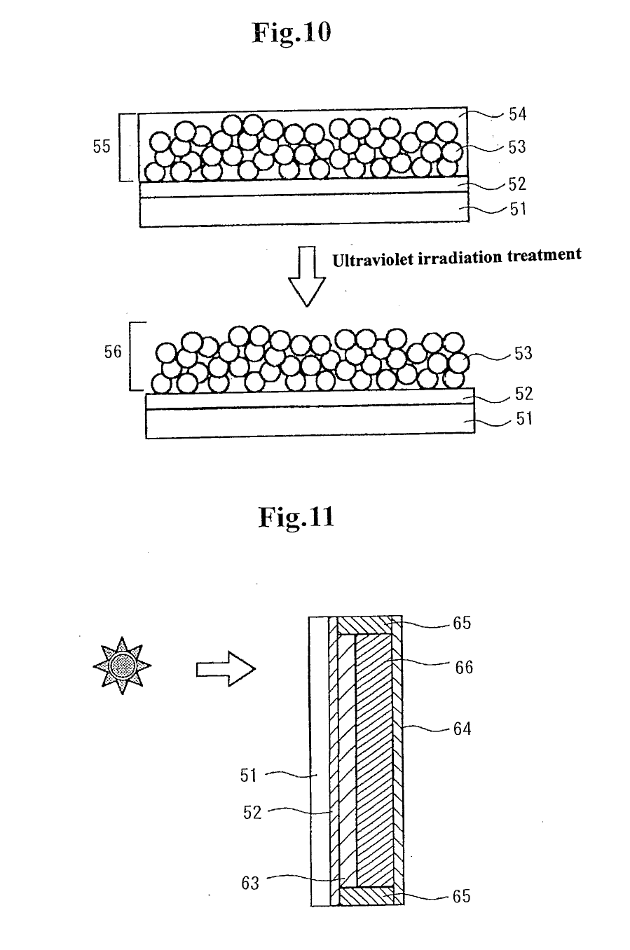

FIG. 10 shows a schematic diagram for explaining a method of forming a metal oxide semiconductor membrane of the fifth invention. Coating liquid in which metal oxide microperticles are dispersed in a binder (generally an organic binder) is applied to a transparent electrode 52 formed on a substrate 51 and is dried so as to form a coating 55 mainly consisting of the metal oxide microperticles 53 and the binder 54. The binder 54 is removed by irradiating the coating with ultraviolet light, thereby forming a metal oxide semiconductor membrane 56 having a large surface area.

The binder 54 (organic matter such as polymer or surface active surfactant) of the coating is decomposed into low-molecular substances (organic acids, carbon dioxide, and the like) by irradiation with ultraviolet light and thus removed. The ultraviolet light to be used to decompose the binder into low-molecular substances is preferably short-wavelength ultraviolet light, generally in a range of from 1 to 400 nm, preferably from 1 to 300 nm, especially from 1 to 200 nm. Therefore, the binder can be quickly removed at a relatively low temperature.

As the mechanism for decomposing the binder (organic matter),
(1) as the binder is irradiated with ultraviolet light, the binder adsorbs the ultraviolet light so that the molecular bonds constructing the binder are directly cut,
(2) atmospheric gas is decomposed by energy of ultraviolet light to generate radicals whereby the binder is decomposed by the radicals (in this case, gas containing O, F, Cl or the like is effectively used), and
(3) metal oxide semiconductor (TiO₂ and the like) adsorbs ultraviolet light and thus is exited so as to decompose the binder (that is, oxidative degradation by photocatalytic reaction).

As an example of the above (2), irradiation of short-wavelength ultraviolet light on the order of 185 nm generates radials having high oxidizing force (for example, OH—) so as to decompose the binder. For generating radicals having high oxidizing force, the irradiation is conducted in a reactive gas containing a compound such as oxygen, fluorine atom containing compound (for example, CF₄) or chlorine atom containing compound. The radicals generated in such a reactive gas react with the binder and decompose the binder. Since this reaction can be conducted at a relatively low temperature, the transparent electrode and the substrate used may be made of a material which is not excellent in thermal resistance (for example, a plastic substrate may be used as the substrate, an ITO may be used as the electrode, and the like). From the aspect of light energy conversion efficiency, titanium oxide, particularly anatase-type titanium dioxide, is preferably used as the aforementioned metal oxide.

The binder to be used is preferably easily discomposed by irradiation with ultraviolet light. The preferable binder generally contains or easily generates a carbonyl group, a hydroperoxide group, and the like. Examples of the preferable binder will be described later.

As an ultraviolet light lamp to be used for ultraviolet light irradiation, a mercury lamp is usually used. As the current is applied between two electrodes within gas or steam, lights of various wavelengths can be emitted. The strength and wavelength of emitted light depend on the kind of gas, the pressure, the current amount, and the tube diameter. The lamp using mercury as the gas or steam is a mercury lamp. Known types of such a mercury lamp are high-pressure, medium-pressure, and low-pressure types. To quickly decompose the binder, a high-pressure mercury lamp is suitable. To generate ultraviolet light of short wavelength, a low-pressure mercury lamp or an Xe excimer lamp is preferable. In case of using a high-pressure mercury lamp, ultraviolet light irradiation is conducted onto the coating generally for a time period of from 1 second to 60 minutes, preferably from 15 seconds to 30 minutes, especially preferably from 10 minutes to 20 minutes. The distance to be taken for irradiation is generally from 1 to 100 cm, preferably from 1 to 20 nm, especially preferably from 1 to 10 cm.

The coating 55, which mainly consists of the metal oxide microparticles 53 and the binder 54 and is formed on the substrate 51, is irradiated with ultraviolet light by an ultraviolet light lamp. To promote the decomposition of the binder, it is preferable to irradiate the coating with ultraviolet light in a state that the aforementioned reactive gas exists between the coating and the lamp as mentioned above.

As a preferable combination of the kind of a binder (polymer), the reactive gas, and the like, it is preferable that a polyester resin is used as the binder and a high-pressure mercury lamp is used in atmosphere of ozone, Cl₂, CF₄, or the like to decompose the binder.

A transparent electrode substrate with a metal oxide semiconductor membrane of the fifth invention is obtained in the aforementioned manner.

An embodiment of a metal oxide semiconductor electrode of the present invention using the aforementioned transparent electrode substrate with a metal oxide semiconductor membrane and an embodiment of an organic dye-sensitized solar cell having the same will be described with reference to drawings.

FIG. 11 is a sectional view showing an embodiment of the organic dye-sensitized solar cell of the fifth invention.

In FIG. 11, an organic dye-sensitized solar cell comprises a substrate 51, a transparent electrode 52 formed on a surface of the substrate 51, a metal oxide semiconductor membrane 63 with spectral sensitizing dye adsorbed therein formed on a surface of the transparent electrode, and a counter electrode 64 formed above the metal oxide semiconductor membrane 63. The counter electrode 64 is arranged at an opposed position to the transparent electrode. The outer edge of the lamination is sealed by sealing material 65and an electrolyte (solution) 66 is encapsulated between the metal oxide semiconductor membrane 63 and the counter electrode 64. It should be noted that the metal oxide semiconductor electrode is basically composed of the substrate 51, the transparent electrode 52 formed thereon, and the metal oxide semiconductor membrane 63 with spectral sensitizing dye adsorbed therein.

In the metal oxide semiconductor electrode and the organic dye-sensitized solar cell having the same of the fifth invention, the metal oxide semiconductor membrane 53, 63 formed on the transparent electrode on the substrate has a configuration in which spherical particles of various sizes are bonded and has large irregularities on surface thereof and a lot of cavities inside thereof as apparent from FIG. 10 and FIG. 11. That is, the metal oxide semiconductor membrane of the fifth invention has numerous cavities which were formed by removing the binder from the coating by irradiation with ultraviolet light so that the porosity is high. The porosity is preferably 30% or more, particularly 35% or more. Though the upper limit of the porosity may be almost 100% if the adsorbed amount of organic dye is increased, the upper limit is preferably about 95% in terms of maintaining the shape as a membrane.

The metal oxide semiconductor membrane 53 of the fifth invention has a large surface area of the surface thereof and has a large surface area of cavities inside thereof so that the area in which the organic dye is adsorbed is large. This structure (configuration) facilitates invasion of organic dye on the surface and into inner sides thereof, thereby achieving the dye adsorption in a short period of time. Since the membrane has a large surface area on the surface thereof and a large surface area inside thereof, it has increased adsorbed amount of organic dye, thereby improving the light energy conversion efficiency.

The metal oxide semiconductor membrane 53 having the aforementioned structure can be obtained by coating, drying, and irradiation with ultraviolet light as mentioned above.

First, a coating liquid in which metal oxide microparticles are dispersed in a binder is applied to the transparent electrode formed on the substrate (preferably, a plastic substrate).

As a metal oxide (metal oxide semiconductor), one or more of known semiconductors such as titanium oxide, zinc oxide, tungsten oxide, antimony oxide, niobium oxide, indium oxide, barium titanate, strontium titanate, and cadmium sulfide. Particularly, titanium oxide is preferable in terms of stability and safety. Exemplary titanium oxides include titanium oxides such as anatase-type titanium dioxide, rutile type titanium dioxide, amorphous titanium oxide, metatitanic acid, and orthotitanic acid, titanium hydroxide, and hydrous titanium oxide. In the present invention, particularly preferable example is anatase-type titanium dioxide. The metal oxide has the form of microparticles. The primary particle diameter of the microparticles is preferably in a range of from 0.001 to 5 μm, more preferably from 0.001 to 0.5 μm, especially preferably from 0.001 to 0.05 μm.

The binder to be used may be any of binders which can be used to disperse the microparticles and be easily discomposed by irradiation with ultraviolet light. The binder is generally a polymer. Examples of such a polymer include polyalkylene glycol (e.g. polyethylene glycol), acrylic resin, polyester, polyurethane, epoxy resin, silicon resin, fluorocarbon resin, polyvinyl acetate, polyvinyl alcohol, polyacetal, polyvinyl butyral, petroleum resin, polystyrene, and cellulose resin.

Examples of acrylic resin include homopolymers and copolymers made from alkyl acrylate (e.g. methylacrylate, ethylacrylate, butylacrylate) and/or alkyl methacrylate (e.g. methylmethacrylate, ethylmethacrylate, butylmethacrylate). The examples further include copolymers of these monomers with other copolymerizable monomers. In terms of reactivity for photocuring, durability after the photocuring, and transparency, polymethylmethacrylate (PMMA) is especially preferable.

A surfactant may be used as the binder. Examples of such a surfactant include nonionic surfactants such as polyethylene glycol and polypropylene glycol, anionic surfactants, and cationic surfactants. Combinations of the aforementioned polymers with the surfactants may also be used.

Examples of preferable binder include polyalkylene glycol (e.g. polyethylene glycol), polyester, acrylic resin, polyacetal, polyvinyl butyral, petroleum resin, polystyrene, and cellulose resin.

In case of using a glass plate as the substrate, condensation products of tetraalkoxysilane and/or trialkoxysilane may be used for providing well adhesion.

The thickness of the metal oxide semiconductor membrane is generally 0.01 μm or more, preferably from 0.1 to 100 μm, more preferably from 1 to 10 μm.

The substrate 51 may be any of transparent substrates, normally is a glass plate such as a silicate glass or a plastic substrate. Any of various plastic substrates capable of ensuring optical transparency of a visible light may be used. The thickness of the substrate is generally from 0.1 mm to 10 mm, preferably from 0.3 mm to 5 mm. As the glass plate, a glass plate which is chemically or thermally reinforced is preferable.

The material of such a plastic substrate is preferably a transparent organic resin of which glass-transition temperature is 50° C. or more. As such a support, transparent resin substrates mainly composed of organic resins such as polyester resins such as polyethylene terephthalate, polycyclohexylene terephthalate, and polyethylene naphtahalate, polyamide resins such as nylon 46, denatured nylon 6T, nylon MXD6, and polyphthal amide, ketone resins such as polyphenylene sulfide, polythioether sulfone, sulfone resins such as polysulfone, polyether sulfone, and organic resin such as polyether nitrile, polyarylate, polyether imide, polyamide imide, polycarbonate, polymethylmethacrylate, triacetylcellulose, polystyrene, and polyvinyl chloride may be used. Among these, polycarbonate, polymethylmetacrylate, polyvinyl chloride, polystyrene, polyethylene terephthalate can be suitably used because these are excellent in transparency and birefringence.

As the transparent electrode 52, a substrate with a thin membrane of conductive metal oxide such as In₂O₃ and SnO₂ or a substrate made of a conductive material such as metal may be employed. Examples of preferable conductive metal oxides include In₂O₃:Sn (ITO), SnO₂:Sb (ATO), SnO₂:F (FTO), ZnO:Al (AZO), ZnO:F, and CdSnO₄.

The organic dye (spectral sensitizing dye) is adsorbed as monomolecular membrane to the oxide semiconductor membrane surface on the substrate thus obtained.

As for the organic dye (spectral sensitizing dye) for adsorbing as monomolecular membrane to the oxide semiconductor membrane surface on the substrate and the method of adsorbing the organic dye, the same description as made for the third invention can be adopted to this invention.

In this manner, the organic dye-sensitized metal oxide semiconductor electrode (semiconductor for photoelectric conversion material) of the fifth invention is obtained.

A solar cell is manufactured by using an organic dye-sensitized metal oxide semiconductor electrode having a transparent electrode and an organic dye-sensitized metal oxide semiconductor formed thereon. That is, a metal oxide semiconductor membrane for photoelectric conversion material is formed on a substrate such as a glass plate or a plastic substrate which is coated with a transparent electrode (transparent conductive membrane) so as to prepare an electrode. Then, another substrate such as a glass plate, which is coated with a transparent conductive membrane, as a counter electrode is bonded to the electrode by sealing agent. An electrolyte is encapsulated between the electrodes, thereby forming a solar cell.

As the spectral sensitizing dye adsorbed to the semiconductor membrane of the fifth invention is irradiated with sun light, the spectral sensitizing dye adsorbs light in visible light range and is thus excited. Electrons generated by the excitation is moved to the semiconductor and then moved to the counter electrode through the transparent conductive glass electrode. The electrons moved to the counter electrode reduce the oxidation-reduction substance in the electrolyte. On the other hand, the spectral sensitizing dye moving the electrons to the semiconductor is in a state of oxidant. The oxidant is reduced by the oxidation-reduction substance in the electrolyte so that the spectral sensitizing dye returns to its original state. Electrons flow in this manner, thereby constituting a solar cell using a semiconductor for photoelectric conversion material.

The same description about the electrolyte (redox electrode) of the third invention can be adopted to the aforementioned electrolyte (redox electrolyte) of this invention.

Though the oxide semiconductor electrode, the electrolyte, and the counter electrode are housed in a casing and then sealed in the solar cell of the fifth invention, these may be sealed entirely with resin. In this case, the resin sealing is designed so that the oxide semiconductor electrode is exposed to light. In the cell having such a structure, as sun light or visible light similar to the sun light is incident on the oxide semiconductor electrode, a potential difference is generated between the oxide semiconductor electrode and the counter electrode so that current flows between the electrodes.

### EXAMPLES OF THE FIFTH INVENTION

### Example 5-1

(1) Production of Transparent Electrode

A transparent electrode membrane was formed by using a sputtering apparatus.

Sputtering was conducted onto a polycarbonate substrate of 5×5 cm (thickness of 2 mm) for 5 minutes using a ceramic target of ITO (indium-tin oxide) of 100 mmφ while supplying argon gas at 10 cc/minute and oxygen gas at 1.5 cc/minute under conditions that the pressure inside the apparatus was set at 5 mTorr and the supply power was 500 W. In this manner, an ITO membrane having a thickness of 300 nm was formed. The surface resistance was 10 Ω/□.

(2) Production of Metal Oxide Semiconductor Membrane

Anatase-type titanium dioxide (primary particle diameter of 30 nm) was dispersed into a solution consisting of water containing 20% by mass of polyethylene glycol and acetylacetone (capacity ratio: 20/1) so as to obtain dispersion liquid of which titanium dioxide concentration was 30% by mass.

The obtained dispersion liquid was applied onto the ITO membrane of the polycarbonate substrate which was obtained in the above (1) by using a bar coater and was dried at 120° C. for 30 minutes, thereby forming a titanium dioxide containing membrane having a thickness of 10 μm.

The substrate with the titanium dioxide containing membrane was placed with the coating side up inside an ultraviolet irradiation apparatus provided with a high-pressure mercury lamp. After oxygen gas and argon gas were supplied at 5 cc/minute and at 5 cc/minute, respectively, the membrane was irradiated with ultraviolet light from the high-pressure mercury lamp (distance for irradiation: 2 cm, time period for irradiation: 20 minutes), thereby forming a titanium dioxide membrane having a thickness of 10 μm.

The porosity of the obtained semiconductor membrane was measured.

Measuring method of porosity:

The following weights were measured, respectively and the porosity was calculated by the following equation (measurement was conducted according to JISZ8807):
w1: mass of a sample when fully filled with water (g)
w2: absolute dry mass of the sample (g)
w3: buoyancy of the sample (g)
Porosity=(w1−w2)/w3×100

According to the measurement, the porosity of the aforementioned semiconductor membrane was 38%.

(3) Adsorption of Spectral Sensitizing Dye

A spectral sensitizing dye represented by cis-di(thiocyanato)-bis (2,2′-bipyridyl-4-dicarboxylate-4′-tetrabutylammonium carboxylate) ruthenium(II) was dissolved into ethanol solvent. The concentration of the spectral sensitizing dye was 3×10⁻⁴ mole/L. The aforementioned substrate having the titanium oxide membrane formed thereon was entered into the ethanol solution and was soaked at a room temperature for 18 hours, thereby obtaining a metal oxide semiconductor electrode of the present invention. The adsorptive amount of the spectral sensitizing dye was 10 μg per 1 cm² specific area of the titanium oxide membrane.

(4) Production of Solar Cell

The aforementioned metal oxide semiconductor electrode was used as one of the electrodes. As a counter electrode, a transparent conductive glass plate, coated with fluorine-doped tin oxide and carrying platinum thereon, was used. An electrolyte was sandwiched between the two electrodes. The sides of the lamination were sealed by resin and lead wires were then attached, thereby producing a solar cell of the present invention. It should be noted that the electrolyte was a solution prepared by dissolving lithium iodide, 1,2 dimethyl-3-propylimidazolium iodide, iodine, and t-butylpyridine into acetonitrile solvent such that the respective concentrations were 0.1 mole/L, 0.3 mole/L, 0.05 mol/L, and 0.5 mole/L. As light with intensity of 100 W/m² was incident on the obtained solar cell by a solar simulator, Voc (voltage in open-circuit) was 0.58V, Jsc (density of current flowing in short-circuit) was 1.30 mA/cm², FF (fill factor) was 0.53, η(conversion efficiency) was 4.01%. From the results, it was confirmed that the solar cell is useful.

### Example 5-2

A solar cell was manufactured in the same manner as Example 5-1 except that (2) Production of metal oxide semiconductor membrane was the following.

(2) Production of Metal Oxide Semiconductor Membrane

Instead of the dispersion liquid of Example 5- 1, dispersion liquid of which titanium dioxide concentration was 50% by mass was used. The process of dipping the substrate in the dispersion liquid and drying the substrate was repeated, thereby forming a titanium dioxide containing membrane.

After that, the same treatment as Example 5-1 was conducted.

The porosity of the semiconductor membrane measured in the same manner as Example 5-1 was 38%.

As light with intensity of 100 W/m² was incident on the obtained solar cell by a solar simulator, Voc (voltage in open-circuit) was 0.59V, Jsc (density of current flowing in short-circuit) was 1.31 mA/cm², FF (fill factor) was 0.53, η(conversion efficiency) was 4.12%. From the results, it was confirmed that the solar cell is useful.

As apparent from the above, a solar cell having an organic dye-sensitized metal oxide semiconductor electrode formed by the method of the fourth invention is a solar cell having a metal oxide conductive membrane which can be easily obtained at a relatively low temperature and having significantly increased adsorptive amount of dye. Therefore, the solar cell has high light energy conversion efficiency and thus is provided with sufficient capability as a solar cell.

(6) Sixth Invention.

Embodiments of a method of forming a transparent electrode of the sixth invention will be described with reference to the drawings.

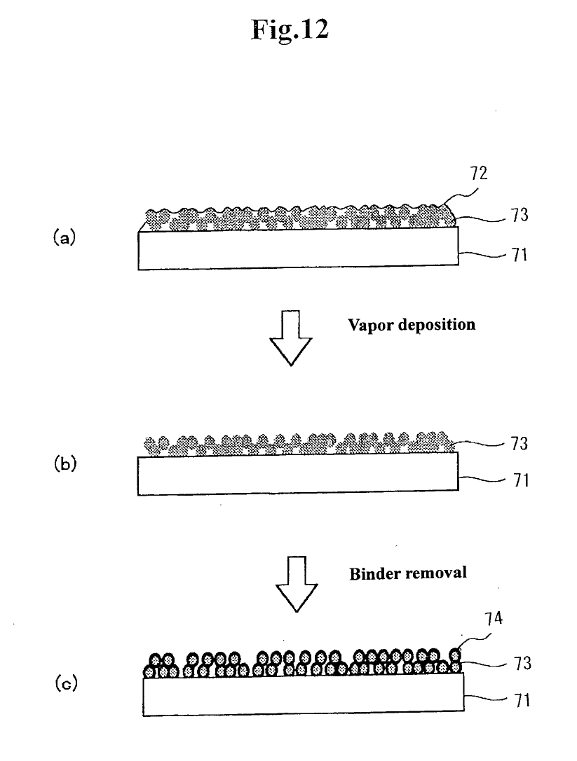

FIG. 12 shows an exemplary schematic drawing for explaining the method of forming a transparent electrode of the sixth invention (6-i). A layer in which conductive metal oxide microparticles 73 are dispersed in a binder 72 is formed on a surface of a transparent substrate 71. By removing the binder 72 from the layer, a coating-type transparent electrode membrane composed of the conductive metal oxide microperticles 73. Then, a vapor deposition-type transparent electrode membrane 74 of a conductive metal oxide is formed on a surface of the coating-type transparent electrode membrane by vapor deposition.

In the coating-type transparent electrode membrane, binder portions become cavities because the binder is removed from the layer of conductive metal oxide microparticles dispersed in the binder so that the layer becomes a layer formed by bonds of the conductive metal oxide microparticles 73. That is, the coating-type transparent electrode membrane has a rough surface having a large surface area. The vapor deposition-type transparent electrode membrane 74 is formed on the coating-type transparent electrode membrane having numerous cavities as mentioned above. The membrane formed by the vapor deposition not only extend over the exposed portions on the surface of the coating-type transparent electrode membrane 73 but also enter into the cavities so that the vapor deposition-type transparent electrode membrane 74 covers substantially all of the exposed portions of the coating-type transparent electrode membrane 73 while maintaining the numerous cavities. Therefore, if there are breakages created by removing the binder, the breakages are connected so as to allow the flow of electric current over the entire transparent electrode (that is, the lamination-type transparent electrode membrane). Therefore, a transparent electrode having low resistance and a large surface area can be obtained. Since the metal oxide semiconductor membrane provided on the rough surface of the transparent electrode has therefore naturally a large surface area, a large amount of organic dye is adsorbed on the surface of the semiconductor membrane. Accordingly, an organic dye-sensitized solar cell using this organic dye-sensitized metal oxide semiconductor electrode can exhibit high light energy conversion efficiency.

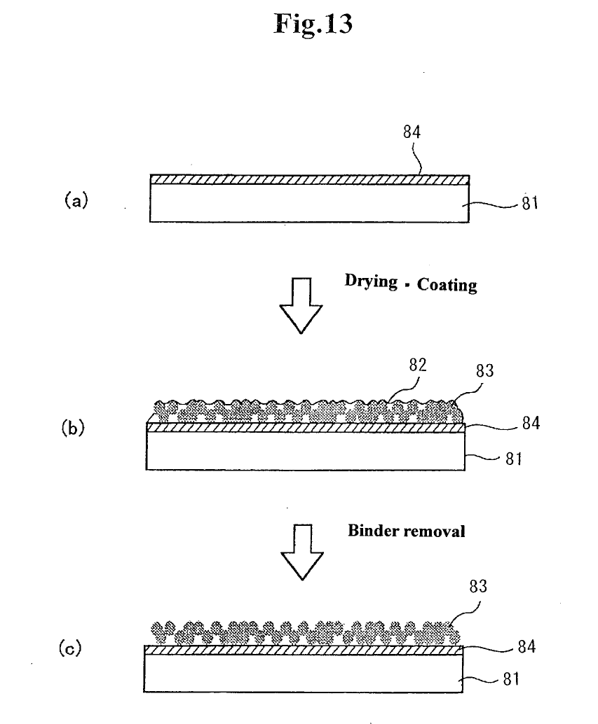

FIG. 13 shows an exemplary schematic drawing for explaining the method of forming a transparent electrode of the sixth invention (6-ii). A vapor deposition-type transparent electrode membrane 84 of conductive metal oxide is formed on a transparent substrate 81 by vapor deposition. Coating liquid in which conductive metal oxide microperticles 83 are dispersed in a binder 82 is applied to a surface of the transparent electrode membrane 84 and is dried so as to form a conductive metal oxide containing coating. Then, the binder is removed from the conductive metal oxide containing coating, thereby forming a coating-type transparent electrode membrane composed of the conductive metal oxide microparticles 83.

The vapor deposition-type transparent electrode membrane 84 directly formed on the transparent substrate is a conventional transparent electrode of which surface is generally flat and smooth. On the other hand, in the coating-type transparent electrode membrane formed on the vapor deposition-type transparent electrode membrane 84, binder portions become cavities because the binder is removed from the layer of conductive metal oxide microparticles dispersed in the binder so that the layer becomes a layer formed by bonds of the conductive metal oxide microparticles 83. Accordingly, the coating-type transparent electrode membrane has a rough surface having a large surface area. Since the metal oxide semiconductor membrane provided on the rough surface has therefore a large surface area, a large amount of organic dye is adsorbed on the surface of the semiconductor membrane. Accordingly, an organic dye-sensitized solar cell using this organic dye-sensitized metal oxide semiconductor electrode can exhibit high light energy conversion efficiency.

In either of the above methods (6-i) and (6-ii), the transparent electrode can be formed at a relatively low temperature, the transparent electrode may be made of a material, which has low resistance and is poor in thermal resistance, such as ITO.

In the above method, the removal of the binder 72, 82 (generally, an organic substance such as polymer and surfactant) from the coating is normally conducted by plasma treatment or ultraviolet irradiation treatment. The binder reacts with cations, anions, radicals in plasma so that the binder is decomposed and is thus removed. Plasma is generated by applying an electric field to reactive gas introduced in a plasma generator to bring gas molecules to collide with high-speed electrons so as to ionize the electrons. The removal of the binder is generally conducted in a reactive gas such as oxygen, fluorine, and chlorine gases. Ions and radicals generated from such a reactive gas react with the binder and decompose the binder. Since this reaction can be conducted at a relatively low temperature, the transparent electrode and the substrate used may be made of a material which are not excellent in thermal resistance (for example, a plastic substrate may be used as the substrate, an ITO may be used as the electrode, and the like).

The aforementioned plasma treatment is preferably conducted by high-frequency plasma, microwave plasma, or a hybrid type thereof. As the plasma is conducted under reduced pressure, the ionization rate is increased and the directional property of ions becomes anisotropy, thereby achieving the uniform removal of the binder. However, if the pressure is reduced in high-frequency discharge (13.56 MHz, 2.45 GHz), the number of collisions between electrons and gas molecules is reduced. In this case, a method of applying electrostatic or inductive electric field is employed in order to improve plasma density (for example, magnetron discharge, ECR discharge, helicon wave discharge, inductive coupling discharge, and the like). Also in this invention, it is preferable to employ high-frequency plasma or microwave plasma with electric field.

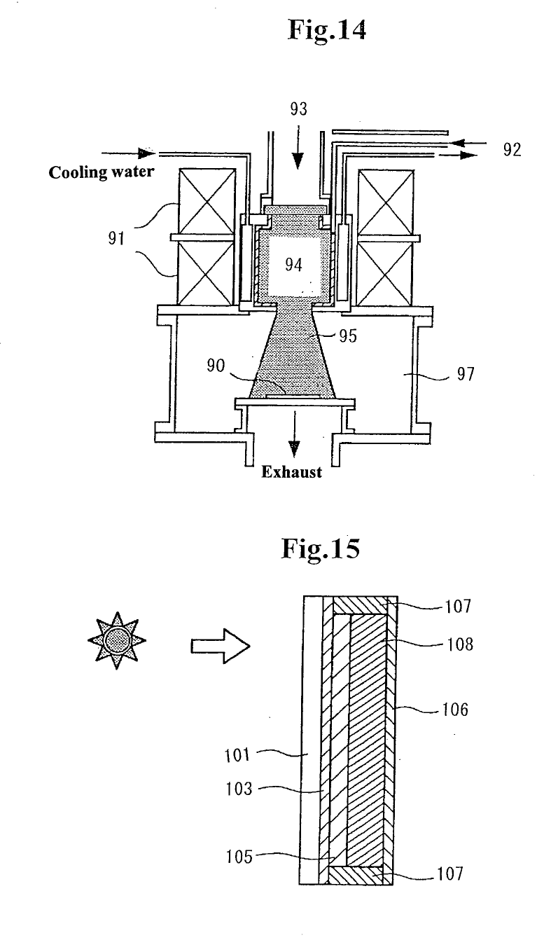

For example, binder is removed from a coating on a substrate by using an ECR plasma generator shown in FIG. 14. A substrate 90 having a coating is placed in a lower portion of an etching chamber 97 and exhaust is removed below the portion where the substrate 90 is placed. Reactive gas 92 is introduced from an upper portion and microwaves 93 are introduced from the middle of the upper portion. The microwaves 93 are introduced into the reactive gas within magnetic fields generated by magnet coils 91 so as to generate plasma. The plasma flow 95 collides with the substrate, thereby decomposing and removing the binder and the like from the coating.

In the plasma treatment, the pressure is preferably set to 10⁻³ Torr or less, especially from 10⁻³ Torr to 10⁻⁴ Torr.

Alternatively, the removal of the binder from the coating may be conducted by ultraviolet irradiation treatment. In this case, the binder of the coating is decomposed into low-molecular substances (organic acids, carbon dioxide, and the like) by irradiation with ultraviolet light and thus removed. To decompose the binder into low-molecular substances, the ultraviolet light to be used is preferably short-wavelength ultraviolet light, generally in a range of from 1 to 400 nm, preferably from 1 to 300 nm, especially from 1 to 200 nm. Therefore, the binder can be quickly removed at a relatively low temperature.

As the mechanism for decomposing the binder (organic matter),
(1) as the binder is irradiated with ultraviolet light, the binder adsorbs the ultraviolet light so that the molecular bonds constructing the binder are directly cut, and
(2) atmospheric gas is decomposed by energy of ultraviolet light to generate radicals whereby the binder is decomposed by the radicals (in this case, gas containing O, F, Cl or the like is effectively used).

As an example of the above (2), irradiation of short-wavelength ultraviolet light on the order of 185 nm generates radials having high oxidizing force (for example, OH—) so as to decompose the binder. For generating radicals having high oxidizing force, the irradiation is conducted in a reactive gas containing a compound such as oxygen, fluorine atom containing compound (for example, CF₄) or chlorine atom containing compound. The radicals generated in such a reactive gas react with the binder and decompose the binder. Since this reaction can be conducted at a relatively low temperature, the transparent electrode and the substrate used may be made of a material which is not excellent in thermal resistance (for example, a plastic substrate may be used as the substrate, an ITO may be used as the electrode, and the like).

The binder to be used is preferably easily discomposed by irradiation with ultraviolet light. The preferable binder generally contains or easily generates a carbonyl group, a hydroperoxide group, and the like. Examples of the preferable binder will be described later.

As for an ultraviolet light lamp to be used for ultraviolet light irradiation, the same description about the ultraviolet light lamp to be used for ultraviolet light irradiation in the fifth invention will be adopted.

The coating, which mainly consists of the metal oxide microparticles and the binder and is formed on the transparent substrate, is irradiated with ultraviolet light by an ultraviolet light lamp. To promote the decomposition of the binder, it is preferable to irradiate the coating with ultraviolet light in a state that the aforementioned reactive gas exists between the coating and the lamp as mentioned above. As a preferable combination of the kind of a binder (organic polymer), the reactive gas, and the like, it is preferable that a polyester resin is used as the binder and a high-pressure mercury lamp is used in atmosphere of ozone, Cl₂, CF₄, or the like to decompose the binder.

The substrate which can be used in this invention may be any of transparent substrates, generally is a glass plate, normally a silicate glass or a plastic substrate. Any of various plastic substrates capable of ensuring optical transparency of a visible light may be used. The thickness of the substrate is generally from 0.1 mm to 10 mm, preferably from 0.3 mm to 5 mm. As the glass plate, a glass plate which is chemically or thermally reinforced is preferable. In case of using a glass plate as the substrate, condensation products of tetraalkoxysilane and/or trialkoxysilane may be used for providing well adhesion. It should be noted that the substrate 46 of the solar cell as will be described may not be transparent.

As for the material of the aforementioned plastic substrate, the same description about the plastic substrate in the fifth invention is adopted.

As the material of the transparent electrode, conductive metal oxide is used in either of the vapor deposition and the coating method Examples of preferable conductive metal oxides include In₂O₃: Sn(ITO), SnO₂:Sb, SnO₂:F, ZnO:Al, SnO₂, ZnO:F, and CdSnO₄. As the substrate with a vapor deposition-type transparent electrode, a substrate with a thin membrane of conductive metal oxide such as In₂O₃ and SnO₂ or a substrate made of a conductive material such as metal may be employed.

In formation of the coating-type transparent electrode membrane, the conductive metal oxide is used in the form of microparticles. The mean primary particle diameter of the conductive metal oxide microparticles is preferably in a range of from 0.001 to 5 μm, especially preferably from 0.001 to 0.05 μm.

The binder may be any of binders which can be used to disperse the microparticles. The binder is generally an organic polymer. Examples of such a polymer include polyalkylene glycol (e.g. polyethylene glycol), acrylic resin, polyester, polyurethane, epoxy resin, silicon resin, fluorocarbon resin, polyvinyl acetate, polyvinyl alcohol, polyacetal, polyvinyl butyral, petroleum resin, polystyrene, and cellulose resin.

As for the acrylic resin of the binder and the surfactant to be used as the binder, the same description about these in the fifth invention is adopted.

The coating liquid in which the conductive metal oxide microparticles are dispersed in the binder is prepared by mixing the aforementioned materials. If necessary, the microparticles are dispersed by kneading. The content of the microparticles in the coating liquid is preferably from 20% to 60% by mass, especially from 20% to 50% by mass. The content of the binder in the coating liquid is from 1% to 20% by mass, especially from 5% to 10% by mass. Examples of solvent include water, acetylacetone, alcohol, toluene, and methyl formamide. If necessary, an additive such as a surfactant may be further added.

The coating may be conducted by a known method such as a spray coater, a bar coater, and a roll coater. The drying is preferably conducted at ordinary temperature. After that, the binder is removed as mentioned above.

In the lamination-type transparent electrode of the sixth invention, the thickness of the vapor deposition-type transparent electrode membrane is preferably set to a range of from 0.1 to 100 nm, especially from 1 to 10 nm and the thickness of the coating-type transparent electrode membrane is set to a range of from 10 to 500 nm, especially from 100 to 300 nm, in order to ensure cavities and to obtain the large surface area.

FIG. 15 is a sectional view showing an embodiment of the organic dye-sensitized solar cell of the sixth invention.

In FIG. 15, an organic dye-sensitized solar cell comprises a transparent substrate 101, a transparent electrode 103 of this invention formed on the transparent substrate 101, a dye adsorptive metal oxide semiconductor membrane 105 with spectral sensitizing dye adsorbed in a metal oxide semiconductor membrane on the transparent electrode, and a counter electrode 106 formed above the metal oxide semiconductor membrane 105. The counter electrode 106 is arranged at an opposed position to the transparent electrode. An electrolyte (solution) 108 is encapsulated between the metal oxide semiconductor membrane 105 and the counter electrode 106. It should be noted that the metal oxide semiconductor electrode of this invention is basically composed of the substrate 101, the transparent electrode 103 formed thereon, and the metal oxide semiconductor membrane 105 with spectral sensitizing dye adsorbed on the transparent electrode.

The transparent electrode of the sixth invention has the metal oxide semiconductor membrane formed thereon as shown in FIG. 15.

In the metal oxide semiconductor electrode of the sixth invention, the metal oxide semiconductor membrane formed on the transparent electrode on the substrate has a configuration in which spherical particles of various sizes are bonded and has large irregularities on surface thereof and a lot of cavities inside thereof. Though the metal oxide semiconductor membrane of this invention may be formed by applying slurry of the conventional oxide semiconductor fine particles on a transparent electrode, drying the applied slurry, and then baking the dried matter for 1 hour at 500° C. as a conventional manner, the metal oxide semiconductor membrane is preferably formed by vapor deposition for the purpose of reducing heat application.

Since the metal oxide semiconductor membrane of the sixth invention is formed on the transparent electrode having a rough surface mentioned above of this invention, the metal oxide semiconductor membrane has significantly high porosity. The metal oxide semiconductor membrane of this invention is ordinarily formed by vapor deposition and preferably has a rough surface and a porosity of 25% or more. The porosity is preferably 30% or more, particularly 35% or more. According to this configuration, the adsorptive amount of organic dye is increased. Though the upper limit of the porosity may be almost 100% if the adsorbed amount of organic dye is increased, the upper limit is preferably about 95% in terms of maintaining the shape as a membrane.

As mentioned above, the metal oxide semiconductor membrane of the sixth invention has a large surface area of the surface thereof and has a large surface area of cavities inside thereof so that the area in which the organic dye is adsorbed is large. This structure (configuration) facilitates invasion of organic dye on the surface and into inner sides thereof, thereby achieving the dye adsorption in a short period of time. Since the membrane has a large surface area on the surface thereof and a large surface area inside thereof, it has increased adsorbed amount of organic dye, thereby improving the light energy conversion efficiency.

As for the aforementioned metal oxide semiconductor, the same description about the metal oxide semiconductor in the fifth invention is adopted.

The metal oxide semiconductor membrane of this invention can be formed by vapor deposition such as physical deposition, vacuum deposition, sputtering, ion plating, CVD, or plasma CVD, using metal and/or metal oxide corresponding to the used material as a target or targets under the conditions as mentioned above. A preferable method of forming the metal oxide semiconductor membrane of this invention is a sputtering method with a target introduction power density and under a pressure condition as mentioned above. As the sputtering method, a facing targets sputtering method is suitable and a reactive sputtering method is also preferable.

The facing targets sputtering method of the sixth invention is preferably a reactive sputtering method in which metal or metal oxide is sputtered while reactive gas such as oxygen gas is introduced. Especially preferable is a sputtering using titanium metal, titanium oxide, particularly conductive titanium oxide as a target while supplying oxygen gas.

Basically, the metal oxide semiconductor membrane of the sixth invention is preferably formed by short-time film formation with high electric power, film formation at high gas pressure, or a method in which these methods are suitably combined by changing the flow rate of gas mixture or using an arc ion sputtering. A preferable method of forming the metal oxide semiconductor membrane of this invention is a sputtering method with a target introduction power density of 1.3 W/cm² or more, particularly 2.6 W/cm² or more, especially 11 W/cm² or more and under a pressure condition of 0.6 Pa or more, particularly 2.0 Pa or more, especially 2.6 Pa or more. As the sputtering method, a facing targets sputtering method is suitable and a reactive sputtering method is also preferable. By employing the more strict condition than the ordinary sputtering condition, the semiconductor membrane can be rapidly formed, thereby obtaining a metal oxide semiconductor membrane having a specific configuration and structure of this invention. Therefore, the adsorbed amount of organic dye can be significantly increased, thus obtaining a high-efficiency solar cell having high energy conversion efficiency.

Alternatively, the metal oxide semiconductor membrane may be formed by the following method; That is, coating liquid in which metal oxide microparticles are dispersed in the binder is applied onto a surface of the transparent electrode of the sixth invention and is dried so as to form a coating mainly consistings of the metal oxide microparticles and the binder. Then, the binder is removed from the coating by plasma treatment or ultraviolet irradiation treatment and the metal oxide microparticles are bonded, thereby forming a metal oxide semiconductor membrane.

The organic dye (spectral sensitizing dye) is adsorbed as monomolecular membrane to the oxide semiconductor membrane surface on the substrate thus obtained.

As for the organic dye to be adsorbed as monomolecular membrane to the oxide semiconductor membrane surface on the substrate and the adsorbing method thereof, the same description in the third invention is adopted.

In this manner, the organic dye-sensitized metal oxide semiconductor electrode (semiconductor for photoelectric conversion material) of the sixth invention is obtained.

A solar cell is manufactured by using an organic dye-sensitized metal oxide semiconductor electrode having a transparent electrode and an organic dye-sensitized metal oxide semiconductor formed thereon. That is, a metal oxide semiconductor membrane for photoelectric conversion material is formed on a substrate such as a glass plate or a plastic substrate which is coated with a transparent electrode (transparent conductive membrane) so as to prepare an electrode. Then, another substrate such as a glass plate, which is coated with a transparent conductive membrane, as a counter electrode is bonded to the electrode by sealing agent. An electrolyte is encapsulated between the electrodes, thereby forming a solar cell.

As the spectral sensitizing dye adsorbed to the semiconductor membrane of the sixth invention is irradiated with sun light, the spectral sensitizing dye adsorbs light in visible light range and is thus excited. Electrons generated by the excitation is moved to the semiconductor and then moved to the counter electrode through the transparent conductive glass electrode. The electrons moved to the counter electrode reduce the oxidation-reduction substance in the electrolyte. On the other hand, the spectral sensitizing dye moving the electrons to the semiconductor is in a state of oxidant. The oxidant is reduced by the oxidation-reduction substance in the electrolyte so that the spectral sensitizing dye returns to its original state. Electrons flow in this manner, thereby constituting a solar cell using a semiconductor for photoelectric conversion material.

The same description about the electrolyte (redox electrolyte) of the third invention can be adopted to the aforementioned electrolyte (redox electrolyte) of this invention.

Though the oxide semiconductor electrode, the electrolyte, and the counter electrode are housed in a casing and then sealed in the solar cell of the sixth invention, these may be sealed entirely with resin. In this case, the resin sealing is designed so that the oxide semiconductor electrode is exposed to light. In the cell having such a structure, as sun light or visible light similar to the sun light is incident on the oxide semiconductor electrode, a potential difference is generated between the oxide semiconductor electrode and the counter electrode so that current flows between the electrodes.

### EXAMPLES OF THE SIXTH INVENTION

### Example 6-1

(1) Production of Transparent Electrode

A lamination-type transparent electrode membrane was formed as follows.

1) ITO (indium-tin oxide) microparticles (mean particle diameter of 0.05 nm) was dispersed into a solution consisting of water containing 20% by mass of polyethylene glycol and acetylacetone (capacity ratio: 20/1) so as to obtain dispersion liquid of which ITO concentration was 30% by mass.

The obtained dispersion liquid was applied onto a polycarbonate substrate of 5×5 cm (thickness of 2 mm) by using a bar coater and was dried at 120° C. for 30 minutes, thereby forming an ITO coating having a thickness of 300 nm.

The substrate was placed with the ITO coating side up inside a chamber of a plasma generator as shown in FIG. 15. After oxygen gas and argon gas were supplied at 5 cc/minute and at 5 cc/minute, respectively, the pressure inside the generator was set to 1 mTorr (0.13 Pa). Plasma treatment was conducted for 60 minutes under conditions that the introduction microwaves was 2.45 GHz, magnetic attraction was 875 gausses, supply power was 3 kW (power density 19 W/cm²) so as to remove the polyethylene glycol, thereby forming a coating-type ITO membrane having a thickness of 100 nm.

2) Sputtering was conducted onto the obtained coating-type ITO membrane for 5 minutes using a ceramic target of ITO of 100 mmφ while supplying argon gas at 10 cc/minute and oxygen gas at 1.5 cc/minute under conditions that the pressure inside the apparatus was set at 5 mTorr and the supply power was 500 W. In this manner, a vapor deposition-type ITO membrane having a thickness of 100 nm was formed. The surface resistance was 10 Ω/□.

The porosity of the obtained transparent electrode was measured.

Measuring method of porosity:

The following weights were measured, respectively and the porosity was calculated by the following equation (measurement was conducted according to JISZ8807):
w1: mass of a sample when fully filled with water (g)
w2: absolute dry mass of the sample (g)
w3: buoyancy of the sample (g)
Porosity=(w1−w2)/w3×100

According to the measurement, the porosity of the aforementioned transparent electrode was 38%.

(2) Production of Metal Oxide Semiconductor Membrane

A facing targets sputtering apparatus was used and two targets of titanium metal having a diameter of 100 mm were placed on the ITO transparent electrode glass plate in the apparatus. After oxygen gas and argon gas were supplied at 5 cc/minute and at 5 cc/minute, respectively, sputtering was conducted for 32 minutes under conditions that the pressure inside the apparatus was set at 5 mTorr (0.7 Pa) and the supply power was 3 kW (power density of 19 W/cm²), thereby forming a titanium oxide membrane having a thickness of 300 nm.

The porosity of the obtained semiconductor membrane was measured in the same manner as the above (1).

The porosity of the aforementioned semiconductor membrane was 42%.

(3) Adsorption of Spectral Sensitizing Dye

A spectral sensitizing dye represented by cis-di(thiocyanato)-bis (2,2′-bipyridyl-4-dicarboxylate-4′-tetrabutylammonium carboxylate) ruthenium(II) was dissolved into ethanol solvent. The concentration of the spectral sensitizing dye was 3×10⁻⁴ mole/L. The aforementioned substrate having the titanium oxide membrane formed thereon was entered into the ethanol solution and was soaked at a room temperature for 18 hours, thereby obtaining a metal oxide semiconductor electrode of the present invention. The adsorptive amount of the spectral sensitizing dye was 10 μg per 1 cm² specific area of the titanium oxide membrane.

(4) Production of Solar Cell

The aforementioned metal oxide semiconductor electrode was used as one of the electrodes. As a counter electrode, a transparent conductive glass plate, coated with fluorine-doped tin oxide and carrying platinum thereon, was used. An electrolyte was sandwiched between the two electrodes. The sides of the lamination were sealed by resin and lead wires were then attached, thereby producing a solar cell of this invention. It should be noted that the electrolyte was a solution prepared by dissolving lithium iodide, 1,2 dimethyl-3-propylimidazolium iodide, iodine, and t-butylpyridine into acetonitrile solvent such that the respective concentrations were 0.1 mole/L, 0.3 mole/L, 0.05 mol/L, and 0.5 mole/L. As light with intensity of 100 W/m² was incident on the obtained solar cell by a solar simulator, Voc (voltage in open-circuit) was 0.58V, Jsc (density of current flowing in short-circuit) was 1.30 mA/cm², FF (fill factor) was 0.53, η(conversion efficiency) was 4.01%. From the results, it was confirmed that the solar cell is useful.

### Example 6-2

A solar cell was produced in the same manner as Example 6-1 except that (1) Production of transparent electrode was the following.

(1) Production of Transparent Electrode

A lamination-type transparent electrode membrane was produced as follows.

1) Sputtering was conducted for 5 minutes using a ceramic target of ITO (indium-tin oxide) of 100 mmφ on a polycarbonate substrate of 5×5 cm (thickness of 2 mm) while supplying argon gas at 10 cc/minute and oxygen gas at 1.5 cc/minute under conditions that the pressure inside the apparatus was set at 5 mTorr and the supply power was 500 W, thereby forming a vapor deposition-type ITO membrane having a thickness of 100 nm.

2) ITO (indium-tin oxide) microparticles (mean particle diameter of 0.05 nm) was dispersed into a solution consisting of water containing 20% by mass of polyethylene glycol and acetylacetone (capacity ratio: 20/1) so as to obtain dispersion liquid of which ITO concentration was 30% by mass.

The obtained dispersion liquid was applied onto the obtained vapor deposition-type ITO membrane by using a bar coater and was dried at 120° C. for 30 minutes, thereby forming an ITO coating having a thickness of 300 nm.

The substrate was placed with the ITO coating side up inside an ultraviolet irradiation apparatus provided with a high-pressure mercury lamp. After oxygen gas and argon gas were supplied at 5 cc/minute and at 5 cc/minute, respectively, the coating was irradiated with ultraviolet light from the high-pressure mercury lamp (distance for irradiation: 2 cm, time period for irradiation: 20 minutes), thereby forming a coating-type ITO membrane having a thickness of 300 nm. The surface resistance was 10 Ω/□.

The porosity of the obtained transparent electrode was measured.

Measuring method of porosity:

The following weights were measured, respectively and the porosity was calculated by the following equation (measurement was conducted according to JISZ8807):
w1: mass of a sample when fully filled with water (g)
w2: absolute dry mass of the sample (g)
w3: buoyancy of the sample (g)
Porosity=(w1−w2)/w3×100

According to the measurement, the porosity of the aforementioned transparent electrode was 38%.

After that, the same treatment as Example 6-1 was conducted.

The porosity of the semiconductor membrane measured in the same manner as Example 6-1 was 42%.

As light with intensity of 100 W/m² was incident on the obtained solar cell by a solar simulator, Voc (voltage in open-circuit) was 0.59V, Jsc (density of current flowing in short-circuit) was 1.31 mA/cm², FF (fill factor) was 0.53, i(conversion efficiency) was 4.12%. From the results, it was confirmed that the solar cell is useful.

### Comparative Example 6-1

A solar cell was produced in the same manner as Example 6-1 except that production of transparent electrode and production of metal oxide semiconductor membrane were the following.

(1) Production of Transparent Electrode

A transparent electrode membrane was produced by using a sputtering apparatus.

Sputtering was conducted for 5 minutes using a ceramic target of ITO (indium-tin oxide) of 100 mmφ on a glass substrate of 5×5 cm (thickness of 2 mm) while supplying argon gas at 10 cc/minute and oxygen gas at 1.5 cc/minute under conditions that the pressure inside the apparatus was set at 5 mTorr and the supply power was 500 W. In this manner, an ITO membrane having a thickness of 3000 nm was formed. The surface resistance was 10 Ω/□.

(2) Production of Metal Oxide Semiconductor Membrane

6 g of titanium oxide powder (P-25, available from Nippon Aerogel Co., Ltd.) was uniformly dispersed in a solution consisting of 2 ml of deionized water, 0.2 ml of acetylacetone, and 0.2 ml of a surfactant. This coating liquid was applied to the ITO transparent electrode and was baked at 500° C. for 1 hour, thereby obtaining a semiconductor electrode having a thickness of 10 μm.

The adsorptive amount of the spectral sensitizing dye in the semiconductor was 10 μg per cm² specific area of the titanium oxide.

The porosity measured in the same manner as Example 6-1 was 38%.

As light with intensity of 100 W/m² was incident on the obtained solar cell by a solar simulator, Voc (voltage in open-circuit) was 0.62V, Jsc (density of current flowing in short-circuit) was 1.00 mA/cm², FF (fill factor) was 0.56, η(conversion efficiency) was 3.50%. From the results, it was found that the solar cell has lower conversion efficiency as compared to the solar cells of the aforementioned examples so that it can be hardly said that the solar cell is useful. This may be because the transparent electrode was deteriorated due to a prolonged period of high-temperature baking.

As apparent from the above, a transparent electrode formed by the method of the sixth invention can be obtained at a relatively low temperature, has a low resistance, and has a large surface area because of numerous cavities. Therefore, a metal oxide semiconductor electrode using the transparent electrode has a large surface area. Further, a solar cell having an organic dye-sensitized metal oxide semiconductor electrode thus produced can be easily obtained at a relatively low temperature and has significantly increased adsorptive amount of dye.

the solar cell has high light energy conversion efficiency and thus is provided with sufficient capability as a solar cell.

1. An electrolyte for dye-sensitized solar cells, wherein an oxidation-reduction substance is carried by a vulcanized rubber.

2. An electrolyte for dye-sensitized solar cells as claimed in claim 1, wherein the vulcanized rubber is manufactured using sulfur and/or an organic sulfur compound as a vulcanizing agent.

3. An electrolyte for dye-sensitized solar cells as claimed in claim 1, wherein the vulcanized rubber has, as side chains, an aromatic ring.

4. An electrolyte for dye-sensitized solar cells as claimed in claim 3, wherein the aromatic ring is a benzene ring and/or a pyridine ring.

5. An electrolyte for dye-sensitized solar cells as claimed in claim 1, wherein the vulcanized rubber is impregnated with a solution of the oxidation-reduction substance and is dried, thereby carrying the oxidation-reduction substance.

6. An electrolyte for dye-sensitized solar cells as claimed in claim 1, wherein the carried amount of the oxidation-reduction substance is from 5 to 50% by weight relative to the vulcanized rubber.

7. An electrolyte for dye-sensitized solar cells, wherein an oxidation-reduction substance is carried by a porous body comprising a high molecular material which has a three-dimensional continuous network skeleton structure.

8. An electrolyte for dye-sensitized solar cells as claimed in claim 7, wherein the porous body is made by mixing a high molecular material and a low molecular material in an amount much more than the high molecular material to obtain a precursor in which the high molecular material forms a three-dimensional continuous network skeleton structure, and removing the low molecular material from the precursor.

9. An electrolyte for dye-sensitized solar cells as claimed in claim 7, wherein the high molecular material is an ethylene-propylene copolymer mainly consisting of ethylene and propylene, wherein the content of ethylene is 60% by weight or more.

10. An electrolyte for dye-sensitized solar cells as claimed in claim 8, wherein the percentage of the high molecular material in the mixture consisting of the high molecular material and the low molecular material is 30% by weight or less.

11. An electrolyte for dye-sensitized solar cells as claimed in claim 7, wherein the average diameter of the skeleton of the three-dimensional continuous network skeleton structure of the porous body is 8 μm or less, and the average diameter of the opening of the network is 80 μm or less.

12. An electrolyte for dye-sensitized solar cells as claimed in claim 7, wherein the porous body is impregnated with a solution of the oxidation-reduction substance and is dried, thereby carrying the oxidation-reduction substance.

13. An electrolyte for dye-sensitized solar cells as claimed in claim 7, wherein the carried amount of the oxidation-reduction substance is from 5 to 90% by weight relative to the porous body.

14. An electrolyte for dye-sensitized solar cells, wherein an oxidation-reduction substance is carried by a phosphazene polymer.

15. An electrolyte for dye-sensitized solar cells as claimed in claim 14, wherein the phosphazene polymer is prepared by polymerizing chain phosphazene derivatives expressed by a general formula (1): (R¹)₃P═N—X (in the general formula (1), R¹ represents a monovalent substituent group or a halogen element. “X” represents an organic group containing at least one kind of element selected from a group consisting of carbon, silicon, germanium, tin, nitrogen, phosphorus, oxygen, and sulfur.).

16. An electrolyte for dye-sensitized solar cells as claimed in claim 14, wherein the phosphazene polymer is prepared by polymerizing cyclic phosphazene derivatives expressed by a following general formula (2): (PNR²₂)ₙ (in the general formula (2), R² represents a monovalent substituent group or a halogen element. “n” represents a number from 2 to 14.).

17. An electrolyte for dye-sensitized solar cells as claimed in claim 14, wherein the phosphazene polymer obtained has 100,000 or more molecules.

18. An electrolyte for dye-sensitized solar cells as claimed in claim 14, wherein the phosphazene polymer is impregnated with a solution of the oxidation-reduction substance and is dried, thereby carrying the oxidation-reduction substance.

19. An electrolyte for dye-sensitized solar cells as claimed in claim 14, wherein the carried amount of the oxidation-reduction substance is from 5 to 90% by weight relative to the phosphazene polymer.

20. An electrolyte for dye-sensitized solar cells, wherein the electrolyte comprises an ethylene vinyl acetate copolymer resin film carrying an oxidation-reduction substance.

21. An electrolyte for dye-sensitized solar cells as claimed in claim 20, wherein the ethylene vinyl acetate copolymer resin film contains a cross-linking agent.

22. An electrolyte for dye-sensitized solar cells as claimed in claim 20, wherein the content of vinyl acetate in the ethylene vinyl acetate copolymer resin is from 5% to 50% by weight.

23. An electrolyte for dye-sensitized solar cells as claimed in claim 20, wherein the electrolyte is made by forming the ethylene vinyl acetate copolymer resin containing the oxidation-reduction substance into a film.

24. An electrolyte for dye-sensitized solar cells as claimed in claim 20, wherein the ethylene vinyl acetate copolymer resin film is impregnated with a solution of the oxidation-reduction substance and is dried, thereby carrying the oxidation-reduction substance.

25. An electrolyte for dye-sensitized solar cells as claimed in claim 20, wherein the carried amount of the oxidation-reduction substance is from 5 to 50% by weight relative to the ethylene vinyl acetate copolymer resin.

26. A dye-sensitized solar cell comprising a dye-sensitized semiconductor electrode, a counter electrode arranged at an opposed position to the dye-sensitized semiconductor electrode, and a solid electrolyte arranged between the dye-sensitized semiconductor electrode and the counter electrode, wherein the solid electrolyte is an electrolyte for dye-sensitized solar cells as claimed in claim 1.

27. A method of manufacturing an electrode for dye-sensitized solar cells including a step of forming a titanium oxide thin membrane on a substrate, wherein
the titanium oxide thin membrane is formed by reactive sputtering using a Ti metal target.

28. A method of manufacturing an electrode for dye-sensitized solar cells as claimed in claim 27, wherein TiOₓ (x<2) thin membrane is formed by reactive sputtering in atmosphere with controlled oxygen concentration.

29. A method of manufacturing an electrode for dye-sensitized solar cells as claimed in claim 28, wherein the oxygen concentration is controlled by plasma emission control.

30. A method of manufacturing an electrode for dye-sensitized solar cells as claimed in claim 28, wherein the oxygen concentration is controlled by plasma impedance control.

31. A method of manufacturing an electrode for dye-sensitized solar cells as claimed in claim 27, wherein the reactive sputtering is conducted by using a dual cathode system and by alternately applying voltage to two cathodes arranged in parallel.

32. A method of manufacturing an electrode for dye-sensitized solar cells as claimed in claim 27, wherein the substrate is an organic resin film.

33. An electrode for dye-sensitized solar cells manufactured by a method as claimed in claim 27.

34. An electrode for dye-sensitized solar cells comprising a titanium oxide thin membrane on an organic resin film, wherein the titanium oxide thin membrane is formed by a reactive sputtering using a Ti metal target.

35. An electrode for dye-sensitized solar cells as claimed in claim 33, wherein the titanium oxide thin membrane is a TiOₓ (x<2) thin membrane.

36. An organic dye-sensitized solar cell comprising a transparent substrate having a transparent electrode on a surface thereof, an organic dye-sensitized metal oxide semiconductor electrode having a metal oxide semiconductor membrane formed on the transparent electrode and organic dye adsorbed in a surface of the semiconductor membrane, a counter electrode arranged at an opposed position to the electrode, and a redox electrolyte filled between these electrodes, wherein
an antireflective membrane is formed on a surface of said transparent substrate at a side where no transparent electrode is formed.

37. An organic dye-sensitized solar cell comprising a transparent substrate having a transparent electrode on a surface thereof, an organic dye-sensitized metal oxide semiconductor electrode having a metal oxide semiconductor membrane formed on the transparent electrode and organic dye adsorbed in a surface of the semiconductor membrane, a counter electrode arranged at an opposed position to the electrode, and a redox electrolyte filled between these electrodes, wherein
an antireflective film having an antireflective membrane is attached to a surface of said transparent substrate at a side where no transparent electrode is formed via an adhesive layer.

38. An organic dye-sensitized solar cell as claimed in claim 36, wherein the antireflective membrane reduces the reflectance in a wavelength in which the absorbancy of the organic dye is maximum.

39. An organic dye-sensitized solar cell as claimed in claim 36, wherein the antireflective membrane has minimum reflectance in a wavelength in which the absorbancy of the organic dye is maximum.

40. An organic dye-sensitized solar cell as claimed in claim 37, wherein the antireflective membrane comprises a transparent polymer film and an antireflective membrane formed on the transparent polymer film.

41. An organic dye-sensitized solar cell as claimed in claim 36, wherein said antireflective film is an inorganic laminated membrane consisting of, in top-to-bottom order, low-refractive transparent inorganic thin membrane(s) and high-refractive transparent inorganic thin membrane(s) which are alternately laminated.

42. An organic dye-sensitized solar cell as claimed in claim 41, wherein a low-refractive transparent organic thin membrane is provided instead of the upper-most low-refractive transparent inorganic thin membrane.

43. An organic dye-sensitized solar cell as claimed in claim 37, wherein said antireflective film has an ultraviolet protection layer between the transparent polymer film and the antireflective membrane formed on the transparent polymer film.

44. An organic dye-sensitized solar cell as claimed in claim 41, wherein said high-refractive transparent inorganic thin membrane is a thin membrane having refractive index of 1.8 or more made of ITO (indium tin oxide), ZnO, Al-doped ZnO, Al-doped TiO₂, Al-doped SnO₂, or ZrO.

45. An organic dye-sensitized solar cell as claimed in claim 41, wherein said low-refractive transparent inorganic thin membrane is a thin membrane having refractive index of 1.6 or less made of SiO₂, MgF₂, or Al₂O₃.

46. An organic dye-sensitized solar cell as claimed in claim 37, wherein said adhesive layer contains ethylene-vinyl acetate copolymer or sticky acrylic resin.

47. An organic dye-sensitized solar cell as claimed in claim 37, wherein the metal oxide semiconductor membrane is formed by the vapor deposition.

48. An organic dye-sensitized solar cell as claimed in claim 47, wherein the vapor deposition is physical deposition, vacuum deposition, sputtering, ion plating, CVD, or plasma CVD.

49. An organic dye-sensitized solar cell as claimed in claim 48, wherein the vapor deposition is a facing targets sputtering method or a dual cathode type sputtering method.

50. An organic dye-sensitized solar cell as claimed in claim 48, wherein the vapor deposition is a reactive sputtering method.

51. An organic dye-sensitized solar cell as claimed in claim 36, wherein the metal oxide semiconductor membrane is made of titanium oxide, zinc oxide, tin oxide, antimony oxide, niobium oxide, tungsten oxide, indium oxide, or any of these metal oxides doped with other metal or other metal oxide.

52. An organic dye-sensitized solar cell as claimed in claim 36, wherein the metal oxide semiconductor membrane is made of titanium oxide.

53. An organic dye-sensitized solar cell as claimed in claim 52, wherein the metal oxide semiconductor membrane is made of anatase-type titanium dioxide.

54. An organic dye-sensitized solar cell as claimed in claim 36, wherein the thickness of the metal oxide semiconductor membrane is 10 nm or more.

55. An organic dye-sensitized solar cell as claimed in claim 36, wherein the organic dye is a ruthenium containing dye (ruthenium phenanthroline, ruthenium diketonate) and the antireflective membrane has a light reflectance of 10% or less in a range of wavelength from 300 to 600 nm.

56. An organic dye-sensitized solar cell as claimed in claim 36, wherein the organic dye is a coumarin derivative dye and the antireflective membrane has a light reflectance of 10% or less in a range of wavelength from 400 to 600 nm.

57. An organic dye-sensitized solar cell comprising a transparent substrate having a transparent electrode on a surface thereof, an organic dye-sensitized metal oxide semiconductor electrode having a metal oxide semiconductor membrane formed on the transparent electrode and organic dye adsorbed in a surface of the semiconductor membrane, a counter electrode arranged at an opposed position to the electrode, and a redox electrolyte filled between these electrodes, wherein
the transparent substrate is a transparent organic polymer substrate and the counter electrode is formed on an organic polymer substrate.

58. An organic dye-sensitized solar cell as claimed in claim 57, wherein a transparent electrode is provided between the counter electrode and the organic polymer substrate.

59. An organic dye-sensitized solar cell as claimed in claim 57, wherein the organic polymer substrate having the counter electrode has a high reflectance.

60. An organic dye-sensitized solar cell as claimed in claim 57, wherein the organic polymer substrate having the counter electrode has a pattern or is colored.

61. An organic dye-sensitized solar cell as claimed in claim 57, wherein the organic polymer substrate having the counter electrode is a transparent substrate.

62. An organic dye-sensitized solar cell as claimed in claim 57, wherein the material of the transparent organic polymer substrate or the organic polymer substrate is polyethylene terephthalate, polycarbonate, polymethyl methacrylate, or fluorocarbon resin.

63. An organic dye-sensitized solar cell as claimed in claim 57, wherein the metal oxide semiconductor membrane is formed by vapor deposition.

64. An organic dye-sensitized solar cell as claimed in claim 63, wherein the vapor deposition is physical deposition, vacuum deposition, sputtering, ion plating, CVD, or plasma CVD.

65. An organic dye-sensitized solar cell as claimed in claim 64, wherein the vapor deposition is a facing targets sputtering method, a dual cathode type sputtering method, or a reactive sputtering method.

66. An organic dye-sensitized solar cell as claimed in claim 57, wherein the metal oxide semiconductor membrane is made of titanium oxide, zinc oxide, tin oxide, antimony oxide, niobium oxide, tungsten oxide, indium oxide, or any of these metal oxides doped with other metal or other metal oxide.

67. An organic dye-sensitized solar cell as claimed in claim 66, wherein the metal oxide semiconductor membrane is made of titanium oxide.

68. An organic dye-sensitized solar cell as claimed in claim 67, wherein the metal oxide semiconductor membrane is made of anatase-type titanium dioxide.

69. An organic dye-sensitized solar cell as claimed in claim 57, wherein a release film is attached to the back surface of the organic polymer substrate having the counter electrode via an adhesive layer.

70. An organic dye-sensitized solar cell as claimed in claim 69, wherein the adhesive layer contains ethylene-vinyl acetate copolymer or sticky acrylic resin.

71. A building material having an organic dye-sensitized solar cell as claimed in claim 57, wherein the back surface of the transparent organic polymer substrate having the counter electrode is bonded to a surface of a base material via an adhesive layer.

72. A building material as claimed in claim 71, wherein the base material is a window pane.

73. A building material as claimed in claim 71, wherein the base material is a roofing material.

74. A method of forming a metal oxide semiconductor membrane having a large surface area, wherein coating liquid in which metal oxide microparticles are dispersed in a binder is applied to a substrate having a transparent electrode formed on a surface thereof and is dried so as to form a metal oxide containing coating, and the metal oxide containing coating is subjected to ultraviolet irradiation treatment so as to remove the binder, thereby forming a metal oxide semiconductor membrane having a large surface area.

75. A method as claimed in claim 74, wherein the wavelength of ultraviolet light to be used for the ultraviolet irradiation treatment is in a range of from 1 to 400 nm.

76. A method as claimed in claim 74, wherein the ultraviolet irradiation treatment is conducted in the presence of gas of at least one selected from a group consisting of ozone, oxygen, fluorine atom containing compound, and chlorine atom containing compound gases.

77. A method as claimed in claim 74, wherein the metal oxide semiconductor membrane is a membrane which is made of substantially only a metal oxide.

78. A method as claimed in claim 74, wherein the metal oxide is titanium oxide, zinc oxide, tin oxide, antimony oxide, niobium oxide, tungsten oxide, indium oxide, or any of these metal oxides doped with other metal or other metal oxide.

79. A method as claimed in claim 78, wherein the metal oxide is titanium oxide.

80. A method as claimed in claim 79, wherein the metal oxide is anatase-type titanium dioxide.

81. A method as claimed in claim 74, wherein the primary diameter of the metal oxide microparticles is in a range of from 0.001 to 5 μm.

82. A method as claimed in claim 74, wherein the metal oxide semiconductor membrane is made of titanium oxide, zinc oxide, tin oxide, antimony oxide, niobium oxide, tungsten oxide, indium oxide, or any of these metal oxides doped with other metal or other metal oxide.

83. A method as claimed in claim 82, wherein the metal oxide semiconductor membrane is titanium oxide.

84. A method as claimed in claim 83, wherein the metal oxide semiconductor membrane is anatase-type titanium dioxide.

85. A method as claimed in claim 74 wherein the binder is an organic polymer.

86. A method as claimed in claim 74, wherein the thickness of the metal oxide semiconductor membrane is 10 nm or more.

87. An organic dye-sensitized metal oxide semiconductor electrode including a substrate having a transparent electrode on the surface thereof and a metal oxide semiconductor membrane formed on the transparent electrode which are obtained by a method as claimed in claim 74, and an organic dye adsorbed in the surface of the semiconductor membrane.

88. An organic dye-sensitized solar cell comprising an organic dye-sensitized metal oxide semiconductor electrode as claimed in claim 87, a counter electrode arranged at an opposed position to the organic dye-sensitized metal oxide semiconductor electrode, and a redox electrolyte filled between these electrodes.

89. A method of forming a transparent electrode, wherein coating liquid in which conductive metal oxide microparticles are dispersed in a binder is applied to a surface of a substrate and is dried so as to form a conductive metal oxide containing coating, the binder is then removed from the conductive metal oxide containing coating so as to form a coating-type transparent electrode membrane, and a conductive metal oxide is deposited on the coating-type transparent electrode membrane by vapor deposition so as to form a vapor deposition-type transparent electrode membrane, thereby providing a lamination-type transparent electrode.

90. A method of forming a transparent electrode, wherein a conductive metal oxide is deposited on a surface of a substrate so as to form a vapor deposition-type transparent electrode membrane by vapor deposition, coating liquid in which conductive metal oxide microparticles are dispersed in a binder is applied to the vapor deposition-type transparent electrode membrane and is dried so as to form a conductive metal oxide containing coating, and then the binder is removed from the conductive metal oxide containing coating so as to form a coating-type transparent electrode membrane, thereby providing a lamination-type transparent electrode.

91. A method as claimed in claim 89, wherein the binder is removed by plasma treatment.

92. A method as claimed in claim 91, wherein the plasma treatment is conducted with high-frequency plasma, microwave plasma, or a hybrid type thereof.

93. A method as claimed in claim 91, wherein the plasma treatment is conducted in the presence of gas of at least one selected from a group consisting of oxygen, fluorine, and chlorine gases.

94. A method as claimed in claim 89, wherein the binder is removed by ultraviolet irradiation treatment.

95. A method as claimed in claim 94, wherein the wavelength of ultraviolet light to be used for the ultraviolet irradiation treatment is in a range of from 1 to 400 nm.

96. A method as claimed in claim 94, wherein the ultraviolet irradiation treatment is conducted in the presence of gas of at least one selected from a group consisting of ozone, oxygen, fluorine atom containing compound and chlorine atom containing compound gases.

97. A method as claimed in claim 89, wherein the conductive metal oxide is at least one of selected from a group consisting of In₂O₃:Sn(ITO), SnO₂:Sb, SnO₂:F, ZnO:Al, SnO₂, ZnO:F, and CdSnO₄.

98. A method as claimed in claim 89, wherein the coating-type transparent electrode membrane is a membrane which is made of substantially only a conductive metal oxide.

99. A method as claimed in claim 89, wherein the primary particle diameter of the conductive metal oxide microparticles is in a range of from 0.001 to 5 μm.

100. A method as claimed in claim 89, wherein the binder is polyalkylene glycol.

101. A method as claimed in claim 89, wherein the vapor deposition for forming the vapor deposition-type transparent electrode membrane is physical deposition, vacuum deposition, sputtering, ion plating, CVD, or plasma CVD.

102. A method as claimed in claim 89, wherein the vapor deposition-type transparent electrode membrane is at least one of selected from a group consisting of In₂O₃:Sn(ITO), SnO₂:Sb, SnO₂:F, ZnO:Al, SnO₂, ZnO:F, and CdSnO₄.

103. A method as claimed in claim 89, wherein the thickness of the vapor deposition-type transparent electrode membrane is in a range of from 0.1 to 100 nm.

104. A method as claimed in claim 89, wherein the thickness of the coating-type transparent electrode membrane is in a range of from 10 to 500 nm.

105. A transparent electrode substrate having a transparent electrode membrane which is formed on a substrate surface according to a method as claimed in claim 89.

106. A method of forming a metal oxide semiconductor membrane including a step of forming a metal oxide semiconductor membrane on a transparent electrode of a transparent electrode substrate as claimed in claim 105 by vapor deposition.

107. A method as claimed in claim 106, wherein the vapor deposition is physical deposition, vacuum deposition, sputtering, ion plating, CVD, or plasma CVD.

108. A method as claimed in claim 106, wherein the metal oxide semiconductor membrane is a membrane formed by depositing titanium oxide, zinc oxide, tin oxide, antimony oxide, niobium oxide, tungsten oxide, indium oxide, or any of these metal oxides doped with other metal or other metal oxide by vapor deposition.

109. A method as claimed in claim 108, wherein the metal oxide semiconductor membrane is made of titanium oxide.

110. A method as claimed in claim 109, wherein the metal oxide semiconductor membrane is made of anatase-type titanium dioxide.

111. An organic dye-sensitized metal oxide semiconductor electrode including a substrate having a transparent electrode on the surface thereof and a metal oxide semiconductor membrane formed on the transparent electrode which are obtained by a method as claimed in any one of claims 106 through 110 claim 106, and an organic dye adsorbed in the surface of the semiconductor membrane.

112. An organic dye-sensitized solar cell comprising an organic dye-sensitized metal oxide semiconductor electrode as claimed in claim 111, a counter electrode arranged at an opposed position to the organic dye-sensitized metal oxide semiconductor electrode, and a redox electrolyte filled between these electrodes.
